(19) United States
(12) Patent Application Publication
(10) Pub. No.: US 2026/0020319 A1
(43) Pub. Date: Jan. 15, 2026

(54) SEMICONDUCTOR DEVICE

(71) Applicant: SEMICONDUCTOR ENERGY LABORATORY CO., LTD., Atsugi-shi (JP)

(72) Inventors: Masashi OOTA, Isehara (JP); Shoki MIYATA, Atsugi (JP); Kazuma FURUTANI, Atsugi (JP); Yusuke KOUMURA, Atsugi (JP); Takeya HIROSE, Atsugi (JP); Yoshinori ANDO, Atsugi (JP); Takanori MATSUZAKI, Atsugi (JP)

(21) Appl. No.: 19/262,425

(22) Filed: Jul. 8, 2025

(30) Foreign Application Priority Data
Jul. 10, 2024 (JP) 2024-111322
Dec. 6, 2024 (JP) 2024-213737

(51) Int. Cl. H10D 64/66; H10B 12/00; H10D 1/68; H10D 30/67

(52) U.S. Cl. CPC H10D 64/666; H10B 12/033; H10B 12/05; H10B 12/312; H10D 1/696; H10D 1/716; H10D 30/6755; H10D 64/667

(57) ABSTRACT

A semiconductor device which is easily miniaturized is provided. A semiconductor device that can be highly integrated is provided. A first insulating layer includes an opening; a first conductive layer is positioned along the opening; a third insulating layer is positioned along the first conductive layer; a second conductive layer is positioned in a depression portion of the third insulating layer; a second insulating layer is positioned over the second conductive layer and includes a slit reaching the second conductive layer; a third conductive layer is positioned over the second insulating layer; a semiconductor layer includes a portion in contact with a side surface of the third conductive layer, a portion in contact with a side surface of the second insulating layer in the slit, and a portion in contact with a top surface of the second conductive layer in the slit; a fourth insulating layer covers the semiconductor layer in the slit; a fourth conductive layer covers the fourth insulating layer in the slit; the second conductive layer includes a first layer, a second layer, and a third layer; a top surface of the first layer includes a depression portion; the second layer is positioned in the depression portion of the first layer; and the third layer is positioned over the first layer and the second layer.

### BACKGROUND OF THE INVENTION

### 1. Field of the Invention

One embodiment of the present invention relates to a semiconductor device. One embodiment of the present invention relates to a transistor. One embodiment of the present invention relates to a memory device.

Note that one embodiment of the present invention is not limited to the above technical field. Examples of the technical field of one embodiment of the present invention disclosed in this specification and the like include a semiconductor device, a display device, a light-emitting apparatus, a power storage device, a memory device, an electronic apparatus, a lighting device, an input device, an input/output device, a driving method thereof, and a manufacturing method thereof. A semiconductor device generally means a device that can function by utilizing semiconductor characteristics.

### 2. Description of the Related Art

In recent years, semiconductor devices have been developed, and a CPU, a memory, or other LSI is mainly used as the semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of a CPU, a memory, or other LSI is mounted on a circuit board, for example, a printed wiring board, to be used as one of components of a variety of electronic apparatuses.

A technique by which a transistor is formed using a semiconductor thin film formed over a substrate having an insulating surface has been attracting attention. The transistor is used in a wide range of electronic devices such as an integrated circuit and an image display device (also simply referred to as a display device). A silicon-based semiconductor material is widely known as a material of a semiconductor thin film that can be used in a transistor. As another material, an oxide semiconductor has been attracting attention.

It is known that a transistor including an oxide semiconductor has an extremely low leakage current in a non-conducting state. For example, Patent Document 1 discloses a low-power CPU utilizing the characteristic of a low leakage current. Furthermore, for example, Patent Document 2 discloses a memory device that can retain stored data for a long time.

In recent years, demand for an integrated circuit with higher density has risen with reductions in size and weight of electronic apparatuses. In addition, the productivity of a semiconductor device including an integrated circuit is desired to be improved. For example, Patent Document 3 discloses a technique to achieve an integrated circuit with higher density by making a plurality of memory cells overlap with each other by stacking a first transistor including an oxide semiconductor film and a second transistor including an oxide semiconductor film. Furthermore, Patent Document 4 discloses a vertical transistor in which the side surface of an oxide semiconductor is covered with a gate electrode with a gate insulator therebetween.

### REFERENCES

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473
[Patent Document 4] Japanese Published Patent Application No. 2013-211537

### Non-Patent Document

[Non-Patent Document 1] Takashi Koida, “High-mobility transparent conductive film”, National Institute of Advanced Industrial Science and Technology, AIST Photovoltaic Technology Research Symposium 2019, Internet URL: https://unit.aist.go.jp/rpd-envene/PV/ja/results/2019/oral/T13.pdf

### SUMMARY OF THE INVENTION

An object of one embodiment of the present invention is to provide a semiconductor device which is easily miniaturized. Another object is to provide a semiconductor device that can be highly integrated. Another object is to provide a semiconductor device in which the load on a wiring is reduced. Another object is to provide a highly reliable semiconductor device. Another object is to provide a semiconductor device showing excellent electrical characteristics. Another object is to provide a semiconductor device which operates at high speed. Another object is to provide a semiconductor device with high productivity.

An object of one embodiment of the present invention is to provide a semiconductor device, a memory device, or an electronic apparatus having a novel structure. An object of one embodiment of the present invention is to at least alleviate at least one of problems in the conventional art.

Note that the description of these objects does not preclude the existence of other objects. In one embodiment of the present invention, there is no need to achieve all of these objects. Objects other than these can be derived from the description of the specification, the drawings, the claims, and the like.

One embodiment of the present invention is a semiconductor device including a capacitor, a transistor over the capacitor, a first insulating layer, and a second insulating layer over the first insulating layer. In the semiconductor device, the capacitor includes a first conductive layer, a second conductive layer, and a third insulating layer; the transistor includes the second conductive layer, a third conductive layer, a fourth conductive layer, a semiconductor layer, and a fourth insulating layer; the first insulating layer includes an opening; the first conductive layer is positioned along the opening; the third insulating layer is positioned along the first conductive layer; the second conductive layer is positioned in a depression portion of the third insulating layer; the second insulating layer is positioned over the second conductive layer and includes a slit reaching the second conductive layer; the third conductive layer is positioned over the second insulating layer; the semiconductor layer includes a portion in contact with a side surface of the third conductive layer, a portion in contact with a side surface of the second insulating layer in the slit, and a portion in contact with a top surface of the second conductive layer in the slit; the fourth insulating layer covers the semiconductor layer in the slit; the fourth conductive layer covers the fourth insulating layer in the slit; the second conductive layer includes a first layer, a second layer, and a third layer; a top surface of the first layer includes a depression portion; the second layer is positioned in the depression portion of the first layer; and the third layer is positioned over the first layer and the second layer.

In the above, it is preferable that the top surface of the first layer be substantially level with a top surface of the second layer.

In the above, it is preferable that a bottom surface of the third layer be in contact with the top surface of the first layer and the top surface of the second layer.

In the above, it is preferable that the third insulating layer and the second conductive layer have substantially the same top surface shapes.

In the above, it is preferable that the semiconductor device further include a connection electrode and a fifth conductive layer, that the slit extend in a first direction, that the fourth conductive layer extend in the first direction in the slit, that the fifth conductive layer be positioned over the fourth conductive layer and extend in a second direction intersecting with the first direction, and that the connection electrode be in contact with a top surface of the third conductive layer and a bottom surface of the fifth conductive layer.

In the above, it is preferable that the semiconductor layer include a first metal oxide, that the third layer include a second metal oxide, and that each of the first metal oxide and the second metal oxide include indium.

In the above, it is preferable that the first layer include tungsten and that the second layer include titanium nitride.

With one embodiment of the present invention, a semiconductor device which is easily miniaturized can be provided. A semiconductor device that can be highly integrated can be provided. A semiconductor device in which the load on a wiring is reduced can be provided. A highly reliable semiconductor device can be provided. A semiconductor device showing excellent electrical characteristics can be provided. A semiconductor device which operates at high speed can be provided. A semiconductor device with high productivity can be provided.

With one embodiment of the present invention, a semiconductor device, a memory device, or an electronic apparatus having a novel structure can be provided. With one embodiment of the present invention, at least one of problems in the conventional art can be at least alleviated.

Note that the description of these effects does not preclude the existence of other effects. One embodiment of the present invention does not necessarily have all these effects. Effects other than these can be derived from the description of the specification, the drawings, the claims, and the like.

### BRIEF DESCRIPTION OF THE DRAWINGS

FIGS. 1A and 1B each illustrate a structure example of a semiconductor device.

FIG. 2 illustrates a structure example of a semiconductor device.

FIG. 3 illustrates a structure example of a semiconductor device.

FIG. 4 illustrates a structure example of a semiconductor device.

FIG. 5 illustrates a structure example of a semiconductor device.

FIG. 6 illustrates a structure example of a semiconductor device.

FIG. 7 illustrates a structure example of a semiconductor device.

FIG. 8 illustrates a structure example of a semiconductor device.

FIG. 9 illustrates a structure example of a semiconductor device.

FIG. 10 illustrates a structure example of a semiconductor device.

FIG. 11 illustrates a structure example of a semiconductor device.

FIG. 12 illustrates a structure example of a semiconductor device.

FIG. 13 illustrates a structure example of a semiconductor device.

FIGS. 14A to 14C illustrate an example of a method for manufacturing a semiconductor device.

FIGS. 15A to 15C illustrate the example of the method for manufacturing the semiconductor device.

FIGS. 16A to 16C illustrate the example of the method for manufacturing the semiconductor device.

FIGS. 17A and 17B illustrate the example of the method for manufacturing the semiconductor device.

FIGS. 18A and 18B illustrate the example of the method for manufacturing the semiconductor device.

FIGS. 19A and 19B illustrate the example of the method for manufacturing the semiconductor device.

FIGS. 20A and 20B illustrate the example of the method for manufacturing the semiconductor device.

FIGS. 21A and 21B illustrate the example of the method for manufacturing the semiconductor device.

FIGS. 22A and 22B each show carrier concentration dependence of Hall mobility, and FIG. 22C is a cross-sectional view for explaining an indium oxide film.

FIG. 23 is a block diagram illustrating a structure example of a semiconductor device.

FIGS. 24A to 24H each illustrate a circuit structure example of a memory cell.

FIGS. 25A and 25B are perspective views each illustrating a structure example of a semiconductor device.

FIG. 26 is a block diagram for explaining a CPU.

FIGS. 27A and 27B are perspective views of a semiconductor device.

FIGS. 28A and 28B are each a perspective view of a semiconductor device.

FIGS. 29A and 29B each illustrate a structure example of an electronic component.

FIGS. 30A to 30C illustrate a structure example of a large computer.

FIG. 31A illustrates a structure example of space equipment. FIG. 31B illustrates a structure example of a storage system.

FIG. 32 is a cross-sectional STEM image in Example 1.

FIGS. 33A and 33B are cross-sectional STEM images in Example 1.

FIG. 34 is a graph in Example 1.

FIG. 35 is a graph in Example 1.

FIG. 36 is a graph in Example 1.

FIG. 37 is a graph in Example 1.

FIG. 38A is a schematic perspective view of a memory cell array. FIG. 38B is a diagram for explaining a manufacturing process of a memory cell.

FIG. 39A is a schematic plan view of a memory cell. FIG. 39B is an equivalent circuit diagram of the memory cell. FIGS. 39C and 39D are schematic cross-sectional views of the memory cell.

FIG. 40A is a schematic plan view of a memory cell. FIG. 40B is an equivalent circuit diagram of the memory cell. FIGS. 40C and 40D are schematic cross-sectional views of the memory cell.

FIGS. 41A and 41B are graphs in Example 2.

FIG. 42 is a graph in Example 2.

FIGS. 43A and 43B are graphs in Example 2.

FIG. 44 is a graph in Example 2.

FIG. 45 illustrates a circuit structure used in simulation.

FIG. 46 is a circuit diagram of a sense amplifier circuit.

FIGS. 47A and 47B are timing charts in Example 2.

FIGS. 48A and 48B are graphs in Example 2.

FIG. 49 is an external-view photograph of a DRAM chip.

FIG. 50 is a cross-sectional STEM image of a DRAM chip.

FIGS. 51A and 51B are block diagrams of a DRAM chip.

FIGS. 52A and 52B are diagrams in Example 2.

FIGS. 53A and 53B are each a timing chart of a DRAM chip.

FIG. 54A is a schematic diagram for explaining a delay circuit. FIG. 54B is a timing chart of the delay circuit.

FIG. 55 is a graph showing simulation results of a delay circuit.

FIG. 56 is a graph in Example 2.

### DETAILED DESCRIPTION OF THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that in this specification and the like, ordinal numbers such as “first” and “second” are used in order to avoid confusion among components and do not limit the number of components.

A transistor is a kind of semiconductor element and enables amplification of a current or a voltage, a switching operation for controlling conduction or non-conduction, and the like. A transistor in this specification includes, in its category, an insulated-gate field effect transistor (IGFET) and a thin film transistor (TFT).

The functions of a “source” and a “drain” are sometimes replaced with each other when a transistor of different polarity is used or when the direction of current flow is changed in a circuit operation, for example. Thus, the terms “source” and “drain” can be used interchangeably in this specification.

In this specification and the like, the term “electrically connected” includes the case where components are connected through an “object having any electric function”. There is no particular limitation on the “object having any electric function” as long as electric signals can be transmitted and received between components that are connected through the object. Examples of the “object having any electric function” are a switching element such as a transistor, a resistor, a coil, and an element with a variety of functions as well as an electrode and a wiring.

Note that in this specification and the like, “electrical connection” does not include the case where two nodes are connected to each other with an insulator (e.g., a dielectric of a capacitor, a gate insulating film of a transistor, or an interlayer insulating film) provided between the two nodes.

In this specification and the like, the expression “having substantially the same top surface shapes” means that the outlines of stacked layers at least partly overlap with each other. For example, the case of patterning an upper layer and a lower layer with the use of the same mask pattern or mask patterns that are partly the same is included. The expression “having substantially the same top surface shapes” also sometimes includes the case where the outlines do not completely overlap with each other; for instance, the edge of the upper layer may be positioned on the inner side or the outer side of the edge of the lower layer.

Note that in this specification and the like, a top surface shape of a component means the outline of the component in a plan view. A plan view means a view to observe the component from a normal direction of a surface where the component is formed or from a normal direction of a surface of a support (e.g., a substrate) where the component is formed.

Note that the expressions indicating directions such as “over” and “under” are basically used to correspond to the directions of drawings. However, in some cases, the term “over” or “under” in the specification indicates a direction that does not correspond to the apparent direction in the drawings, for the purpose of easy description or the like. For example, in the description of the stacked order (formation order) of a stacked body or the like, even in the case where a surface on which the stacked body is provided (e.g., a formation surface, a support surface, a bonding surface, or a planarization surface) is positioned over the stacked body in the drawings, the following expressions are used in some cases: the formation surface side is under the stacked body or the stacked body side is over the formation surface side.

Note that in this specification and the like, the channel length direction of a transistor refers to one of directions parallel to the shortest straight line connecting a source region and a drain region. That is, the channel length direction corresponds to one of directions of current flow in a semiconductor layer when a transistor is in an on state. The channel width direction refers to a direction orthogonal to the channel length direction. Each of the channel length direction and the channel width direction is not fixed to one direction in some cases depending on the structure or the shape of a transistor.

In this specification and the like, the terms “film” and “layer” can be interchanged with each other. For example, in some cases, the term “insulating layer” can be interchanged with the term “insulating film”.

Unless otherwise specified, an off-state current in this specification and the like refers to a drain current of a transistor in an off state (also referred to as a non-conduction state or a cutoff state). Unless otherwise specified, the off state of an n-channel transistor means that gate-source voltage Vgs is lower than threshold voltage Vth, and the off state of a p-channel transistor means that Vgs is higher than Vth.

### Embodiment 1

In this embodiment, structure examples of a semiconductor device of one embodiment of the present invention and a manufacturing method example thereof are described. The semiconductor device described below can be applied to a memory device.

The semiconductor device of one embodiment of the present invention includes a plurality of memory cells. The memory cell includes one transistor and one memory element. As the memory element, any of a variety of elements that can retain stored data, such as a capacitor, a resistive random access element, a ferroelectric element, a charge trap element, and a floating-gate element, can be used.

In the transistor included in the memory cell, a source electrode and a drain electrode are positioned at different heights, so that a current flows in a semiconductor layer in the height direction. In other words, the channel length direction includes a height (vertical) component, so that one embodiment of the present invention can be referred to as a vertical field effect transistor (VFET), a vertical transistor, a vertical-channel transistor, or the like.

More specifically, an insulating layer functioning as a spacer is provided above a lower electrode which is one of the source electrode and the drain electrode, and an upper electrode which is the other of the source electrode and the drain electrode is provided above the insulating layer. The insulating layer is provided with a slit extending in a first direction and reaching the lower electrode. The slit has a side surface substantially perpendicular to a substrate surface. The semiconductor layer includes a portion in contact with the side surface of the upper electrode, a portion in contact with the side surface of the insulating layer in the slit, and a portion in contact with the top surface of the lower electrode in the slit. A gate insulating layer is provided to cover the semiconductor layer inside the slit. A gate electrode is provided to cover the gate insulating layer inside the slit.

The semiconductor layer preferably includes a metal oxide exhibiting semiconductor characteristics (an oxide semiconductor). For example, to form a source region and a drain region using silicon, which is a typical material of a semiconductor, the regions need to be doped with an impurity functioning as a donor or an acceptor. However, in the vertical transistor of one embodiment of the present invention, it may be difficult to perform impurity doping on the semiconductor layer with high accuracy because the levels of a source and a drain are different from each other and the channel formation region is oriented in the vertical direction with respect to the substrate surface, for example. In contrast, the oxide semiconductor can form a low-resistance region without such impurity doping and can be connected to the source electrode and the drain electrode favorably; thus, a transistor having a three-dimensional structure as in one embodiment of the present invention can be fabricated with high yield.

A capacitor included in the memory cell can be provided below the transistor. For example, the capacitor may be formed in an opening having a vertical hole shape provided in an insulating layer. Stacking the transistor and the capacitor enables the memory cells to be arranged at high density. The capacitor can be what is called a metal-insulator-metal (MIM) capacitor, in which a dielectric is provided between a pair of electrodes. In that case, the lower electrode of the transistor also preferably serves as the upper electrode of the capacitor.

Here, the lower electrode of the transistor preferably includes a first layer in which a depression portion overlapping with the opening is formed, a second layer provided to fill the depression portion of the first layer, and a third layer formed over the first layer and the second layer. With such a structure, the top surfaces of the first layer and the second layer can be planarized, so that the top surfaces of the first layer and the second layer can be substantially level with each other. Thus, a formation surface of the third layer can be planarized, so that the third layer can have a flat shape. This can prevent formation of a locally thinned portion in the third layer. Thus, when the slit is formed, the slit can be prevented from penetrating the third layer. In this manner, the semiconductor layer being in contact with the third layer and not being in contact with the first layer can be formed.

The third layer in contact with the semiconductor layer preferably includes a conductive metal oxide (an oxide conductor). A metal oxide is preferably used for the conductive film which is in contact with the semiconductor layer including a metal oxide, in which case contact resistance between the conductive film and the semiconductor layer can be reduced and the load on a wiring can be reduced. It is particularly preferable that the third layer include the same metal element as the semiconductor layer, in which case the contact resistance can be further reduced. Specifically, the semiconductor layer and the third layer preferably include one or more of In, Sn, Zn, Ga, and Ti. For the first layer, a low-resistance metal material can be used. Accordingly, both the contact resistance and the wiring resistance can be reduced, so that the load on a wiring can be further reduced.

More specific examples are described below with reference to drawings.

### [Structure Example]

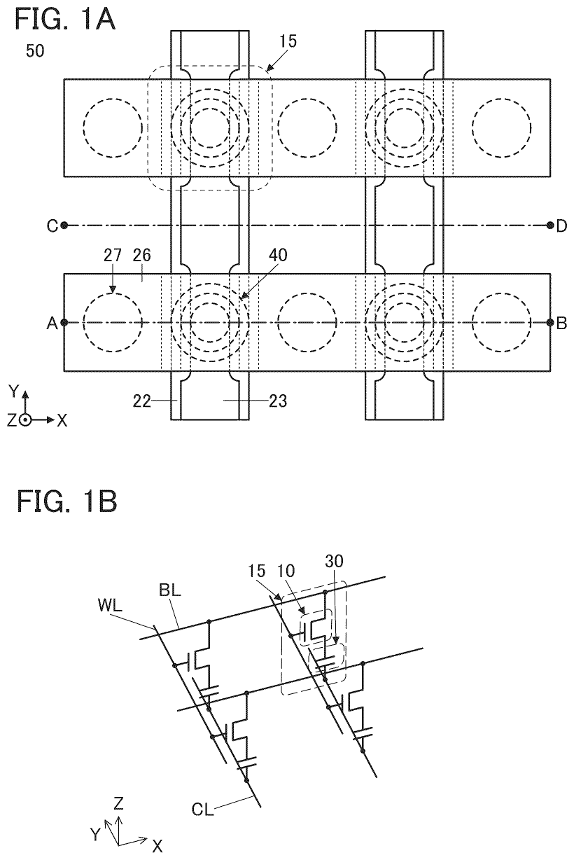

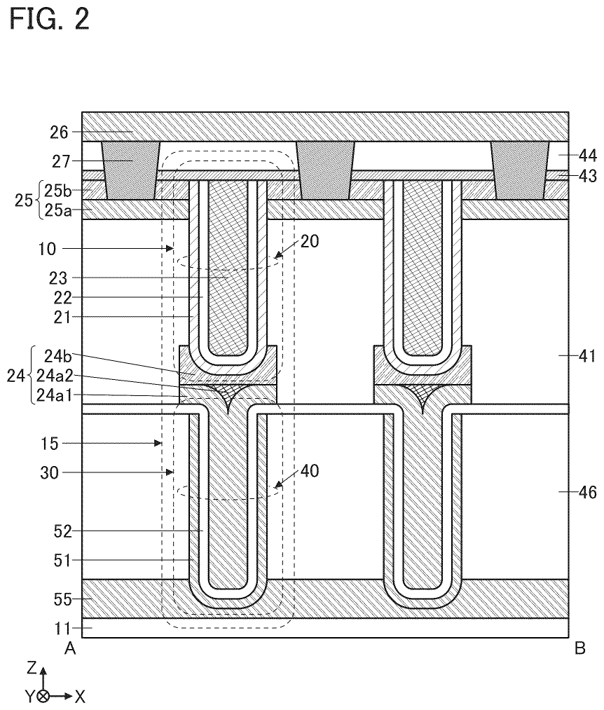

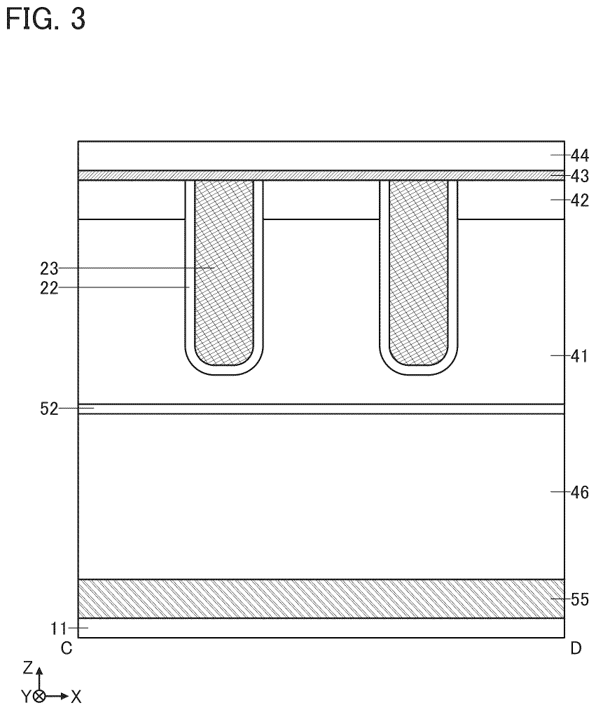

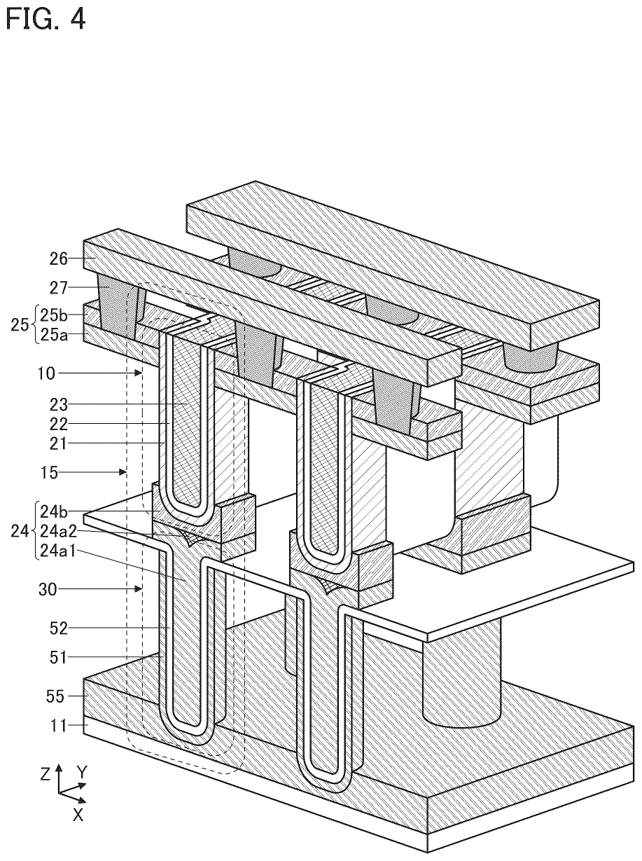

FIG. 1A is a schematic top view of a semiconductor device 50. FIG. 2 and FIG. 3 are schematic cross-sectional views taken along line A-B and line C-D in FIG. 1A, respectively. FIG. 4 is a perspective view of the semiconductor device 50. Some components (e.g., insulating layers) are omitted in FIG. 4. In each drawing, the arrows indicate directions of X, Y, and Z. Here, the X direction, the Y direction, and the Z direction intersect with each other; for example, the X direction, the Y direction, and the Z direction are orthogonal to each other.

The semiconductor device 50 has a structure in which a plurality of memory cells 15 are arranged in the X direction and the Y direction. In the semiconductor device 50, a conductive layer 26 functioning as a bit line extends in the X direction and a conductive layer 23 functioning as a word line extends in the Y direction. As illustrated in FIG. 2, the memory cell 15 includes a transistor 10 and a capacitor 30 thereunder.

FIG. 1B is a circuit diagram corresponding to the semiconductor device 50. FIG. 1B illustrates a plurality of wirings BL functioning as bit lines, a plurality of wirings WL being orthogonal to the bit lines and functioning as word lines, and a wiring CL. Although FIG. 1B illustrates an example in which the wiring CL is parallel to the wiring WL, the wiring CL can be parallel to the wiring BL or can be placed in a lattice shape. Alternatively, the wiring CL may be a flat plate-like (can also be referred to as plate-like) conductive film.

The memory cell 15 includes one transistor 10 and one capacitor 30. A gate of the transistor 10 is connected to the wiring WL, one of a source and a drain of the transistor 10 is connected to the wiring BL, and the other of the source and the drain of the transistor 10 is connected to one electrode of the capacitor 30. The other electrode of the capacitor 30 is connected to the wiring CL.

The wiring BL functions as a wiring for writing and reading data. The wiring WL functions as a wiring for controlling on/off (conduction/non-conduction state) of the transistor 10 serving as a switch. The wiring CL has a function of a constant potential line connected to the capacitor 30.

As illustrated in FIG. 2, the transistor 10 and the capacitor 30 are provided over an insulating layer 11 provided over a substrate (not illustrated). The insulating layer 11 serves as a base insulating layer.

The transistor 10 includes a semiconductor layer 21, an insulating layer 22 functioning as a gate insulating layer, the conductive layer 23 functioning as a gate electrode, a conductive layer 24 functioning as one of a source electrode and a drain electrode, and a conductive layer 25 functioning as the other of the source electrode and the drain electrode. Here, the conductive layer 24 has a stacked-layer structure including a conductive layer 24a1, a conductive layer 24a2 over the conductive layer 24a1, and a conductive layer 24b over the conductive layer 24a1 and the conductive layer 24a2. Note that the conductive layers 24a1 and 24a2 are collectively referred to as a conductive layer 24a in some cases below. In the illustrated example, the conductive layer 25 includes a conductive layer 25a and a conductive layer 25b positioned over the conductive layer 25a.

The capacitor 30 is provided over a conductive layer 55 functioning as the wiring CL. The capacitor 30 includes a conductive layer 51 functioning as a lower electrode, the conductive layer 24 functioning as an upper electrode, and an insulating layer 52 positioned therebetween and functioning as a dielectric. In this manner, the conductive layer 24 preferably serves as the lower electrode of the transistor 10 and the upper electrode of the capacitor 30. In that case, the manufacturing process can be simplified and the manufacturing cost can be reduced. In the case where the conductive layer 24 has a stacked-layer structure of the conductive layer 24a and the conductive layer 24b as illustrated in FIG. 2 and the like, the lower conductive layer 24a can function as the upper electrode of the capacitor 30. In this case, it can be said that the upper conductive layer 24b functions as a connection electrode for connecting the conductive layer 24a and the semiconductor layer 21.

The conductive layer 55 is provided over the insulating layer 11. Although an example in which the conductive layer 55 has a two-dimensional flat plate-like (plate-like) shape is described here, a wiring (a linear shape) extending in the X direction, the Y direction, or any of the other directions can also be employed. Alternatively, a lattice shape in which two or more portions extending in different directions are combined can be employed.

An insulating layer functioning as a protective insulating layer can be provided between the insulating layer 11 and the conductive layer 55. Alternatively, the insulating layer 11 may function as a protective insulating layer. The insulating layer has a function of preventing diffusion of impurities such as hydrogen into the semiconductor layer 21 from the insulating layer 11 or from below the insulating layer 11. For example, a film which is less likely to allow diffusion of hydrogen (which has a higher barrier property against hydrogen) than a silicon oxide film, such as a silicon nitride film, a silicon nitride oxide film, an aluminum oxide film, a magnesium oxide film, a hafnium oxide film, or a gallium oxide film, can be used. Specifically, a silicon nitride film or a silicon nitride oxide film is preferably used.

Note that in this specification and the like, oxynitride refers to a material in which an oxygen content is higher than a nitrogen content, and nitride oxide refers to a material in which a nitrogen content is higher than an oxygen content. For example, silicon oxynitride refers to a material that contains more oxygen than nitrogen, and silicon nitride oxide refers to a material that contains more nitrogen than oxygen.

An insulating layer 46 is provided over the conductive layer 55. The insulating layer 46 functions as an interlayer insulating layer. The insulating layer 46 includes a plurality of openings 40 reaching the conductive layer 55, and one capacitor 30 is provided in each of the openings 40. The opening 40 preferably has a vertical hole shape with a high aspect ratio. When the opening 40 is formed deeply, the area where the pair of electrodes of the capacitor 30 face each other can be increased, so that the capacitance can be increased.

The conductive layer 51 is provided along the opening 40. Specifically, the conductive layer 51 includes a portion provided along the side surface of the insulating layer 46 in the opening 40 and a portion in contact with the top surface of the conductive layer 55. In other words, the conductive layer 51 has a cylindrical shape with the bottom (also referred to as a cup-like shape) and includes a depression portion. The conductive layers 51 are provided separately for the respective memory cells 15, and the conductive layers 51 are connected to each other by the conductive layer 55.

The insulating layer 52 is provided along the conductive layer 51. Specifically, the insulating layer 52 includes a portion provided along the depression portion of the conductive layer 51, a portion in contact with the top surface of the conductive layer 51, and a portion in contact with the top surface of the insulating layer 46. The insulating layer 52 does not need to be formed separately for each of the memory cells 15 and can be formed as one continuous component. However, without limitation to this structure, the insulating layers 52 can be provided separately for the respective memory cells 15.

The conductive layer 24 is formed to fill the depression portion of the insulating layer 52. In other words, the conductive layer 24 is provided to fill the depression portion of the conductive layer 51 with the insulating layer 52 therebetween, or the conductive layer 24 includes a portion provided over the insulating layer 46 with the insulating layer 52 therebetween. The conductive layers 24 are provided for the respective memory cells 15.

Although FIG. 1A and FIG. 4 and the like illustrate an example in which the outline of the conductive layer 51 in the plan view (outline of the opening 40) is circular, one embodiment of the present invention is not limited thereto. The cross-sectional shape of the conductive layer 51 in the horizontal direction is not limited to a circular ring shape and only needs to be a ring shape. For example, the shape of the outline of the conductive layer 51 in the plan view and the cross-sectional shape of the conductive layer 51 in the horizontal direction are not limited to circular shapes and can each be an elliptical shape, a quadrangular shape with rounded corners, or the like. Alternatively, a regular polygonal shape such as a regular triangular shape, a square shape, or a regular pentagonal shape or a polygonal shape other than the regular polygonal shape may be employed. By employing a concave polygonal shape in which at least one interior angle is greater than 180°, such as a star polygonal shape, the capacity can be increased. Alternatively, a polygonal shape with rounded corners, a closed curve in which a straight line and a curve are combined, or the like can be employed.

The capacitor 30 illustrated in FIG. 2 and the like is what is called a cylinder capacitor or a trench capacitor. The structure of the capacitor 30 is not limited thereto, and a pillar capacitor may be used, for example.

FIG. 2 and FIG. 4 illustrate an example in which the bottom portion of the conductive layer 51 is rounded (has a concave surface). Furthermore, the bottom portion of the insulating layer 52 provided along the conductive layer 51 and the bottom portion of the conductive layer 24 provided along the insulating layer 52 each have a rounded shape (a convex surface). When the conductive layer 51 which forms the formation surface of the insulating layer 52 has no corner portion in this manner, the insulating layer 52 can be prevented from being locally thinned. Furthermore, when the bottom portion of the conductive layer 51 has no corner portion, local concentration of electric fields can be prevented. This can reduce a leakage current of the capacitor, so that the reliability can be increased.

Moreover, the top surface of the conductive layer 55 is provided with a round depression, and the bottom portion of the conductive layer 51 is provided to be fitted in the round depression. Such a structure can increase the contact area between the conductive layer 55 and the conductive layer 51 and reduce contact resistance therebetween. The round depression of the conductive layer 55 can be formed by etching part of the upper portion of the conductive layer 55 at the time of forming the opening in the insulating layer 46.

The conductive layer 24a1 is preferably formed using a conductive material having lower resistance than the conductive layer 24b. In particular, a metal material is preferably included. When a metal material having a lower resistance than the conductive layer 24b is used for the conductive layer 24a1, both the contact resistance and the wiring resistance can be reduced, so that the load on a wiring can be further reduced. For example, a conductive material containing tungsten, copper, or aluminum can be used for the conductive layer 24al.

Since the conductive layer 24a1 is formed to fill the opening 40 having a high aspect ratio, a depression portion is sometimes formed on the top surface of the conductive layer 24a1, in particular, in a region overlapping with the opening 40 and the vicinity thereof. As illustrated in FIG. 2, the conductive layer 24a2 is formed to fill the depression portion of the conductive layer 24a1.

The conductive layer 24a2 is preferably formed using a conductive material. A conductive film to be the conductive layer 24a2 preferably has a function of preventing oxidation of a conductive film to be the conductive layer 24a1 in the manufacturing process. For such a conductive film, a conductive nitride can be used, for example. For example, the conductive layer 24a2 can be formed using a conductive nitride such as titanium nitride, a nitride containing titanium and aluminum, tantalum nitride, or a nitride containing tantalum and aluminum.

The top surface of the conductive layer 24a1 and the top surface of the conductive layer 24a2 are preferably planarized. For example, the top surface of the conductive layer 24a1 and the top surface of the conductive layer 24a2 are preferably substantially level with each other. With such a structure, the conductive layer 24b provided over the conductive layer 24a1 and the conductive layer 24a2 can also have a flat shape. This can prevent formation of unevenness in the conductive layer 24b and formation of a locally thinned region. Thus, a slit 20 can be prevented from being formed to reach the conductive layer 24a through the conductive layer 24b.

For the conductive layer 24b, a conductive metal oxide (an oxide conductor) is preferably used. The conductive metal oxide is preferably used for the conductive layer 24b which is in contact with the semiconductor layer 21 including a metal oxide, in which case contact resistance between the conductive layer 24b and the semiconductor layer 21 can be reduced and a load on a wiring can be reduced. It is particularly preferable that the conductive layer 24b include the same metal element that is included in the semiconductor layer 21, in which case the contact resistance can be further reduced. Specifically, the semiconductor layer 21 and the conductive layer 24b preferably include the same element(s) that is/are one or more selected from In, Sn, Zn, Ga, and Ti. For example, it is possible to use a conductive oxide such as indium oxide, zinc oxide, In—Sn oxide, In—Zn oxide, In—W oxide, In—W—Zn oxide, In—Ti oxide, In—Ti—Sn oxide, In—Sn—Si oxide, or Ga—Zn oxide for the conductive layer 24b.

The conductive layer 24b is preferably in contact with the conductive layer 24a1. As illustrated in FIG. 2, the bottom surface of the conductive layer 24b is preferably in contact with the top surface of the conductive layer 24a1 and the top surface of the conductive layer 24a2. When the conductive layer 24b is in contact with the conductive layer 24a1 having lower electric resistance, a load on a wiring can be further reduced.

An insulating layer 41 is provided above the conductive layer 24 and the insulating layer 52. The insulating layer 41 includes a belt-like slit 20 extending in the Y direction. The side surface of the insulating layer 41 in the slit 20 is preferably substantially perpendicular to the substrate surface. The height of the insulating layer 41 is preferably larger than the width of the slit 20 in the X direction.

In this specification and the like, the expression “two surfaces are perpendicular to each other” indicates a state where the interior angle between them is greater than or equal to 80° and less than or equal to 100°. Moreover, the expression “two surfaces are substantially perpendicular to each other” indicates a state where the interior angle between them is greater than or equal to 60° and less than or equal to 120° (including a state where the surfaces are perpendicular to each other). In this specification and the like, the expression “two surfaces are parallel to each other” indicates a state where the interior angle between them is greater than or equal to −10° and less than or equal to 10°. Moreover, the expression “two surfaces are substantially parallel to each other” indicates a state where the interior angle between them is greater than or equal to −30° and less than or equal to 30° (including a state where the surfaces are parallel to each other).

The conductive layer 25 is provided over the insulating layer 41. In the example described here, the conductive layer 25 has a stacked-layer structure of the conductive layer 25a and the conductive layer 25b provided over the conductive layer 25a. The conductive layer 25 is provided with a slit overlapping with the slit 20, and the conductive layer 25 is divided into two parts with the slit as a boundary. That is, a pair of the conductive layers 25 are provided over the insulating layer 41 such that one slit 20 is positioned between the pair of conductive layers 25. As illustrated in FIG. 4, the island-shaped conductive layers 25 are arranged at regular intervals along the extending direction of the slit 20.

The semiconductor layer 21, the insulating layer 22, and the conductive layer 23 each include a portion positioned inside the slit 20. The semiconductor layer 21 and the insulating layer 22 are provided along the side surface of the insulating layer 41 in the slit 20 and the top surface of the conductive layer 24 in the slit 20. The conductive layer 23 is provided to fill a depression portion of the insulating layer 22.

The semiconductor layer 21 includes a portion in contact with the side surface of the conductive layer 25, a portion in contact with the side surface of the insulating layer 41 in the slit 20, and a portion in contact with the top surface of the conductive layer 24b. Here, a conductive metal oxide similar to that used for the above-described conductive layer 24b is preferably used for one of the conductive layer 25a and the conductive layer 25b included in the conductive layer 25. For the other of the conductive layer 25a and the conductive layer 25b, a low-resistance metal material is preferably used. When a conductive film with low contact resistance with the semiconductor layer 21 and a conductive film with low wiring resistance are stacked, both the contact resistance and the wiring resistance can be reduced, so that the load on a wiring can be further reduced. An example in which a conductive metal oxide is used for the conductive layer 25b and a metal material is used for the conductive layer 25a is described below, but a conductive metal oxide can be used for the conductive layer 25a and a metal material can be used for the conductive layer 25b.

One of the conductive layers 25a and 25b which includes a conductive metal oxide preferably includes the same metal element that is included in the semiconductor layer 21, in which case the contact resistance can be further reduced. Specifically, the semiconductor layer 21 and one of the conductive layers 25a and 25b preferably include the same element(s) that is/are one or more selected from In, Sn, Zn, Ga, and Ti.

In the transistor 10, the source electrode and the drain electrode are located at different heights, so that a current flows in the height direction in the semiconductor. In other words, the channel length direction includes a height (vertical) component, and thus the transistor of one embodiment of the present invention can also be referred to as a VFET, a vertical transistor, a vertical channel transistor, or the like. Since two or more of the source electrode, the semiconductor, and the drain electrode can overlap with each other in the transistor 10, the area occupied by the transistor 10 can be significantly smaller than that occupied by what is called a planar transistor (also referred to as a lateral transistor, a lateral FET (LFET), or the like) in which a semiconductor is positioned over a flat plane.

The channel length of the transistor 10 can be precisely adjusted by the thickness of the insulating layer 41 serving as a spacer; thus, a variation in the channel length can be extremely smaller than that of a planar transistor. Furthermore, by reducing the thickness of the insulating layer 41, a transistor with an extremely short channel length can be manufactured. For example, it is possible to manufacture a transistor with a channel length of 2 μm or shorter, 1 μm or shorter, 500 nm or shorter, 300 nm or shorter, 200 nm or shorter, 100 nm or shorter, 50 nm or shorter, 30 nm or shorter, or 20 nm or shorter, and 5 nm or longer, 7 nm or longer, or 10 nm or longer. Thus, it is possible to achieve a transistor with an extremely short channel length that could not be achieved with a light-exposure apparatus for mass production. Moreover, a transistor with a channel length shorter than 10 nm can also be achieved without using an extremely expensive light-exposure apparatus used in the latest LSI technology.

A variety of semiconductor materials can be used for the semiconductor layer 21; in particular, an oxide semiconductor including a metal oxide is preferably used. The use of an oxide semiconductor formed under an appropriate condition allows a transistor having both a high on-state current and an extremely low off-state current to be achieved at a low cost. Described below are structure examples of the case where an oxide semiconductor is used for the semiconductor layer 21 unless otherwise specified.

Here, FIG. 2 illustrates an example in which the top surface of a region of the conductive layer 24b overlapping with the slit 20 has a round depression portion (a concave surface). Thus, inside the slit 20, bottom portions of the semiconductor layer 21, the insulating layer 22, and the conductive layer 23 are provided along the concave surface of the conductive layer 24b and have rounded projecting portions (convex surfaces). Accordingly, a structure in which an electric field is less likely to be concentrated can be achieved as in the conductive layer 51 of the capacitor 30. Thus, a transistor having a low leakage current and high reliability can be achieved.

It is preferable that the upper portions of the semiconductor layer 21, the insulating layer 22, and the conductive layer 23 be planarized such that the top surfaces of the semiconductor layer 21, the insulating layer 22, and the conductive layer 23 are substantially level with each other (e.g., at substantially the same levels from the substrate surface). Furthermore, the top surfaces of the semiconductor layer 21, the insulating layer 22, and the conductive layer 23 are preferably substantially level with the top surface of the conductive layer 25 (specifically, the conductive layer 25b). With such a structure, the conductive layer 25 and the conductive layer 23 do not overlap with each other in a plan view, so that parasitic capacitance between the conductive layer 25 and the conductive layer 23 can be reduced. Accordingly, a semiconductor device capable of a high-speed operation can be achieved.

An insulating layer 43 is provided in contact with the top surface of the conductive layer 25, the top surface of the semiconductor layer 21, the top surface of the insulating layer 22, and the top surface of the conductive layer 23. The insulating layer 43 functions as a barrier film that prevents diffusion of impurities such as hydrogen into the semiconductor layer 21 from above the insulating layer 43. For example, a film which is less likely to allow diffusion of hydrogen (which has a higher barrier property against hydrogen) than a silicon oxide film, such as a silicon nitride film, a silicon nitride oxide film, an aluminum oxide film, a magnesium oxide film, a hafnium oxide film, or a gallium oxide film, can be used. Specifically, a silicon nitride film or a silicon nitride oxide film is preferably used.

The insulating layer 43 preferably has a stacked-layer structure of an insulating film functioning as the above-described barrier film and an insulating film on the semiconductor layer 21 side having a function of capturing or fixing hydrogen. Accordingly, hydrogen that may diffuse into the semiconductor layer 21 by heat applied during the manufacturing process of the transistor 10 or the memory cell 15 can be captured or fixed by the insulating film, so that the concentration of hydrogen contained in the semiconductor layer 21 can be reduced. Thus, the transistor 10 or the semiconductor device 50 can have favorable electrical characteristics and high reliability. As the insulating film that captures or fixes hydrogen, a hafnium oxide film, a hafnium silicate film, an aluminum oxide film, a hafnium zirconium oxide film, or the like is preferably used.

An insulating layer 44 functioning as an interlayer insulating film is provided over the insulating layer 43. Note that the insulating layer 44 is not necessarily provided when not needed.

The conductive layer 26 functioning as a bit line is provided over the insulating layer 44. A plug 27 for connecting the conductive layer 25 and the conductive layer 26 to each other through an opening provided in the insulating layer 44 and the insulating layer 43 is provided. The plug 27 is in contact with the top surface of the conductive layer 25 and the bottom surface of the conductive layer 26. Thus, a plurality of the conductive layers 25 arranged in the X direction with the slits 20 therebetween can be connected to each other by the conductive layer 26. When the opening is formed also in the conductive layer 25b as illustrated in FIG. 2, the plug 27 can be provided in contact with the conductive layer 25a. With such a structure, the plug 27 can be connected to the lower-resistance conductive layer 25a, so that wiring resistance can be reduced.

Here, in the semiconductor device 50, a layer where the memory cell 15 is provided and a layer where a functional circuit is provided are preferably stacked. As the functional circuit, a driver circuit for driving the memory cell 15, an arithmetic circuit, a power supply circuit, or the like can be provided, for example. The driver circuit includes, for example, one or more of a row decoder, a column decoder, a row driver, a column driver, an input circuit, an output circuit, and a sense amplifier. Accordingly, the footprint of the semiconductor chip including the semiconductor device 50 can be reduced, and the wiring length can be shorter than that of the case where the functional circuit and the memory cell 15 are arranged side by side; hence, a high-speed operation and low power consumption can be achieved.

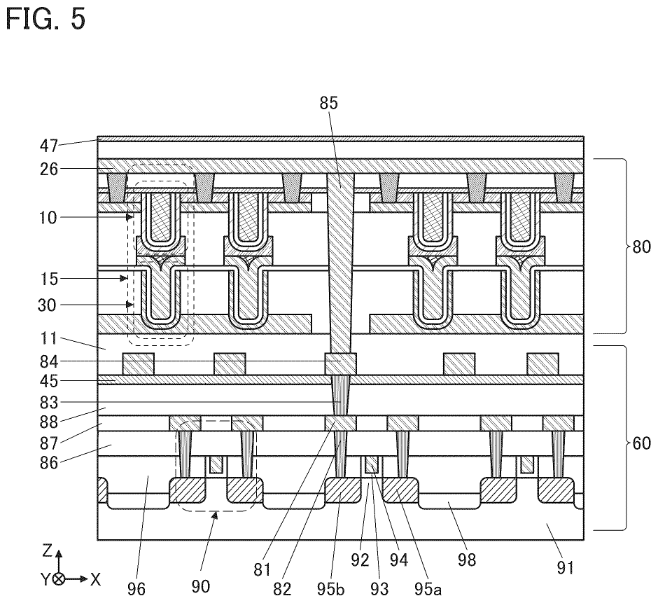

FIG. 5 illustrates an example in which a layer 60 provided with a transistor 90 included in the functional circuit is positioned below a layer 80 provided with the memory cell 15. Here, an example in which one of a source electrode and a drain electrode of the transistor 90 is connected to the conductive layer 26 functioning as a bit line is illustrated.

The transistor 90 is a transistor whose channel is formed in part of a substrate 91, which is a single crystal semiconductor substrate. For the substrate 91, single crystal silicon can be typically used. For the substrate 91, a semiconductor of a single element such as germanium, or a compound semiconductor of silicon carbide, silicon germanium, gallium arsenide, indium phosphide, zinc oxide, gallium oxide, or gallium nitride can be used, for example. The above semiconductor substrate in which an insulator region is included, e.g., a silicon on insulator (SOI) substrate, may be used as the substrate 91.

The transistor 90 is provided on the substrate 91 and includes a conductive layer 94 serving as a gate, an insulating layer 93 serving as a gate insulating layer, a semiconductor region 92 that is a part of the substrate 91, and a low-resistance region 95a and a low-resistance region 95b serving as a source region and a drain region. As the transistor 90, either a p-channel transistor or an n-channel transistor can be used. In the substrate 91, an element isolation layer 98 is provided between two adjacent transistors 90.

In the transistor 90, the semiconductor region 92 where a channel is formed has a projecting shape (fin shape). Although not illustrated in FIG. 5, the conductive layer 94 is provided to cover the side surface and the top surface of the semiconductor region 92 with the insulating layer 93 therebetween in the Y direction. A transistor like the transistor 90 is also referred to as a FIN transistor.

An insulating layer 96 is provided to cover the transistor 90, an insulating layer 86 is provided over the insulating layer 96, and an insulating layer 87 is provided over the insulating layer 86. A conductive layer 81 is provided to be embedded in the insulating layer 87. An insulating layer 88 is provided to cover the conductive layer 81 and the insulating layer 87, an insulating layer 45 is provided over the insulating layer 88, and the insulating layer 11 is provided over the insulating layer 45. A plug 82 is provided in the opening provided in the insulating layer 96 and the insulating layer 86, and the conductive layer 81 and the low-resistance region 95b are connected to each other through the plug 82. A conductive layer 84 is provided over the insulating layer 45, and the conductive layer 84 is connected to the conductive layer 81 through a plug 83 provided in an opening provided in the insulating layer 45 and the insulating layer 88. The conductive layer 84 and the conductive layer 26 are connected to each other through a plug 85 provided in an opening provided in each of the insulating layers between the conductive layer 84 and the conductive layer 26. Thus, one of a source and a drain of the transistor 90 is connected to the conductive layer 26.

Although the conductive layer 81 is provided as a wiring layer in the upper portion of the layer 60 in this example, one embodiment of the present invention is not limited thereto. For example, a structure in which interlayer insulating layers and wiring layers are alternately stacked (also referred to as a multilayer wiring layer) can be employed in the upper portion of the layer 60.

As illustrated in FIG. 5, an insulating layer 47 is provided over the layer 80. That is, the layer 80 is positioned between the insulating layer 45 and the insulating layer 47.

As the insulating layer 45 and the insulating layer 47, the above-described film having a barrier property against hydrogen can be used. Specifically, a silicon nitride film or a silicon nitride oxide film is preferably used.

Furthermore, the insulating layer 45 and the insulating layer 47 preferably have a stacked-layer structure in which the insulating film functioning as the above-described barrier film and the insulating film having a function of capturing or fixing hydrogen on the inner side (the transistor 10 side) are stacked. For example, a hafnium oxide film, a hafnium silicate film, an aluminum oxide film, a hafnium zirconium oxide film, or the like is preferably used.

Thus, diffusion of hydrogen from the outside into the region sandwiched between the insulating layer 45 and the insulating layer 47 can be inhibited. Furthermore, the hydrogen concentration in the region can be reduced. Accordingly, hydrogen that might be diffused into the semiconductor layer 21 of the transistor 10 can be effectively reduced, so that the transistor 10 with high reliability can be achieved.

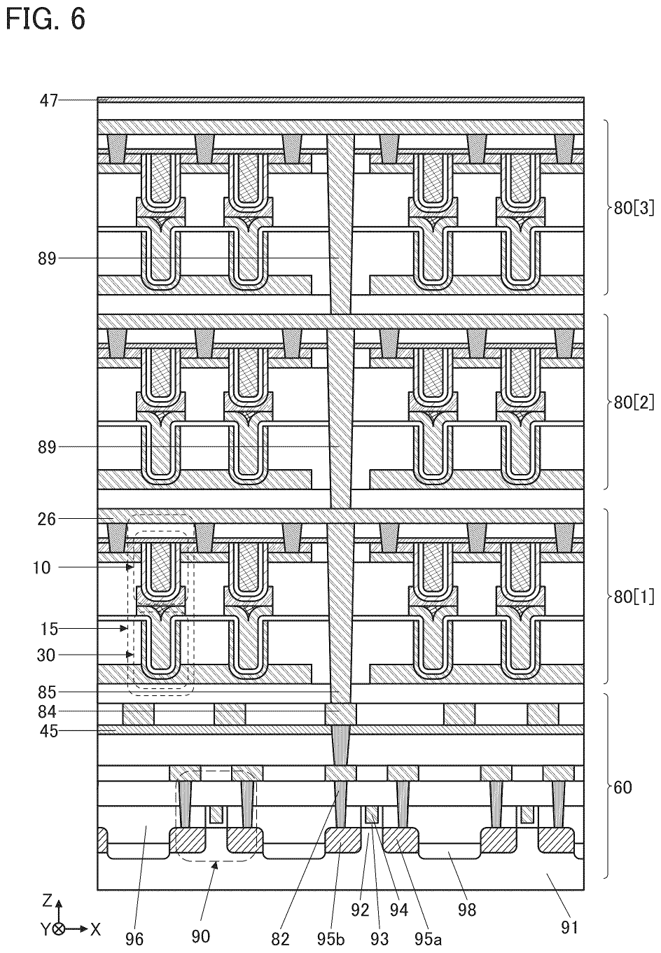

FIG. 6 illustrates an example in which the layers 80 including the memory cells 15 are stacked. Although FIG. 6 illustrates an example in which three of the layers 80 (layers 80[1] to 80[3] from the substrate 91 side) are stacked, the number of layers 80 to be stacked may be two or four or more.

The plug 85 connects the conductive layer 84 to the conductive layer 26 included in the layer 80[1]. Furthermore, a plug 89 connects the conductive layer 26 included in one layer 80 to the conductive layer 26 included in another layer 80. Thus, three of the conductive layers 26 included in the layers 80[1] to 80[3] are connected to the one of the source and the drain of the transistor 90.

The insulating layer 47 is provided over the layer 80[3]. Without limitation to this structure, the insulating layer 47 can be provided for each of the layers 80.

Although the structure in which the layer 80 is stacked directly over the substrate 91 where the transistor 90 is provided is described here, one embodiment of the present invention is not limited thereto. For example, the substrate 91 provided with the transistor 90 and the substrate provided with the memory cell 15 may be bonded to each other. For example, two substrates can be bonded to each other by direct bonding (hybrid bonding) using a direct bonding technique typified by Cu—Cu bonding. Alternatively, a method may be used in which two or more layers are bonded to each other with their insulating surfaces and then a through electrode is formed to connect electrodes or the like provided in the layers to each other. A method using direct bonding or a through electrode is particularly preferably used, in which case the pitch width between the connection electrodes can be extremely narrowed and thus a large number of connection electrodes can be arranged at high density, whereby a larger amount of data can be transmitted between layers.

When two layers are bonded, any of a chip on chip (CoC) bonding, a chip on wafer (CoW) bonding, or a wafer on wafer (WoW) bonding may be used as a bonding method. The WoW bonding bonds wafers to each other and is thus excellent in productivity; however, since the WoW bonding bonds all the chips, including defective and non-defective chips, to each other, the yield is reduced in some cases. Meanwhile, the CoW bonding where a chip is bonded to a wafer and the CoC bonding where chips are bonded to each other are inferior to the WoW bonding in terms of productivity; however, the CoW bonding and the CoC bonding can bond non-defective chips to each other and thus achieve a significantly improved yield. Although the CoC bonding is less productive than the other two bonding methods, the CoC bonding can bond two layers with largely different sizes and thus has high versatility.

Note that a wiring layer such as an interposer may be provided between two layers. Thus, the positions of the bonding electrodes and the like do not need to be aligned between the two adjacent layers, so that the design flexibility of the layers can be increased and a semiconductor device with higher performance can be achieved.

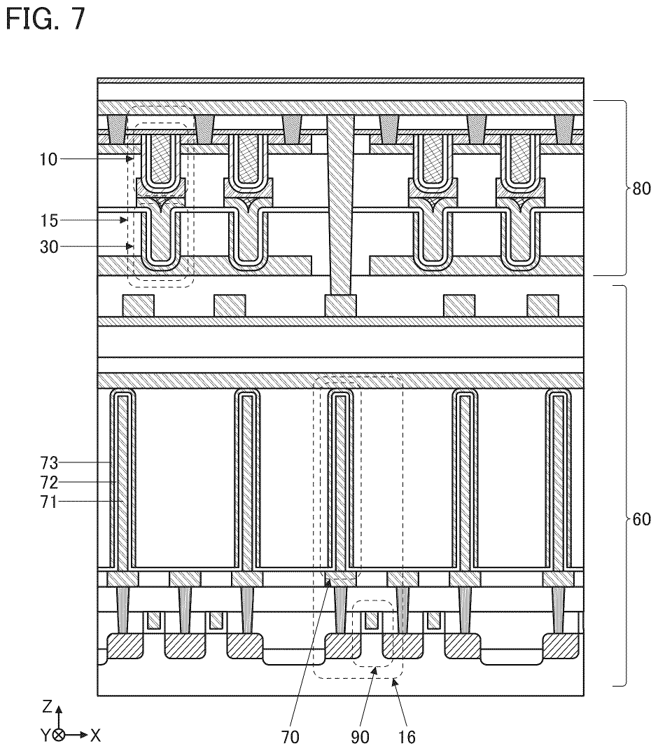

FIG. 7 illustrates an example in which a layer 60 including a memory cell 16 that can be used as a dynamic random access memory (DRAM) is stacked with the layer 80. The memory cell 16 includes the transistor 90 and a capacitor 70.

The one of the source electrode and the drain electrode of the transistor 90 is connected to the bit line, and the other of the source electrode and the drain electrode of the transistor 90 is connected to the capacitor 70. The capacitor 70 includes a conductive layer 71, a conductive layer 73, and an insulating layer 72 sandwiched therebetween. The structure illustrated in FIG. 7 includes the columnar (pillar-shaped) conductive layer 71, and the insulating layer 72 and the conductive layer 73 which are provided to cover the conductive layer 71.

FIG. 7 illustrates an example in which two of the transistors 90 are connected to the same bit line. With such a structure, the memory cells can be arranged at a high density.

Although FIG. 7 illustrates an example in which the layer 80 is stacked directly over the layer 60, the layer 60 and the layer 80 may be formed separately and bonded to each other. In that case, the stacking order of the layer 60 and the layer 80 is not limited, and the layer 60 may be stacked over the layer 80. There is also no limitation on the vertical orientation of the layer 60 and the layer 80. In each of the layer 60 and the layer 80, the substrate side (the formation surface side) may be a bonding surface or the surface opposite to the substrate side may be a bonding surface.

### [Components]

### <Substrate>

As a substrate where a transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, gallium oxide, or gallium nitride. Other examples include the above semiconductor substrate including an insulator region, e.g., a silicon on insulator (SOI) substrate. Examples of the conductor substrate include a graphite substrate, a metal substrate, an alloy substrate, and a conductive resin substrate. Other examples of the conductor substrate include a substrate including a nitride of a metal and a substrate including an oxide of a metal. Moreover, other examples of the conductor substrate include an insulator substrate provided with a conductive layer or a semiconductor layer, a semiconductor substrate provided with a conductive layer or an insulating layer, and a conductor substrate provided with a semiconductor layer or an insulating layer. Alternatively, these substrates provided with elements may be used. Examples of the elements provided over the substrates include a capacitor, a resistor, a switching element (such as a transistor), a light-emitting element, and a memory element.

### <Semiconductor Layer>

The semiconductor layer 21 preferably includes a metal oxide (an oxide semiconductor).

Examples of the metal oxide that can be used for the semiconductor layer 21 include an In oxide, a Ga oxide, and a Zn oxide. The metal oxide preferably contains at least In or Zn. The metal oxide preferably includes two or three elements selected from In, an element M, and Zn. The element M is a metal element or metalloid element that has a high bonding energy with oxygen, such as a metal element or metalloid element whose bonding energy with oxygen is higher than that of In, for example. Specific examples of the element M include Al, Ga, Sn, Y, Ti, V, Cr, Mn, Fc, Co, Ni, Zr, Mo, Hf, Ta, W, La, Ce, Nd, Mg, Ca, Sr, Ba, B, Si, Ge, and Sb. The element M contained in the metal oxide is preferably one or more kinds selected from the above elements. Specifically, the element M is preferably one or more kinds selected from Al, Ga, Y, and Sn, further preferably Ga. Hereinafter, a metal oxide containing In, M, and Zn is referred to as In-M-Zn oxide in some cases. In this specification and the like, a metal element and a metalloid element may be collectively referred to as a “metal element”, and a “metal element” in this specification and the like may refer to a metalloid element.

When the metal oxide is an In-M-Zn oxide, the proportion of the number of In atoms is preferably higher than or equal to that of the number of M atoms in the In-M-Zn oxide. Examples of the atomic ratio of the metal elements of such In-M-Zn oxide include In:M:Zn=1:1:1, In:M:Zn=1:1:1.2, In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, and In:M:Zn=5:2:5 and a composition in the vicinity thereof. Note that the vicinity of the atomic ratio includes ±30% of an intended atomic ratio. By increasing the proportion of the number of In atoms in the metal oxide, the on-state current, field-effect mobility, or the like of the transistor can be improved.

The proportion of the number of In atoms may also be lower than that of the number of element M atoms in the In-M-Zn oxide. Examples of the atomic ratio of the metal elements of such In-M-Zn oxide include In:M:Zn=1:3:2, In:M:Zn=1:3:3, and In:M:Zn=1:3:4 and a composition in the vicinity of any of the above atomic ratios. By increasing the proportion of the number of element M atoms in the metal oxide, generation of oxygen vacancies can be inhibited.

For the semiconductor layer 21, for example, In oxide, In—Zn oxide, In—Ga oxide, In—Sn oxide, In—Ti oxide, In—Ga—Al oxide, In—Ga—Sn oxide, In—Ga—Zn oxide, In—Sn—Zn oxide, In—Al—Zn oxide, In—Ti—Zn oxide, In—Ga—Sn—Zn oxide, or In—Ga—Al—Zn oxide can be used. Alternatively, Ga—Zn oxide may be used. A material that does not contain Zn like indium oxide is preferred in improving the compatibility with an LSI manufacturing process. By contrast, a material that contains Zn is preferred in the easiness of increasing crystallinity.

Instead of indium or in addition to indium, the metal oxide may contain one or more kinds of metal elements whose period number in the periodic table is large. The larger the overlap between orbits of metal elements is, the more likely it is that the metal oxide will have high carrier conductivity. Thus, when a metal element with a large period number is contained in the metal oxide, the field-effect mobility of the transistor can be increased in some cases. Examples of the metal element with a large period number include metal elements belonging to Period 5 and metal elements belonging to Period 6. Specific examples of the metal element include Y, Zr, Ag, Cd, Sn, Sb, Ba, Pb, Bi, La, Ce, Pr, Nd, Pm, Sm, and Eu. Note that La, Ce, Pr, Nd, Pm, Sm, and Eu are referred to as light rare earth elements.

The metal oxide may contain one or more kinds selected from nonmetallic elements. A transistor including the metal oxide including a nonmetallic element can have high field-effect mobility in some cases. Examples of the nonmetallic element include carbon, nitrogen, phosphorus, sulfur, selenium, fluorine, chlorine, bromine, and hydrogen.

For the formation of a metal oxide, a sputtering method or an atomic layer deposition (ALD) method can be suitably used. In particular, a film of the metal oxide is preferably formed by an ALD method, which enables good coverage. Note that in the case where the metal oxide is formed by a sputtering method, the composition of the formed metal oxide film may be different from the composition of a target. In particular, the zinc content percentage of the formed metal oxide film may be reduced to approximately 50% of that of the target.

In this specification and the like, the content of a certain metal element in a metal oxide refers to the proportion of the number of atoms of the metal element to the total number of metal element atoms contained in the metal oxide. In the case where a metal oxide contains a metal element X, a metal element Y, and a metal element Z whose atomic numbers are respectively represented by A_{X}, A_{Y}, and A_{Z}, the content of the metal element X can be represented by A_{X}/(A_{X}+A_{Y}+A_{Z}). Moreover, in the case where the atomic ratio of the metal element X to the metal element Y and the metal element Z contained in the metal oxide is represented by B_{X}:B_{Y}:B_{Z}, the content of the metal element X can be represented by B_{X}/(B_{X}+B_{Y}+B_{Z}).

In the case of using a metal oxide containing In, for example, an increase in the In content enables a transistor to have a high on-state current.

When the semiconductor layer 21 includes a metal oxide not containing Ga or having a low Ga content, a transistor can have high reliability against positive bias application. That is, the transistor can show a small amount of change in the threshold voltage in the positive bias temperature stress (PBTS) test. In the case of using a metal oxide containing Ga, the Ga content is preferably lower than the In content. Accordingly, the transistor can have high mobility and high reliability.

Meanwhile, a transistor having a high Ga content can have high reliability against light. That is, the transistor can show a small amount of change in the threshold voltage of the transistor in the negative bias temperature illumination stress (NBTIS) test. Specifically, a metal oxide in which the proportion of the number of Ga atoms is greater than or equal to that of the number of In atoms has a wider band gap and can reduce the amount of change in the threshold voltage of the transistor in the NBTIS test.

Furthermore, a metal oxide having a high zinc content has high crystallinity whereby diffusion of impurities can be inhibited. Consequently, a change in electrical characteristics of the transistor is suppressed and the transistor can have high reliability.

The semiconductor layer 21 may have a stacked-layer structure including two or more metal oxide layers. The two or more metal oxide layers included in the semiconductor layer 21 may have the same composition or substantially the same compositions. Employing a stacked-layer structure of metal oxide layers having the same composition can reduce the manufacturing cost because the metal oxide layers can be formed using the same sputtering target. Note that a stacked-layer structure including two or more oxide semiconductor layers having different compositions may be employed. The use of an ALD method can form a metal oxide layer with a composition that continuously changes in the thickness direction. This not only increases the range of choices for design without need for use of a film with a predetermined composition but also prevents generation of an interface state or the like between two layers with different compositions; thus, the electrical characteristics and reliability can be improved. A metal oxide layer having a stacked-layer structure may be formed by both a sputtering method and an ALD method.

In the case where the semiconductor layer 21 has a two-layer structure, the second layer, i.e., the layer closer to the gate electrode, preferably includes a material with higher mobility (higher conductivity) than the first layer. This structure enables the transistor to have normally-off characteristics and a high on-state current. Consequently, both low power consumption and high performance can be achieved. Alternatively, the first layer, i.e., the layer in contact with the source electrode and the drain electrode, may include a material having higher mobility than the second layer. In that case, contact resistance between the semiconductor layer 21 and the source electrode or the drain electrode can be reduced and the parasitic resistance can be reduced accordingly, so that the transistor can have a high on-state current.

In the case where the semiconductor layer 21 has a three-layer structure, the second layer preferably includes a material having higher mobility than the first and third layers. This structure enables the transistor with a high on-state current and high reliability.

The above-described differences in the mobility and conductivity can be replaced with a difference in the indium content percentage, for example. In addition, the mobility and the conductivity are affected by whether or not an element that contributes to an improvement in conductivity is contained in addition to indium, by the content of the element, or the like. Examples of the high-mobility material include a material having an atomic ratio of In:Ga:Zn=4:2:3 or in the vicinity thereof, a material having an atomic ratio of In:Zn=1:1 or in the vicinity thereof, a material having an atomic ratio of In:Zn=2:1 or in the vicinity thereof, a material having an atomic ratio of In:Zn=4:1 or in the vicinity thereof, and a material having an atomic ratio of In:Sn:Zn=40:X:10 (X is greater than or equal to 0.1 and less than or equal to 5, typically X=1) or in the vicinity thereof. Examples of a material having lower mobility or conductivity than the above-described materials include a material having an atomic ratio of In:Ga:Zn=1:3:2 or in the vicinity thereof, a material having an atomic ratio of In:Ga:Zn=1:3:4 or in the vicinity thereof, a material having an atomic ratio of In:Ga:Zn=2:2:1 or in the vicinity thereof, a material having an atomic ratio of In:Ga:Zn=1:1:1 or in the vicinity thereof, and a material having an atomic ratio of In:Ga:Zn=1:1:2 or in the vicinity thereof.

It is preferable to use a metal oxide layer having crystallinity as the semiconductor layer 21. For example, a metal oxide layer having a c-axis aligned crystal (CAAC) structure, a polycrystalline structure, a nano-crystal (nc) structure, or the like can be used. By using a metal oxide layer having crystallinity as the semiconductor layer 21, the density of defect states in the semiconductor layer 21 can be reduced, which enables the semiconductor device to have high reliability.

As the crystallinity of the metal oxide layer used as the semiconductor layer 21 becomes higher, the density of defect states in the semiconductor layer 21 can be reduced. By contrast, the use of a metal oxide layer having low crystallinity enables a transistor to flow a high current.

A transistor including an oxide semiconductor (hereinafter referred to as an OS transistor) has much higher field-effect mobility than a transistor including amorphous silicon. In addition, the OS transistor has an extremely low leakage current between a source and a drain in an off state (hereinafter also referred to as an off-state current), and electric charge accumulated in a capacitor that is connected in series to the transistor can be held for a long period. Furthermore, the power consumption of the semiconductor device can be reduced with the OS transistor.

The semiconductor device of one embodiment of the present invention can be used in a processor, a memory device, or any of a variety of ICs, for example. The transistor of one embodiment of the present invention can make a high current flow therethrough and has a feature of an extremely low off-state current; thus, a high-speed operation of a circuit and a reduction in power consumption can be achieved at the same time.

The semiconductor device of one embodiment of the present invention can also be used for a display device, for example. To increase the luminance of a light-emitting device included in a pixel circuit of a display device, it is necessary to increase the amount of current flowing through the light-emitting device. To increase the current amount, the source-drain voltage of a driving transistor included in the pixel circuit needs to be increased. Since an OS transistor has a higher withstand voltage between a source and a drain than a transistor including silicon (hereinafter referred to as a Si transistor), a high voltage can be applied between the source and the drain of the OS transistor. Therefore, when an OS transistor is used as the driving transistor in the pixel circuit, the amount of current flowing through the light-emitting device can be increased, so that the luminance of the light-emitting device can be increased.

When transistors operate in a saturation region, a change in source-drain current relative to a change in gate-source voltage can be smaller in an OS transistor than in a Si transistor. Accordingly, when an OS transistor is used as the driving transistor included in the pixel circuit, the amount of current flowing through the light-emitting device can be precisely controlled. Consequently, the number of gray levels expressed by the pixel circuit can be increased. Moreover, a stable current can flow through the light-emitting device even when the electrical characteristics (e.g., resistance) of the light-emitting device change or the electrical characteristics of the light-emitting devices vary.

As described above, with use of an OS transistor as a driving transistor included in a pixel circuit, it is possible to achieve “inhibition of black floating”, “increase in emission luminance”, “increase in gray level”, “reduction in influence of manufacturing variation in light-emitting devices”, and the like.

A change in electrical characteristics of an OS transistor due to irradiation with radiation is small, that is, an OS transistor has high resistance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

Note that a semiconductor material that can be used for the semiconductor layer 21 is not limited to an oxide semiconductor. For example, a single-element semiconductor or a compound semiconductor can be used. Examples of the single-element semiconductor include silicon (such as single crystal silicon, polycrystalline silicon, microcrystalline silicon, and amorphous silicon) and germanium. Examples of the compound semiconductor include gallium arsenide and silicon germanium. Examples of the compound semiconductor include an organic semiconductor, a nitride semiconductor, and an oxide semiconductor. These semiconductor materials may contain impurities as dopants.

Alternatively, the semiconductor layer 21 may include a layered material functioning as a semiconductor. The layered material generally refers to a group of materials having a layered crystal structure. In the layered crystal structure, layers formed by covalent bonding or ionic bonding are stacked with bonding such as the van der Waals binding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, the transistor can have a high on-state current.

Examples of the layered material include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSc₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSc₂).

There is no particular limitation on the crystallinity of a semiconductor material used for the semiconductor layer 21, and any of an amorphous semiconductor, a single crystal semiconductor, and a semiconductor having crystallinity other than single crystal (a polycrystalline semiconductor, a microcrystalline semiconductor, or a semiconductor partly including crystal regions) may be used. A semiconductor having crystallinity is preferably used, in which case deterioration of transistor characteristics can be suppressed.

### <Gate Insulating Layer>

The insulating layer 22 functions as a gate insulating layer of the transistor. In the case where the semiconductor layer 21 is formed using an oxide semiconductor, an oxide insulating film is preferably used for at least a part of the insulating layer 22 that is in contact with the semiconductor layer 21. For example, one or more of silicon oxide, silicon oxynitride, aluminum oxide, aluminum oxynitride, hafnium oxide, hafnium oxynitride, gallium oxide, gallium oxynitride, yttrium oxide, yttrium oxynitride, and Ga—Zn oxide can be used. In addition, as the insulating layer 22, a nitride insulating film of silicon nitride, silicon nitride oxide, aluminum nitride, or aluminum nitride oxide can also be used. The insulating layer 22 may have a stacked-layer structure, e.g., a stacked-layer structure including at least one oxide insulating film and at least one nitride insulating film.

The insulating layer 22 preferably has a stacked-layer structure including an insulating material that contains a high dielectric constant (high-k) material. A stacked-layer structure including a high-k material and a material with higher dielectric strength than the high-k material is preferably used. For example, as the insulating layer 22, an insulating film (also referred to as ZAZ) in which zirconium oxide, aluminum oxide, and zirconium oxide are stacked in this order can be used. An insulating film (also referred to as ZAZA) in which zirconium oxide, aluminum oxide, zirconium oxide, and aluminum oxide are stacked in this order can be used, for example. For another example, an insulating film in which hafnium zirconium oxide, aluminum oxide, hafnium zirconium oxide, and aluminum oxide are stacked in this order can be used. The stacking of such an insulator having relatively high dielectric strength, such as aluminum oxide, can increase the dielectric strength and inhibit electrostatic breakdown of the capacitor.

Alternatively, a material that exhibits ferroelectricity may be used for the insulating layer 22. Examples of the material that exhibits ferroelectricity include metal oxides such as hafnium oxide, zirconium oxide, and HfZrO_{X} (X is a real number greater than 0). A metal oxide obtained by adding Y (yttrium) to HfZrO_{X} can also be used. When Y is added to HfZrO_{X}, the ferroelectricity can be enhanced.

In the case where the insulating layer 22 has a two-layer structure, an insulating film having a function of capturing or fixing hydrogen is preferably used as a film in contact with the semiconductor layer 21, and an insulating film having a barrier property against hydrogen is preferably used as a film closer to the conductive layer 23 functioning as the gate electrode. This can inhibit diffusion of hydrogen into the semiconductor layer 21 from the conductive layer 23 side, so that the transistor can have high reliability.

As the insulating film that captures or fixes hydrogen, a hafnium oxide film, a hafnium silicate film, an aluminum oxide film, or the like is preferably used. As the insulating film having a barrier property against hydrogen, a silicon nitride film, a silicon nitride oxide film, an aluminum oxide film, a magnesium oxide film, a hafnium oxide film, a gallium oxide film, or the like is preferably used.

Alternatively, an insulating film that releases oxygen by heating may be used as the film in contact with the semiconductor layer 21, and an insulating film having a barrier property against hydrogen may be used as the film positioned on the conductive layer 23 side. Alternatively, an insulating film that releases oxygen by heating may be used as the film in contact with the semiconductor layer 21, and an insulating film having a function of capturing or fixing hydrogen may be used as the film positioned on the conductive layer 23 side.

In the case where the insulating layer 22 has a three-layer structure, it is preferable that an insulating film including a material to which oxygen is easily diffused be used as the film in contact with the semiconductor layer 21, an insulating film having a barrier property against hydrogen and oxygen be used as the film positioned on the conductive layer 23 side, and an insulating film having a function of capturing or fixing hydrogen be used as a film positioned between the film in contact with the semiconductor layer 21 and the film positioned on the conductive layer 23 side. As the material to which oxygen is easily diffused, silicon oxide or silicon oxynitride can be used. With such a structure, oxygen can be supplied from the film in contact with the semiconductor layer 21 to the semiconductor layer 21. The film positioned on the conductive layer 23 side can prevent diffusion of oxygen to the conductive layer 23 side and inhibit oxidation of the conductive layer 23.

As an insulating film having a barrier property against oxygen, an aluminum oxide film, a silicon nitride film, a hafnium oxide film, a hafnium silicate film, or the like is preferably used. As an insulating film having a barrier property against oxygen and hydrogen, an aluminum oxide film, a silicon nitride film, a hafnium oxide film, or the like is preferably used.

In the case where the insulating layer 22 has a four-layer structure, it is preferable that an insulating film having a barrier property against oxygen be used as the film in contact with the semiconductor layer 21, and an insulating film including a material to which oxygen is easily diffused, an insulating film having a function of capturing or fixing hydrogen, and an insulating film having a barrier property against hydrogen and oxygen be provided in this order from the side closer to the semiconductor layer 21. That is, a structure in which the film in contact with the semiconductor layer 21 is added to the above-described three-layer structure can be employed. When an insulating film having a barrier property against oxygen is used as the film in contact with the semiconductor layer 21, release of oxygen from the semiconductor layer 21 can be inhibited. In that case, an aluminum oxide film is suitably used as the film in contact with the semiconductor layer 21. Aluminum oxide has a function of capturing or fixing hydrogen in addition to having a barrier property against oxygen, and thus has an effect of preventing diffusion of hydrogen into the semiconductor layer 21.

In the case where the insulating layer 22 has a stacked-layer structure, each insulating film thereof is preferably a thin film. For example, when the insulating layer 22 has a thickness greater than or equal to 1 nm and less than or equal to 20 nm, preferably greater than or equal to 3 nm and less than or equal to 10 nm, the subthreshold swing value (also referred to as S value) of the transistor can be reduced. The thickness of each insulating layer is preferably greater than or equal to 0.1 nm and less than or equal to 10 nm, further preferably greater than or equal to 0.1 nm and less than or equal to 5 nm, further preferably greater than or equal to 0.5 nm and less than or equal to 5 nm, further preferably greater than or equal to 1 nm and less than 5 nm, further preferably greater than or equal to 1 nm and less than or equal to 3 nm.

As a specific example, a four-layer structure in which an aluminum oxide film, a silicon oxide film, a hafnium oxide film, and a silicon nitride film are stacked in this order from the semiconductor layer 21 side is preferably employed, and their thicknesses are preferably 1 nm, 2 nm, 2 nm, and 1 nm from the semiconductor layer 21 side.

Note that in this specification and the like, the barrier property refers to a property that does not easily allow diffusion of a target substance (also referred to as a property that does not easily allow passage of a target substance, a property with low permeability of a target substance, or a function of inhibiting diffusion of a target substance). Note that hydrogen described as a target substance refers to at least one of a hydrogen atom, a hydrogen molecule, and a substance bonded to hydrogen, such as a water molecule or OH⁻, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom and an oxygen molecule.

Here, a transistor including a metal oxide film can have stable electrical characteristics when surrounded by an insulating film having a function of inhibiting passage of impurities and oxygen. The insulating film having a function of inhibiting passage of impurities and oxygen can have, for example, a single-layer structure or a stacked-layer structure of an insulating film containing one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum. Specifically, as a material for the insulating film having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide or a nitride such as aluminum nitride, silicon nitride oxide, or silicon nitride can be used.

Specifically, as a material of the insulating film having a function of inhibiting passage of oxygen and impurities such as water and hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide can be used. Other examples of the material of the insulating film having a function of inhibiting passage of oxygen and impurities such as water and hydrogen include oxides containing aluminum and hafnium (hafnium aluminate). Other examples of the material of the insulating film having a function of inhibiting passage of oxygen and impurities such as water and hydrogen include nitrides such as aluminum nitride, silicon nitride oxide, and silicon nitride.

Examples of a material for an insulating film having a function of capturing or fixing hydrogen include metal oxides such as an oxide containing hafnium, an oxide containing magnesium, an oxide containing aluminum, and an oxide containing aluminum and hafnium (hafnium aluminate). Furthermore, these metal oxides may further contain zirconium, and an example of such a metal oxide is an oxide containing hafnium and zirconium. Note that in a metal oxide having an amorphous structure, some oxygen atoms have a dangling bond, which allows the metal oxide to have a high property of capturing or fixing hydrogen. Thus, these metal oxides preferably have an amorphous structure. For example, these oxides may have an amorphous structure by containing silicon. For example, an oxide containing hafnium and silicon (hafnium silicate) is preferably used. Note that the metal oxide may partly include one or both of a crystal region and a crystal grain boundary.

### <Conductive Layer>

The conductive layers 24 and 25 are in contact with the semiconductor layer 21. Here, when the semiconductor layer 21 is formed using an oxide semiconductor and a part of the conductive layer 24 or the conductive layer 25 in contact with the semiconductor layer 21 is formed using, for example, a metal that is likely to be oxidized such as aluminum, an insulating oxide (e.g., aluminum oxide) may be formed between the conductive layer 24 or 25 and the semiconductor layer 21, which may inhibit electrical continuity between the conductive layer and the semiconductor layer. Therefore, at least a part of the conductive layer 24 or the conductive layer 25 in contact with the semiconductor layer 21 is preferably formed using a conductive material that is less likely to be oxidized, a conductive material that maintains low electric resistance even when oxidized, or an oxide conductive material.

For a conductive film in contact with the semiconductor layer 21, for example, titanium, tantalum nitride, titanium nitride, a nitride containing titanium and aluminum, a nitride containing tantalum and aluminum, ruthenium, ruthenium oxide, ruthenium nitride, an oxide containing strontium and ruthenium, or an oxide containing lanthanum and nickel is preferably used. These materials are preferable because they are conductive materials that are less likely to be oxidized or materials that maintain the conductivity even when oxidized.

It is also possible to use a conductive oxide such as indium oxide, zinc oxide, In—Sn oxide, In—Zn oxide, In—W oxide, In—W—Zn oxide, In—Ti oxide, In—Ti—Sn oxide, In—Sn—Si oxide, or Ga—Zn oxide. A conductive oxide containing indium is particularly preferable because of its high conductivity. Alternatively, the above-described oxide material such as In—Ga—Zn oxide that can be used for the semiconductor layer 21 can be used for the conductive layer when the carrier concentration is increased.

For each of the conductive layers 24 and 25, any of the following structures can be used: a single-layer structure of the above conductive oxide film, a three-layer structure in which a titanium nitride film, a tungsten film, and a titanium nitride are stacked in this order, a two-layer structure in which a ruthenium film or a ruthenium oxide film is stacked over a tungsten film, a two-layer structure in which a ruthenium film or a ruthenium oxide film is stacked over the above conductive oxide film, a two-layer structure in which the above conductive oxide film is stacked over a ruthenium film or a ruthenium oxide film, or the like, for example.

The conductive layer 23 serves as a gate electrode and can be formed using a variety of conductive materials. The conductive layer 23 can be formed using, for example, a metal element selected from aluminum, chromium, copper, silver, gold, platinum, tantalum, nickel, cobalt, titanium, molybdenum, tungsten, hafnium, vanadium, niobium, manganese, magnesium, zirconium, beryllium, indium, ruthenium, iridium, strontium, lanthanum, and the like; or an alloy containing any of the above metal elements. It is also possible to use a nitride or an oxide of any of the above metals or the alloy. For example, tantalum nitride, titanium nitride, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. Alternatively, a semiconductor having high electric conductivity, typified by polycrystalline silicon containing an impurity element such as phosphorus, or silicide such as nickel silicide may be used.

For the conductive layer 23, the nitride and the oxide that can be used for the conductive layers 24 and 25 may be used.

The conductive layer 23, the conductive layer 24, and the conductive layer 25 also serve as wirings and thus are preferably formed using stacked low-resistance conductive materials. For example, the above-described low-resistance conductive material that can be used for the conductive layer 23 can also be used for the conductive layer 24a1, the conductive layer 24a2, and the conductive layer 25b. The conductive layer 24a2 may be formed using a conductive material that is not easily oxidized, a conductive material that maintains low electric resistance even when oxidized, or an oxide conductive material.

### <Insulating Layer>

The insulating layer 41 can be used as an interlayer insulating film. The insulating layer 41 is preferably formed by a film formation method such as a sputtering method or a plasma CVD method, for example. It is particularly preferable to employ a sputtering method, in which a hydrogen gas does not need to be used as a deposition gas, to form a film having an extremely low hydrogen content. Consequently, supply of hydrogen to the semiconductor layer 21 is inhibited and the electrical characteristics of the transistor 10 can be stabilized.

The insulating layer 41 is in contact with the channel formation region of the semiconductor layer 21 and therefore is preferably formed using an oxide insulating film. In particular, an oxide insulating film that releases oxygen by heating is preferably used. An oxide insulating film that can be used as the gate insulating layer can be used as the insulating layer 41.

Since the insulating layer 41 serves as an interlayer insulating layer, it is preferably formed by a film formation method that enables a higher film formation rate than those of the other insulating layers. For example, a silicon oxide film formed by a plasma CVD method using tetraethyl orthosilicate (TEOS) whose chemical formula is Si(OC₂H₅)₄) (also referred to as a TEOS film) may be used as the insulating layer 41. The productivity can be thus increased.

The insulating layer 11, an insulating layer 42, the insulating layer 44, the insulating layer 46, and the insulating layer 47 each function as an interlayer insulating layer. For the insulating layer 11, the insulating layer 42, the insulating layer 44, the insulating layer 46, and the insulating layer 47, an insulating material that can be used for the insulating layer 41 can be used.

The insulating layer 52 functions as the dielectric of the capacitor 30. An insulating material similar to that of the insulating layer 22 can be used for the insulating layer 52. For example, an insulating material containing a high-k material that can be used for the insulating layer 22 can be used. Furthermore, for example, it is preferable to employ a stacked-layer structure of a high dielectric constant (high-k) material and a material having higher dielectric strength than the high-k material. When the above-described material that exhibits ferroelectricity is used for the insulating layer 52, the capacitor 30 can be a ferroelectric capacitor, which enables a nonvolatile memory device. Note that as the capacitor 30, a resistive random access memory element utilizing a colossal electro resistance (CER) effect can also be used.

The above is the description of the components.

### VARIATION EXAMPLES

A structure example partly different from the above structure examples will be described below. Note that portions similar to those described above are denoted by the same reference numerals as those described above and are not described.

### Variation Example 1

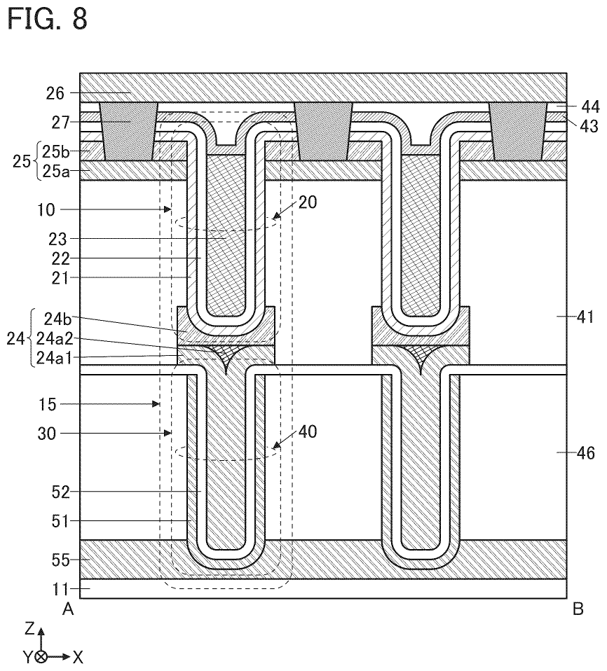

The structure illustrated in FIG. 8 is different from the above structure example mainly in the shapes of the semiconductor layer 21, the insulating layer 22, and the conductive layer 23.

In FIG. 8, the semiconductor layer 21 includes a portion in contact with the top surface of the conductive layer 25b. The insulating layer 22 is provided to cover the semiconductor layer 21 and includes a portion overlapping with the conductive layer 25b with the semiconductor layer 21 therebetween. Thus, in the structure illustrated in FIG. 8, the top surfaces of the semiconductor layer 21 and the insulating layer 22 are not planarized.

The top surface of the conductive layer 23 is positioned lower than the top surface of the conductive layer 25b. Thus, the parasitic capacitance between the conductive layer 23 and the conductive layer 26 and that between the conductive layer 23 and the conductive layer 25 can be reduced. For example, in the case where the upper portion of the conductive layer 23 is removed not by planarization treatment but by etching, the top surface of the conductive layer 23 can be made lower in height by overetching.

Here, when the level of the top surface of the conductive layer 23 is lower than the level of the bottom surface of the conductive layer 25, what is called an offset region, to which a gate electric field is not applied, can be formed in the semiconductor layer 21. Meanwhile, when the level of the top surface of the conductive layer 23 is higher than the level of the bottom surface of the conductive layer 25, an offset region is not formed; thus, a transistor with a high on-state current can be achieved. The level of the top surface of the conductive layer 23 can be adjusted in accordance with characteristics needed for the transistor.

### Variation Example 2

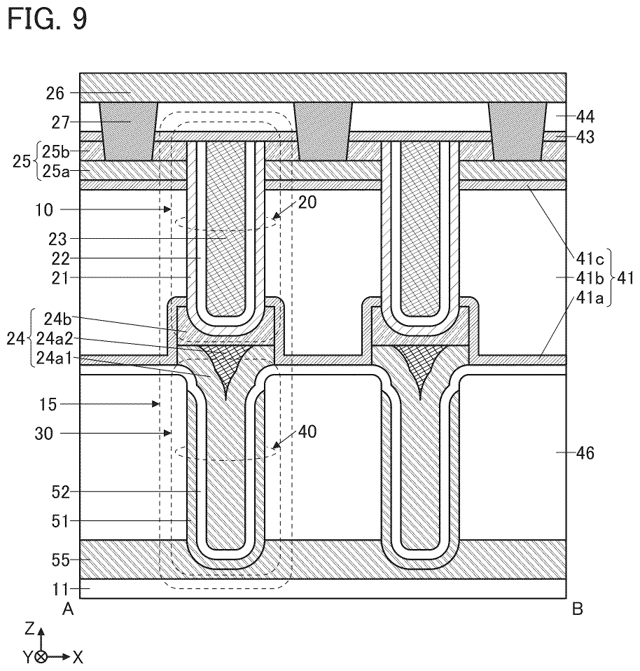

The structure illustrated in FIG. 9 is different from the above structure examples mainly in the shape of the conductive layer 51 included in the capacitor 30 and in that the insulating layer 41 has a stacked-layer structure.

In FIG. 9, an upper end of the conductive layer 51 is positioned below the top surface of the insulating layer 46, and the upper end of the conductive layer 51 and an upper end of the insulating layer 46 are each rounded. When the conductive layer 51 and the insulating layer 46 that form the formation surface of the insulating layer 52 are not provided with corner portions in this manner, coverage with the insulating layer 52 can be improved and the insulating layer 52 can be prevented from being locally thinned. This can reduce a leakage current of the capacitor 30, so that the reliability can be increased.

In the example illustrated in FIG. 9, the insulating layer 41 has a stacked-layer structure in which an insulating layer 41a, an insulating layer 41b, and an insulating layer 41c are stacked in this order from the insulating layer 52 side.

The semiconductor layer 21 is provided in contact with the inner wall of the slit 20 in the insulating layer 41. An oxide insulating film is preferably used as the insulating layer 41b. In particular, an oxide insulating film that releases oxygen by heating is preferably used. Furthermore, the insulating layer 41b is preferably interposed between the insulating layers 41a and 41c having a barrier property against oxygen. This enables oxygen contained in the insulating layer 41b to be enclosed in a region surrounded by the insulating layers 41a and 41c and the semiconductor layer 21. Furthermore, oxygen in the insulating layer 41b can be prevented from decreasing by being released during the process. Accordingly, oxygen can be supplied to the semiconductor layer 21 more efficiently.

A part of the semiconductor layer 21 that is in contact with the insulating layer 41b is a region where oxygen vacancies are reduced, i.e., an i-type region. The other part of the semiconductor layer 21 that is not in contact with the insulating layer 41b is preferably an n-type region including a large amount of carriers. That is, the part of the semiconductor layer 21 that is in contact with the insulating layer 41b can be referred to as a channel formation region and regions of the outer side of the channel formation region can be referred to as low-resistance regions (or a source region or a drain region).

The insulating layer 41b is preferably a film that includes as little hydrogen as possible because the insulating layer 41b is in contact with the semiconductor layer 21. Bonding of oxygen vacancies in the semiconductor layer 21 and hydrogen causes generation of carriers, which might affect the threshold voltage of the transistor 10, for example. Thus, the insulating layer 41b may be an insulating film which does not easily allow diffusion of hydrogen other than an oxide insulating film. For example, a single layer of an insulating film having a barrier property against hydrogen and oxygen can be used as the insulating layer 41.

Since the semiconductor layer 21 and the insulating layer 22 are formed along the inner wall of the slit 20 in the insulating layer 41, the thicknesses of the semiconductor layer 21 and the insulating layer 22 are sometimes reduced in the slit 20 depending on the film formation method. For example, when a film formation method such as a sputtering method or a plasma CVD method is used, a film formed on a surface inclined with respect to the substrate surface or a surface perpendicular to the substrate surface tends to be thinner than a film formed on a surface parallel to the substrate surface. By contrast, a film formation method such as an atomic layer deposition (ALD) method or a thermal CVD method allows a film with a uniform thickness to be formed on a surface with any angle. The semiconductor layer 21 and the insulating layer 22 are preferably formed by an ALD method when the angle formed between a side wall of the slit 20 in the insulating layer 41 and the substrate surface is 75° or more, 80° or more, or 85° or more, for example.

The insulating layer 41b can be used as an interlayer insulating film. The insulating layer 41b is preferably formed by a film formation method such as a sputtering method or a plasma CVD method, for example. It is particularly preferable to employ a sputtering method, in which a hydrogen gas does not need to be used as a deposition gas, to form a film having an extremely low hydrogen content. Consequently, supply of hydrogen to the semiconductor layer 21 is inhibited and the electrical characteristics of the transistor 10 can be stabilized.

The insulating layer 41b is in contact with the channel formation region of the semiconductor layer 21 and therefore is preferably formed using an oxide insulating film. In particular, an oxide insulating film that releases oxygen by heating is preferably used. An oxide insulating film that can be used as the gate insulating layer can be used as the insulating layer 41b.

Since the insulating layer 41b serves as an interlayer insulating layer, it is preferably formed by a film formation method that enables a higher film formation rate than those of the other insulating layers. For example, an insulating film formed by a plasma CVD method using tetraethyl orthosilicate (TEOS) whose chemical formula is Si(OC₂H₅)₄ may be used as the insulating layer 41. The productivity can be thus increased.

As the insulating layers 41a and 41c, films which do not easily allow diffusion of hydrogen are preferably used. The layers 41a and 41c which do not easily allow diffusion of hydrogen are provided above and below the insulating layer 41b, respectively, thereby preventing entry of hydrogen from the outside into the insulating layer 41b in contact with the semiconductor layer 21.

For the insulating layer 41a and the insulating layer 41c, for example, one or more of silicon nitride, silicon nitride oxide, silicon oxynitride, aluminum oxide, aluminum oxynitride, aluminum nitride, hafnium oxide, and hafnium aluminate can be used. Silicon nitride and silicon nitride oxide are particularly suitable for the insulating layer 41a and the insulating layer 41c because they release fewer impurities (e.g., water and hydrogen) and are less likely to transmit oxygen and hydrogen.

### Variation Example 3

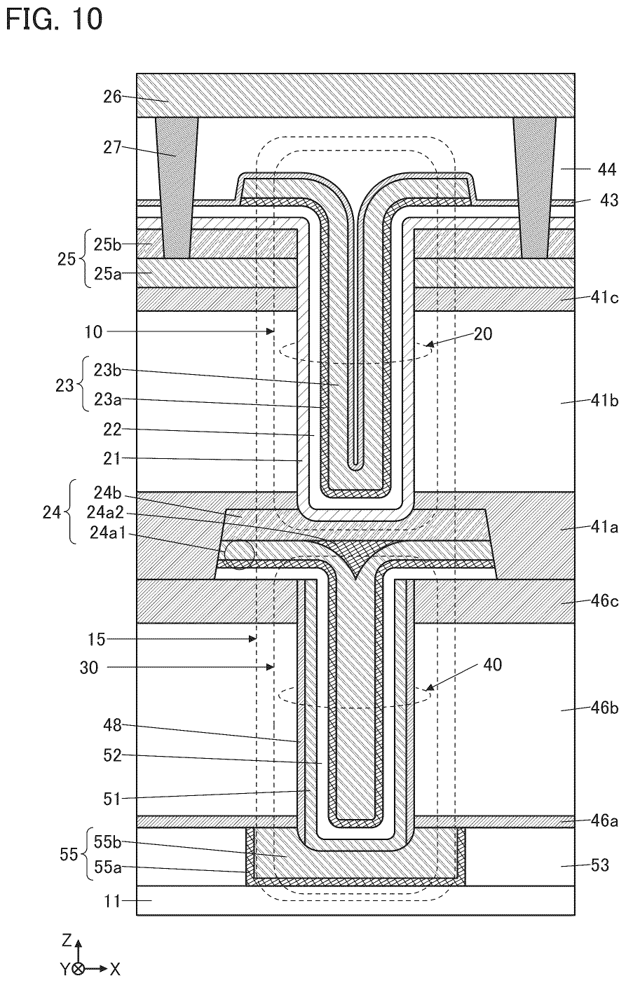

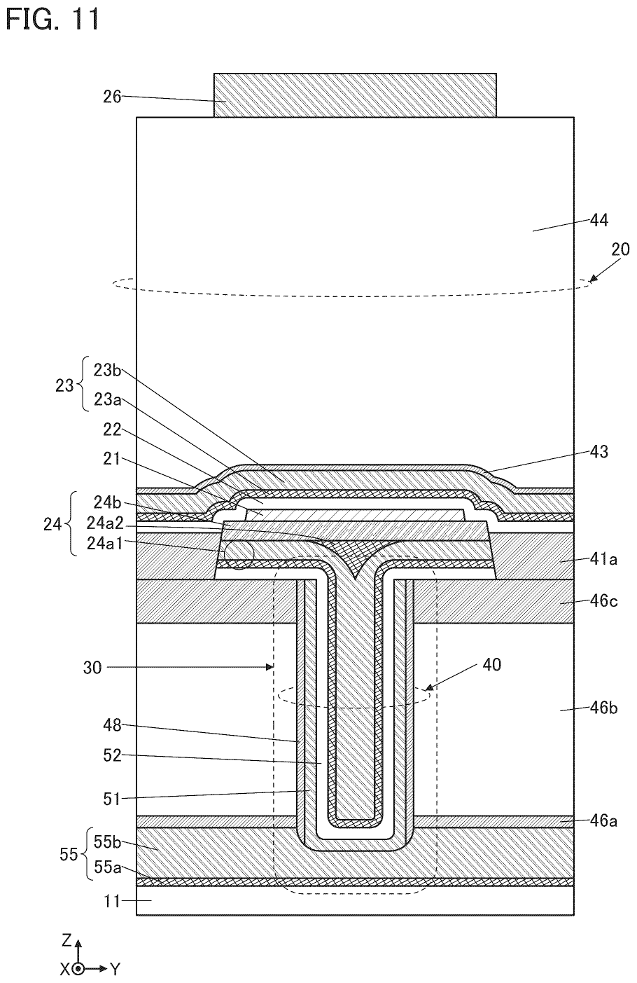

Alternatively, the memory cell 15 may have a structure illustrated in FIG. 10 and FIG. 11.

As illustrated in FIG. 10 and FIG. 11, the conductive layer 55 may have a stacked-layer structure of a conductive layer 55a and a conductive layer 55b over the conductive layer 55a. The conductive layer 55a is provided along an opening in an insulating layer 53, and the conductive layer 55b is provided to fill a depression portion of the conductive layer 55a. For the conductive layer 55a, a conductive material that is not easily oxidized or a conductive material that maintains low electric resistance even when oxidized, which can be used for the conductive layer 24a2 or the like, can be used. For the conductive layer 55b, a low-resistance conductive material that can be used for the conductive layer 24a1 or the like can be used.

Furthermore, as illustrated in FIG. 10 and FIG. 11, the conductive layer 55 can be provided to extend in the Y direction so as to function as a wiring.

As illustrated in FIG. 10 and FIG. 11, the insulating layer 46 may have a stacked-layer structure of an insulating layer 46a, an insulating layer 46b over the insulating layer 46a, and an insulating layer 46c over the insulating layer 46b. The insulating layer 46a, the insulating layer 46b, and the insulating layer 46c can be formed using materials similar to those of the insulating layer 41a, the insulating layer 41b, and the insulating layer 41c, respectively, and can have structures similar to those of the insulating layer 41a, the insulating layer 41b, and the insulating layer 41c, respectively. In addition, a sidewall-shaped insulating layer 48 can be provided in contact with a sidewall of the opening 40. For the insulating layer 48, a material similar to those of the insulating layer 41a and the insulating layer 41c can be used. When a film into which hydrogen is not easily diffused is used as each of the insulating layer 41a, the insulating layer 41c, and the insulating layer 48 in this manner, hydrogen contained in the insulating layer 41b can be prevented from being diffused into the semiconductor layer 21 through the capacitor 30.

As illustrated in FIG. 10 and FIG. 11, the conductive layer 24a1 can have a stacked-layer structure. For the conductive layer 24a1, a conductive material that is not easily oxidized or a conductive material that maintains low electric resistance even when oxidized is preferably used for the lower layer, and a conductive material with low resistance is preferably used for the upper layer. For example, the conductive layer 24a1 can have a stacked-layer structure of a titanium nitride film and a tungsten film over the titanium nitride film.

As illustrated in FIG. 10 and FIG. 11, the conductive layer 24b, the conductive layer 24a1, and the insulating layer 52 may have substantially the same top surface shapes. Here, the side surface of the conductive layer 24b, the side surface of the conductive layer 24a1, and the side surface of the insulating layer 52 are preferably aligned. That is, the conductive layer 24b, the conductive layer 24a1, and the insulating layer 52 are preferably etched using the same mask pattern. In providing the plug 85 to penetrate a plurality of interlayer films as illustrated in FIG. 5, the insulating layer 52 makes the degree of etching difficulty high in some cases. By contrast, when the insulating layer 52 is formed into an island shape as described above, the insulating layer 52 does not need to be etched in providing the plug 85. Accordingly, the productivity of a semiconductor device can be improved.

As illustrated in FIG. 10 and FIG. 11, the insulating layer 41a can be provided to have a flat top surface. In this case, the insulating layer 41a is formed so as to fill a region not overlapping with the conductive layer 24, and the top surface of the insulating layer 41a is planarized by CMP treatment. With this structure, the structure above the insulating layer 41a is not affected by a step caused by the structure of the conductive layer 24; thus, the productivity of the semiconductor device can be improved. In this case, as illustrated in FIG. 10 and FIG. 11, the thickness of the insulating layer 41a is larger in a region overlapping with the insulating layer 46 than in a region overlapping with the conductive layer 24.

As illustrated in FIG. 10 and FIG. 11, part of the semiconductor layer 21, part of the insulating layer 22, and part of the conductive layer 23 can be positioned over the conductive layer 25. In this case, the semiconductor layer 21 and the insulating layer 22 can be provided to overlap with the conductive layer 25. As illustrated in FIG. 11, it is preferable that the semiconductor layer 21 be provided over and in contact with the conductive layer 24b and not extend beyond the edge of the conductive layer 24b. This can prevent oxygen in the semiconductor layer 21 from being extracted to the insulating layer 41a owing to the contact between the semiconductor layer 21 and the insulating layer 41a. However, without limitation to this structure, a structure in which the semiconductor layer 21 covers the conductive layer 24b and is in contact with the top surface of the insulating layer 41a can be employed.

As illustrated in FIG. 10, it is preferable that a portion of the conductive layer 23 positioned above the conductive layer 25 be made smaller than a portion of the semiconductor layer 21 above the conductive layer 25 so that a region where the conductive layer 23 overlaps with the top surface of the conductive layer 25 can be small. With this structure, the parasitic capacitance between the conductive layer 23 and the conductive layer 25 can be reduced. As illustrated in FIG. 10, a depression portion is formed in the center portion of the conductive layer 23b, and the insulating layer 43 and the insulating layer 44 are formed also in the depression portion in some cases. Alternatively, only the insulating layer 43 is formed in the depression portion in some cases.

As illustrated in FIG. 10 and FIG. 11, the conductive layer 23 can have a stacked-layer structure of a conductive layer 23a and a conductive layer 23b over the conductive layer 23a. For the conductive layer 23a, a conductive material that is not easily oxidized or a conductive material that maintains low electric resistance even when oxidized, which can be used for the conductive layer 24a2 or the like, can be used. For the conductive layer 23b, a low-resistance conductive material that can be used for the conductive layer 24a1 or the like can be used.

### Variation Example 4

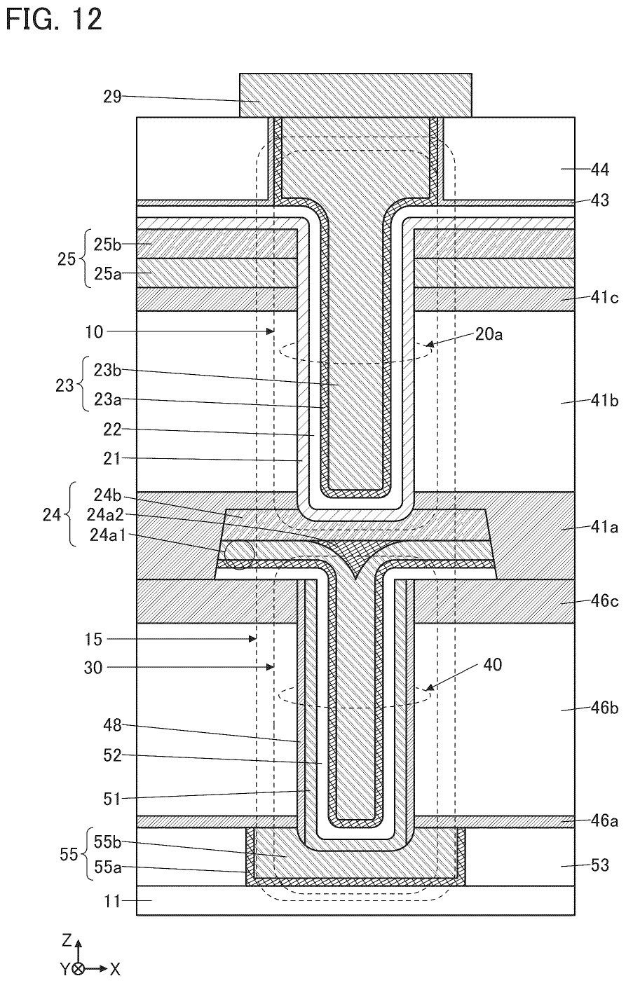

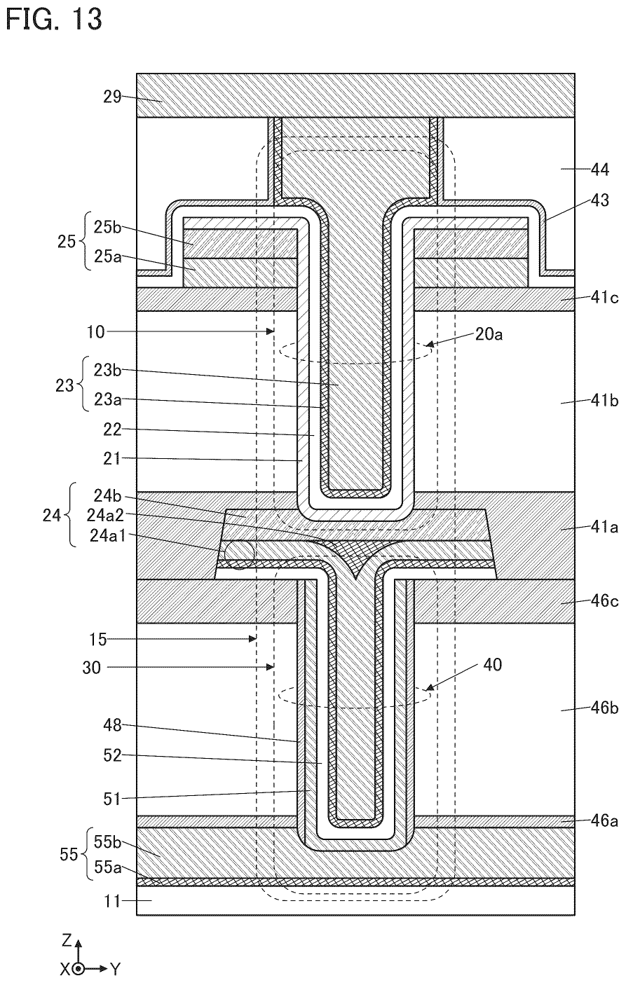

Although FIG. 2 and the like illustrate a structure in which a plurality of transistors 10 are arranged in the slit 20 extending in the Y direction, the present invention is not limited thereto. For example, as illustrated in FIG. 12 and FIG. 13, an opening 20a can be provided in the insulating layer 41 and one transistor 10 can be provided in the opening 20a.

The opening 20a is formed in the insulating layer 41 and the conductive layer 25. Like the opening 40, the opening 20a preferably has a vertical hole shape with a high aspect ratio. A plurality of the openings 20a are preferably provided in the Y direction. With this structure, a plurality of the transistors 10 can be provided in the Y direction as in the structure illustrated in FIG. 2.

As illustrated in FIG. 12 and FIG. 13, the conductive layer 25 is not divided by the opening 20a. That is, the conductive layer 25 extends in the X direction and functions as a bit line.

As illustrated in FIG. 12 and FIG. 13, the semiconductor layer 21 can also be provided to extend in the X direction. The semiconductor layer 21 is provided over the conductive layer 25 and along the opening 20a in the opening 20a. In the structure illustrated in FIG. 2 and the like, the semiconductor layer 21 is processed into an island shape in the slit 20 for isolation from the semiconductor layer 21 of the adjacent transistor 10. In contrast, in the structures illustrated in FIG. 12 and FIG. 13, the semiconductor layer 21 can be processed outside the opening 20a; thus, high-accuracy processing is not necessary. Accordingly, the productivity of a semiconductor device can be improved.

As illustrated in FIG. 13, the insulating layer 22 can be formed to cover the outer side surface of the semiconductor layer 21 and the outer side surface of the conductive layer 25.

As illustrated in FIG. 12 and FIG. 13, an upper portion of the conductive layer 23 may be positioned in an opening provided in the insulating layer 44, and the top surface of the insulating layer 44 may be aligned with the top surface of the conductive layer 23. Part of the insulating layer 43 may be provided between the insulating layer 44 and the conductive layer 23. A conductive layer 29 is preferably provided over the conductive layer 23 and the insulating layer 44. The conductive layer 29 is provided to extend in the Y direction and is connected to the conductive layer 23. That is, the conductive layer 29 functions as a word line. For the conductive layer 29, the same material that is used in the conductive layer 26 can be used.

By providing the conductive layer 29 as described above, the distance between the conductive layer 29 and the conductive layer 25 can be increased, so that the parasitic capacitance between the conductive layer 29 and the conductive layer 25 can be reduced. When the conductive layer 23 is provided as described above, the area where the conductive layer 23 and the conductive layer 25 overlap with each other can be reduced, so that the parasitic capacitance between the conductive layer 23 and the conductive layer 25 can be reduced.

The above is the description of the variation examples.

### Manufacturing Method Example

An example of a method for manufacturing a semiconductor device of one embodiment of the present is described below. Here, the semiconductor device including the memory cell 15 described in the above structure example is described as an example.

Note that thin films included in the semiconductor device (e.g., insulating films, semiconductor films, and conductive films) can be formed by a sputtering method, a chemical vapor deposition (CVD) method, a vacuum evaporation method, a pulsed laser deposition (PLD) method, an atomic layer deposition (ALD) method, or the like.

Alternatively, the thin films included in the semiconductor device (e.g., an insulating film, a semiconductor film, and a conductive film) can be formed by a method such as spin coating, dipping, spray coating, inkjet printing, dispensing, screen printing, or offset printing or with a doctor knife, a slit coater, a roll coater, a curtain coater, or a knife coater.

Examples of the sputtering method include an RF sputtering method using a high-frequency power source for a sputtering power source, a DC sputtering method using a DC power source, and a pulsed DC sputtering method in which a voltage applied to an electrode is changed in a pulsed manner. For film formation using an insulating target, an RF sputtering method is preferably used. A DC sputtering method is used mainly in the case of film formation using a conductive target. In a DC sputtering method, not only formation of a conductive film but also formation of an insulating film is possible by reactive sputtering using a pulsed DC sputtering method. The pulsed DC sputtering method can be specifically used for forming a film of a compound such as an oxide, a nitride, or a carbide by a reactive sputtering method.

CVD methods can be classified into a plasma enhanced CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method according to a source gas.

A high-quality film can be obtained at a relatively low temperature through a plasma CVD method. A thermal CVD method does not use plasma and thus causes less plasma damage to an object. A thermal CVD method yields a film with few defects because of no plasma damage during film formation.

As an ALD method, a thermal ALD method, in which a precursor and a reactant react with each other only by thermal energy, a PEALD method, in which a reactant excited by plasma is used, or the like can be used.

Unlike a sputtering method, a CVD method and an ALD method are less likely to be influenced by the shape of an object to be processed and thus enable favorable step coverage. In particular, an ALD method allows excellent step coverage and excellent thickness uniformity and can be suitably used to cover a surface of an opening portion with a high aspect ratio, for example. Note that an ALD method has a relatively low film formation rate; hence, in some cases, an ALD method is preferably combined with another film formation method with a high film formation rate, such as a CVD method.

By a CVD method, a film with a certain composition can be formed by adjusting the flow rate ratio of the source gases. For example, a CVD method enables formation of a film whose composition is gradually changed by changing the flow rate ratio of the source gases during film formation. In the case where a film is formed while the flow rate ratio of the source gases is changed, as compared with the case where a film is formed using a plurality of film formation chambers, the time taken for the film formation can be shortened because the time taken for transfer or pressure adjustment is not required. Hence, the productivity of the semiconductor device can be improved in some cases.

An ALD method, in which a plurality of different kinds of precursors are introduced at a time, enables formation of a film with a desired composition. In the case where a plurality of different kinds of precursors are introduced, the number of cycles for each precursor is controlled, whereby a film with a desired composition can be formed. Furthermore, a film whose composition is continuously changed can be formed as in the CVD method.

Thin films included in the semiconductor device can be formed by a photolithography method or the like. Besides, a nanoimprinting method, a sandblasting method, a lift-off method, or the like may be employed to process the thin films. Alternatively, island-shaped thin films may be directly formed by a film formation method using a shielding mask such as a metal mask.

There are two typical examples of photolithography methods. In one of the methods, a resist mask is formed over a thin film to be processed, the thin film is processed by etching or the like, and then the resist mask is removed. In the other method, a photosensitive thin film is formed and then processed into a desired shape by light exposure and development.

As light for exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Instead of the light for exposure, an electron beam can be used. EUV, X-rays, or an electron beam is preferably used to enable extremely minute processing. Note that a photomask is not needed when exposure is performed by scanning with a beam such as an electron beam.

For etching of thin films, a dry etching method, a wet etching method, a sandblast method, or the like can be used.

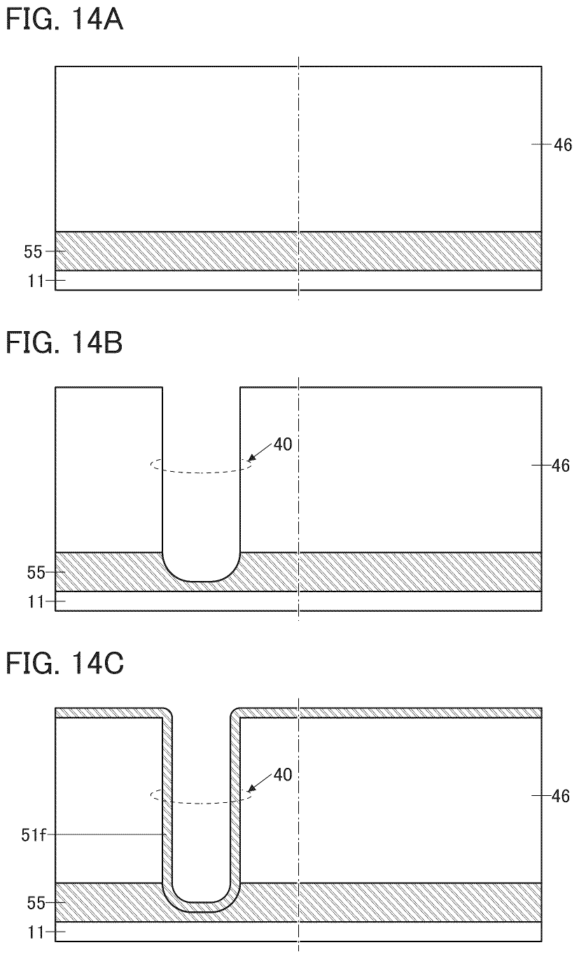

FIG. 14A to FIG. 21B are schematic cross-sectional views corresponding to steps of the manufacturing method example described below. Each drawing illustrates a cross section corresponding to FIG. 2 on the left side of the dashed-dotted line, and a cross section corresponding to FIG. 3 on the right side.

First, a substrate (not illustrated) is prepared, and the insulating layer 11 is formed over the substrate.

As the substrate, a substrate that has heat resistance high enough to withstand at least heat treatment performed later can be used.

An inorganic insulating film such as a silicon oxide film or a silicon oxynitride film can be used as the insulating layer 11. The insulating layer 11 can be formed by a sputtering method, a CVD method, an MBE method, a PLD method, an ALD method, or the like. In the case where the formation surface of the insulating layer 11 is not flat, planarization treatment may be performed after the formation of the insulating layer 11 so that the insulating layer 11 has a flat top surface.

Next, a conductive film to be the conductive layer 55 is formed over the insulating layer 11. The conductive film can be formed by a film formation method such as a sputtering method, an ALD method, or a CVD method. Next, a resist mask is formed over the conductive film, and an unnecessary portion of the conductive film is removed by etching, whereby the conductive layer 55 is formed. The conductive layer 55 can have a plate-like shape, a line-like shape, or a lattice-like shape.

Next, an insulating film may be formed to cover the conductive layer 55, and then planarization treatment may be performed until the top surface of the conductive layer 55 is exposed. Thus, the conductive layer 55 can be embedded in an insulating layer (not illustrated). Although an example in which the insulating layer (not illustrated) is formed after the formation of the conductive layer 55 is described here, the conductive layer 55 and the insulating layer may be formed in the following manner: an insulating film is formed, an opening (or a depression portion) for embedding the conductive layer 55 is formed in the insulating film, a conductive film to be the conductive layer 55 is formed, and planarization treatment is performed until the surface of the insulating film is exposed. For the planarization treatment, a chemical mechanical polishing (CMP) method, a dry etching method, or the like can be used, for example.

Next, the insulating layer 46 is formed over the conductive layer 55 (FIG. 14A). The insulating layer 46 can be formed by a film formation method such as a sputtering method, an ALD method, or a CVD method.

Note that in the case where the conductive layer 55 is not embedded in the insulating layer which is not illustrated, the top surface of the insulating layer 46 after its formation can have an unevenness reflecting the shape of the conductive layer 55. In that case, planarization treatment is preferably performed on the top surface of the insulating layer 46.

Next, the opening 40 reaching the conductive layer 55 is formed in the insulating layer 46 (FIG. 14B). At this time, part of the top surface of the conductive layer 55 is etched in some cases. Etching is preferably performed such that a curved surface is formed at the upper portion of the conductive layer 55.

Next, a conductive film 51f to be the conductive layer 51 is formed to cover the top surface of the insulating layer 46, the side surface of the insulating layer 46 in the opening 40, and the top surface of the conductive layer 55 in the opening 40 (FIG. 14C). The conductive film 51f can be formed by a CVD method, an ALD method, a sputtering method, or the like. In terms of coverage, the conductive film 51f is particularly preferably formed by a CVD method.

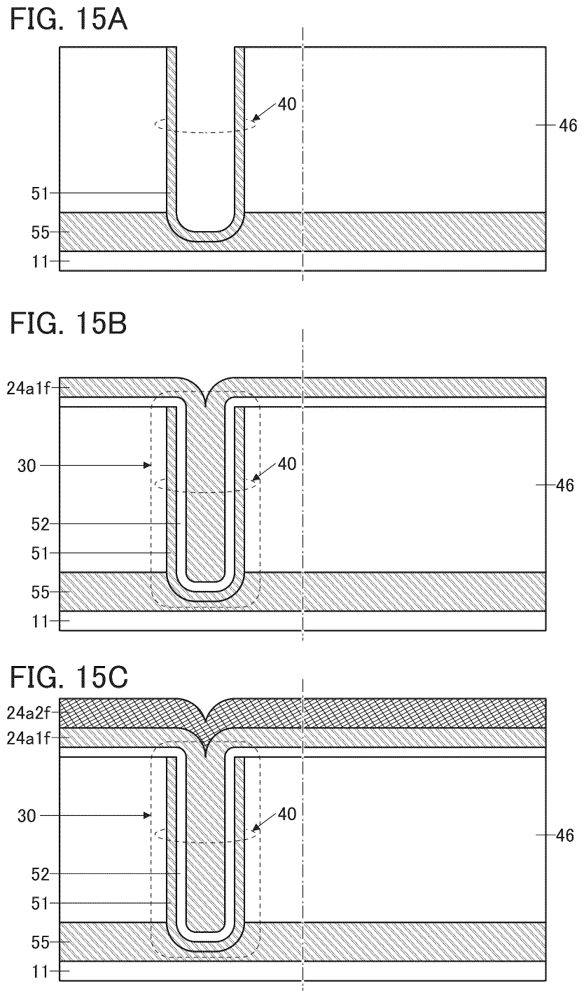

A sacrificial layer is formed over the conductive film to cover the depression portion in the opening 40, planarization treatment is performed until the top surface of the insulating layer 46 is exposed, and the sacrificial layer is removed, whereby the conductive layer 51 positioned only inside the opening 40 can be formed (FIG. 15A).

Here, at the time of planarization treatment or removal of the sacrificial layer, the level of the top surface of the conductive layer 51 is lower than the level of the top surface of the insulating layer 46 in some cases. In addition, the edges of the upper end portion of the conductive layer 51 and the upper end portion of the insulating layer 46 in the opening 40 are removed and rounded in some cases. Thus, the structure illustrated in FIG. 9 can be obtained.

Next, the insulating layer 52 is formed along the surfaces of the insulating layer 46 and the conductive layer 51. The insulating layer 52 can be formed by a film formation method such as a sputtering method, an ALD method, or a CVD method; an ALD method is preferable in terms of coverage. Next, a conductive film 24a1f to be the conductive layer 24a1 is formed over the insulating layer 52 to fill the depression portion in the opening 40 of the insulating layer 46 (FIG. 15B). The conductive film 24a1f can be formed by a film formation method such as a sputtering method, an ALD method, or a CVD method. The conductive film 24a1f is preferably formed by a CVD method with high embeddability (a metal CVD method). With such a method, the conductive film 24a1f can be formed to be embedded in the opening 40 having a high aspect ratio.

Next, a conductive film 24a2f to be the conductive layer 24a2 is formed over the conductive film 24a1f (FIG. 15C). The conductive film 24a2f can be formed by a film formation method such as a sputtering method, an ALD method, or a CVD method. As described above, a conductive film having a function of inhibiting oxidation of the conductive film 24a1f, such as a conductive nitride, is preferably used as the conductive film 24a2f. The conductive film 24a2f is preferably embedded in a depression portion formed on the top surface of the conductive film 24a1f at a position overlapping with the opening 40. The depression portion on the top surface of the conductive film 24a1f is shallower than the opening 40; thus, the conductive film 24a2f is preferably formed by a CVD method (metal CVD method) or an ALD method. In the case where a metal CVD method or the like is used to form the conductive film 24a1f, the top surface of the conductive film 24a1f may become more uneven to have lower planarity. Also in that case, unevenness on the top surface of the conductive film 24a1f can be filled with the conductive film 24a2f.

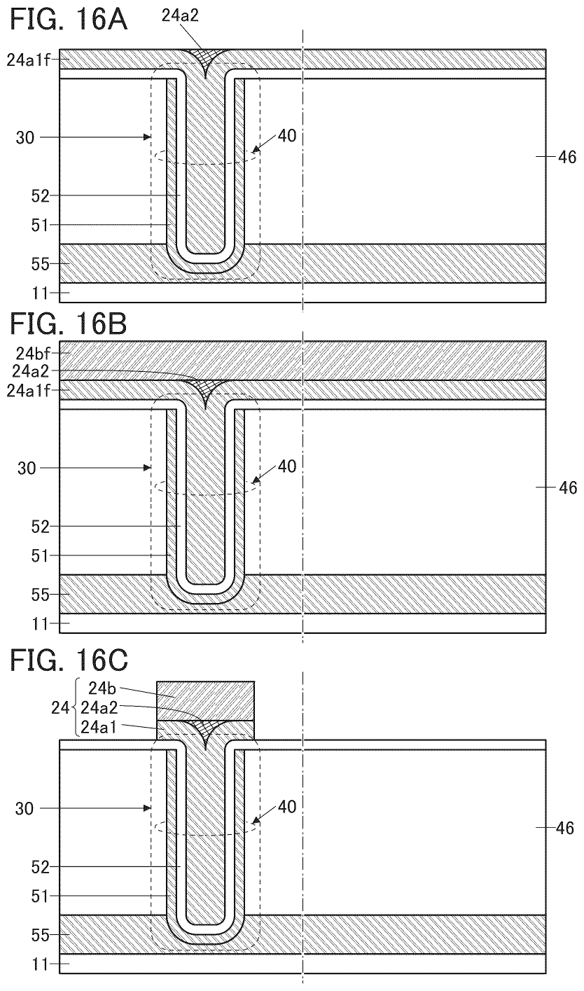

Next, CMP treatment is performed until at least part of the top surface of the conductive film 24a1f is exposed (FIG. 16A). Consequently, part of the conductive film 24a2f remains in the depression portion on the top surface of the conductive film 24a1f, so that the conductive layer 24a2 is formed. As illustrated in FIG. 16A, after the CMP treatment, the top surface of the conductive film 24a1f and the top surface of the conductive layer 24a2 have high planarity. The top surface of the conductive film 24a1f and the top surface of the conductive layer 24a2 are substantially level with each other.

Next, a conductive film 24bf to be the conductive layer 24b is formed over the conductive film 24a1f and the conductive layer 24a2 (FIG. 16B). The conductive film 24bf can be formed by a film formation method such as a sputtering method, an ALD method, or a CVD method. As described above, since the top surface of the conductive film 24a1f and the top surface of the conductive layer 24a2, i.e., the surface where the conductive film 24bf is formed has high planarity, the conductive film 24bf can have high planarity.

Next, a resist mask is formed over the conductive film 24bf and unnecessary portions of the conductive films are removed by etching, whereby the conductive layer 24 including the conductive layer 24a1, the conductive layer 24a2, and the conductive layer 24b is formed (FIG. 16C). At this time, the capacitor 30 is completed. Here, the bottom surface of the conductive layer 24b is preferably in contact with the top surface of the conductive layer 24a1 and the top surface of the conductive layer 24a2. When the conductive layer 24b is in contact with the conductive layer 24a1 having lower electric resistance in this manner, the conductivity can be improved.

In the case where the capacitor 30 illustrated in FIG. 10 and FIG. 11 is formed, the insulating layer 52 is also formed into an island shape in accordance with the conductive layer 24. When the insulating layer 52 is formed into an island shape here, the insulating layer 52 can be prevented from being excessively widened. Although a high-k material is preferably used for the insulating layer 52 as described above, such a material is a difficult-to-etch material in some cases. In providing the plug 85 to penetrate a plurality of interlayer films as illustrated in FIG. 5, the insulating layer 52 makes the degree of etching difficulty high. By contrast, in the case where the insulating layer 52 is formed into an island shape as described above, the insulating layer 52 does not need to be etched in providing the plug 85. Accordingly, the productivity of a semiconductor device can be improved. In addition, when the insulating layer 52 and the conductive layer 24 are collectively etched using the same mask pattern, the productivity of the semiconductor device can be improved.

Next, the insulating layer 41 is formed to cover the conductive layer 24, and planarization treatment is performed on the top surface of the insulating layer 41. The insulating layer 41 can be formed by a film formation method such as a sputtering method, an ALD method, or a CVD method.

The insulating layer 41 is preferably an oxide film including such a large amount of oxygen as to release oxygen by heating and including a small amount of hydrogen. The insulating layer 41 can be formed by a film formation method such as a PECVD method, a sputtering method, or an ALD method, and is particularly preferably formed by a sputtering method. In particular, when a gas containing not hydrogen but oxygen is used as a deposition gas, an insulating film including an extremely small amount of hydrogen and an excess amount of oxygen can be formed. When the insulating layer 41 is formed in this manner, oxygen can be supplied to the channel formation region of the semiconductor layer 21 from the insulating layer 41, so that oxygen vacancies can be reduced.

Next, heat treatment may be performed. The heat treatment is preferably performed at a temperature higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in a nitrogen gas atmosphere, an inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is preferably approximately 20%. The heat treatment may be performed under reduced pressure. Alternatively, the heat treatment may be performed in such a manner that heat treatment is performed in a nitrogen gas atmosphere or an inert gas atmosphere, and then another heat treatment is performed in an atmosphere containing an oxidizing gas at 10 ppm or more, 1% or more, or 10% or more in order to compensate for released oxygen. By the above-described heat treatment, impurities such as water and hydrogen included in the insulating layer 41, for example, can be reduced before an oxide semiconductor film to be the semiconductor layer is formed.

The gas used in the above heat treatment is preferably highly purified. For example, the amount of moisture contained in the gas used in the above-described heat treatment is preferably 1 ppb (0.001 ppm) or less, preferably 0.1 ppb or less, and further preferably 0.05 ppb or less. The heat treatment using a highly purified gas can prevent the entry of moisture or the like into the insulating layer 41 or the like as much as possible.

After the formation of the insulating layer 41, treatment for supplying oxygen to the insulating layer 41 may be performed. Accordingly, oxygen can be supplied from the insulating layer 41 to a semiconductor film 21f by heat applied after the formation of the semiconductor film 21f later, or the like.

Examples of the treatment for supplying oxygen include heat treatment in an oxygen-containing atmosphere, plasma treatment in an oxygen-containing atmosphere (including microwave plasma), and the like. Alternatively, an oxide film (preferably a metal oxide film) may be formed by a sputtering method in an oxygen-containing atmosphere to supply oxygen to the insulating layer. The formed oxide film may be removed immediately or left as it is. Note that examples of the atmosphere containing oxygen include not only an atmosphere containing an oxygen gas (O₂) but also an atmosphere containing a gas of a compound containing oxygen, such as ozone (O₃) or dinitrogen monoxide (N₂O).

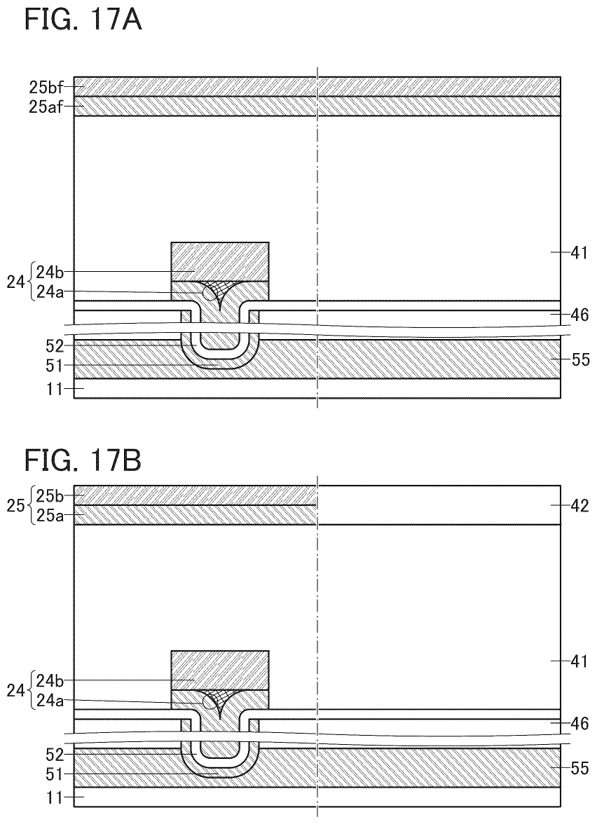

Next, a conductive film 25af to be the conductive layer 25a and a conductive film 25bf to be the conductive layer 25b are stacked over the insulating layer 41 (FIG. 17A). The conductive film 25af and the conductive film 25bf can each be formed by a film formation method such as a sputtering method, an ALD method, or a CVD method.

Next, a resist mask is formed over the conductive film 25bf, and unnecessary portions of the conductive films are removed, whereby the conductive layer 25a and the conductive layer 25b are formed. Next, an insulating film to be the insulating layer 42 is formed and planarization treatment is performed until the top surface of the conductive layer 25b is exposed, whereby the insulating layer 42 can be formed (FIG. 17B). Thus, the conductive layer 25a and the conductive layer 25b can be embedded in the insulating layer 42.

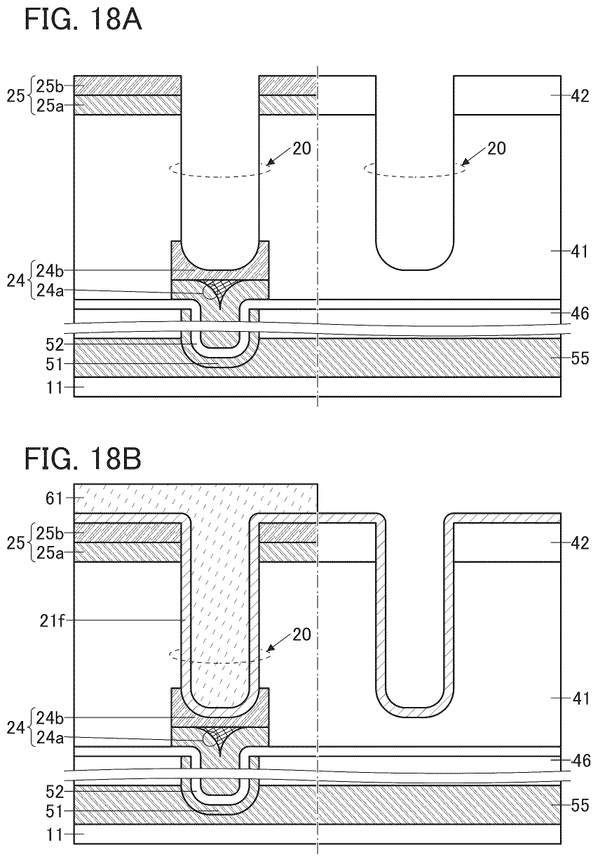

Next, a resist mask is formed over the conductive layer 25b and the insulating layer 42, and the slit 20 is formed in the conductive layer 25b, the conductive layer 25a, the insulating layer 42, and the insulating layer 41 (FIG. 18A). At the time of forming the slit 20, part of the conductive layer 24b positioned at the bottom portion of the slit 20 is preferably etched to form a depression portion in the conductive layer 24b. At this time, etching is preferably performed so that a concave surface is formed at an upper portion of the conductive layer 24b. As illustrated on the right side in FIG. 18A, a concave surface is preferably formed also on the top surface of the insulating layer 41 positioned at the bottom portion of the slit 20 in a portion where the conductive layer 24b is not provided.

Here, in the case where the conductive layer 24b has a shape with high flatness as described above, an opening reaching the conductive layer 24a can be prevented from being formed in the conductive layer 24b by the above etching. This can prevent the semiconductor layer 21 including a metal oxide, which is formed later, from being in contact with the conductive layer 24a2 having high conductivity, whereby extraction of oxygen in the semiconductor layer 21 to the conductive layer 24a2 can be prevented.

At the time of forming the slit 20, sidewalls of the slit 20 (side surfaces of the conductive layer 25b, the conductive layer 25a, the insulating layer 42, and the insulating layer 41) are preferably processed by anisotropic dry etching so as to be substantially perpendicular to the formation surface. Note that the sidewalls of the slit 20 may be inclined relative to the direction perpendicular to the formation surface to have a tapered shape, depending on the processing conditions.

Next, the semiconductor film 21f to be the semiconductor layer 21 is formed to cover the top and side surfaces of the conductive layer 25b, the side surface of the conductive layer 25a, the side and top surfaces of the insulating layer 41, and the top surface of the conductive layer 24b.

As the semiconductor film 21f, a metal oxide film having semiconductor characteristics (oxide semiconductor film) can be used. The formation of the metal oxide film can be performed by appropriately using a sputtering method, a CVD method, an MBE method, a PLD method, an ALD method, or the like. Here, the metal oxide film is preferably formed in contact with the substantially perpendicular side surface of the insulating layer 41. Thus, the metal oxide film is preferably formed by a film formation method with favorable coverage, and is further preferably formed by an ALD method.

The metal oxide film preferably has crystallinity. It is particularly preferable that the metal oxide film of one embodiment of the present invention include a metal oxide having a CAAC structure.

Note that treatment for increasing the crystallinity of the metal oxide film is preferably performed during or after the formation of the metal oxide film. Examples of the treatment for increasing the crystallinity of the metal oxide film include heat treatment, plasma treatment, microwave (typically, 2.45 GHZ) treatment, microwave plasma treatment, and light (e.g., ultraviolet light) irradiation treatment. Some of these treatments may be performed concurrently or sequentially. For example, heat treatment and microwave plasma treatment can be performed concurrently. Alternatively, microwave plasma treatment can be performed after heat treatment.

It is further preferable that the treatment for increasing the crystallinity of the metal oxide film be performed a plurality of times during the formation of the metal oxide film. For example, in the case where the metal oxide film is formed by an ALD method, microwave plasma treatment is preferably performed every time an atomic layer is formed. Alternatively, the treatment for increasing crystallinity is preferably performed every time the metal oxide film with a thickness in a predetermined range is formed, in which case the productivity can be increased. Specifically, the metal oxide film is preferably formed in the following manner: a first metal oxide film with a thickness greater than or equal to 1 nm and less than or equal to 10 nm is formed, first microwave plasma treatment is performed, a second metal oxide film with a thickness greater than or equal to 1 nm and less than or equal to 10 nm is formed, and then second microwave plasma treatment is performed.

Note that methods for forming the first metal oxide film and the second metal oxide film are not particularly limited, and can be an ALD method or a sputtering method. It is particularly preferable to form the first metal oxide film by an ALD method, in which case entry (also referred to as mixing) of an element of a layer on which the first metal oxide film is formed into the first and second metal oxide films can be prevented. Forming the first metal oxide film by an ALD method is particularly preferable in the case where the element of the layer on which the first metal oxide film is formed hinders crystallization of a metal oxide (e.g., the case where silicon, carbon, or the like is contained in the layer). The first metal oxide film and the second metal oxide film may have different compositions. Although the stacked-layer structure of the first metal oxide film and the second metal oxide film is exemplified here, one embodiment of the present invention is not limited thereto. Treatment similar to the above treatment can be performed on the metal oxide film having a single-layer structure or a stacked-layer structure of three or more layers.

The treatment for increasing the crystallinity of the metal oxide film may be performed after the formation of the metal oxide film. Specifically, after the formation of the metal oxide film, the treatment may be performed directly on the metal oxide film, or may be performed on the metal oxide film through another film such as an insulating film formed over the metal oxide film. For example, microwave plasma treatment may be performed on the metal oxide film after the formation of the metal oxide film; alternatively, an insulating film (e.g., a silicon nitride film, a silicon oxide film, or an aluminum oxide film) may be formed after the deposition of the metal oxide film, and then heat treatment or microwave plasma treatment may be performed on the metal oxide film through the insulating film.

Note that the treatment for increasing the crystallinity of the metal oxide film can also serve as treatment for removing impurities contained in the metal oxide film. For example, carbon, hydrogen, nitrogen, and the like contained in the metal oxide film can be favorably removed. Alternatively, by performing the treatment for increasing the crystallinity of the metal oxide film in an oxygen gas atmosphere, oxygen vacancies in the metal oxide film can be reduced.

During the treatment for increasing the crystallinity of the metal oxide film, the temperature of the heat treatment (or the substrate temperature) is preferably higher than or equal to room temperature (e.g., 25° C.), higher than or equal to 100° C. and lower than or equal to 700° C., higher than or equal to 100° C. and lower than or equal to 600° C., or higher than or equal to 300° C. and lower than or equal to 450° C. Even in the case where the heat treatment is performed, by setting the temperature within the above-described range, deformation (distortion or warpage) of the substrate can be significantly inhibited. In addition, release of hydrogen from the metal oxide film in the form of a hydrogen molecule or a water molecule can be promoted.

By increasing the crystallinity of the metal oxide film, a highly reliable transistor can be obtained.

The metal oxide film can be formed by a sputtering method using a metal oxide target, for example.

The metal oxide film is preferably a dense film with as few defects as possible. The metal oxide film is preferably a highly purified film in which impurities such as hydrogen and water are reduced as much as possible. It is particularly preferable to use a metal oxide film having crystallinity as the metal oxide film.

In forming the metal oxide film, an oxygen gas and an inert gas (such as a helium gas, an argon gas, or a xenon gas) may be mixed. Note that the higher the proportion of the oxygen gas in the whole deposition gas (hereinafter also referred to as oxygen flow rate ratio) is in forming the metal oxide film, the higher the crystallinity of the metal oxide film can be, achieving a highly reliable transistor. By contrast, the lower the oxygen flow rate ratio is, the lower the crystallinity of the metal oxide film is, offering a transistor with increased on-state current.

In forming the metal oxide film, as the substrate temperature becomes higher, a denser metal oxide film having higher crystallinity can be formed. On the other hand, as the substrate temperature becomes lower, a metal oxide film having lower crystallinity and higher electrical conductivity can be formed.

The metal oxide film is preferably formed at a substrate temperature higher than or equal to room temperature and lower than or equal to 250° C., preferably higher than or equal to room temperature and lower than or equal to 200° C., further preferably higher than or equal to room temperature and lower than or equal to 140° C. For example, the substrate temperature is preferably set to be higher than or equal to room temperature and lower than 140° C. in order to increase productivity. In the case where the metal oxide film is formed at a substrate temperature set to room temperature or without intentional heating, the metal oxide film can have low crystallinity.

In the case of employing an ALD method, a film formation method such as a thermal ALD method or a plasma enhanced ALD (PEALD) method is preferably employed. The thermal ALD method is preferable because of its capability of forming a film with extremely high step coverage. The PEALD method is preferable because of its capability of forming a film at low temperatures, in addition to its capability of forming a film with high step coverage.

For example, the semiconductor layer 21 including a metal oxide can be formed by an ALD method using a precursor containing a constituent metal element and an oxidizer.

For example, a film of In—Ga—Zn oxide can be formed using a precursor containing indium, a precursor containing gallium, and a precursor containing zinc. Alternatively, a precursor containing indium and a precursor containing gallium and zinc may be used.

As the precursor containing indium, it is possible to use triethylindium, trimethylindium, tris(2,2,6,6-tetramethyl-3,5-heptanedionato) indium, cyclopentadienylindium, indium (III) chloride, (3-(dimethylamino)propyl)dimethylindium, or the like.

As the precursor containing gallium, it is possible to use trimethylgallium, triethylgallium, tris(dimethylamido) gallium (III), gallium (III) acetylacetonate, tris(2,2,6,6-tetramethyl-3,5-heptanedionato) gallium, dimethylchlorogallium, diethylchlorogallium, gallium (III) chloride, or the like.

As the precursor containing zinc, it is possible to use dimethylzinc, diethylzinc, bis(2,2,6,6-tetramethyl-3,5-heptanedionato) zinc, zinc chloride, or the like.

Ozone, oxygen, water, or the like can be used as the oxidizer.

As an example of a method for controlling the composition of a film to be formed, adjusting the flow rate ratio, flowing time, flowing order, or the like of the source gases is given. By adjusting such conditions, a film whose composition is gradually changed can be formed. Furthermore, two or more films having different compositions can be formed successively.

After the metal oxide film is formed, heat treatment is preferably performed. The heat treatment is preferably performed at a temperature higher than or equal to 250° C. and lower than or equal to 650° C., preferably higher than or equal to 400° C. and lower than or equal to 600° C. so that the above-described metal oxide film does not become polycrystals. Note that the heat treatment is performed in a nitrogen gas atmosphere, an inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is preferably approximately 20%. The heat treatment may be performed under reduced pressure. Alternatively, the heat treatment may be performed in such a manner that heat treatment is performed in an atmosphere of a nitrogen gas or an inert gas, and then another heat treatment is performed in an atmosphere containing an oxidizing gas at 10 ppm or more, 1% or more, or 10% or more in order to compensate for released oxygen.

The gas used in the above heat treatment is preferably highly purified. For example, the amount of moisture contained in the gas used in the above-described heat treatment is preferably 1 ppb (0.001 ppm) or less, preferably 0.1 ppb or less, and further preferably 0.05 ppb or less. The heat treatment using a highly purified gas can, for example, prevent the entry of moisture into the metal oxide film as much as possible.

Although the semiconductor film 21f is illustrated as a single layer in the drawings, a stacked-layer structure may be employed. For example, a two-layer structure formed by an ALD method, a three-layer structure formed by an ALD method, a two-layer structure in which the first layer is formed by an ALD method and the second layer is formed by a sputtering method, or a three-layer structure in which the first layer is formed by an ALD method, the second layer is formed by a sputtering method, and the third layer is formed by an ALD method or a sputtering method can be employed. The first layer is preferably formed by an ALD method, which can inhibit mixing; alternatively, the first layer can also be formed by a sputtering method. Note that the semiconductor film 21f may have a stacked-layer structure of four or more layers.

Then, a resist mask 61 is formed over the semiconductor film 21f (FIG. 18B). In that case, in order to reduce variation in the thickness of the resist mask 61, an organic material or an inorganic material formed by a coating method may be provided between the resist mask 61 and the semiconductor film 21f as a planarization film that fills the slit 20. More specifically, a coating insulating film such as a spin on carbon (SOC) film or a spin on glass (SOG) film can be used, for example.

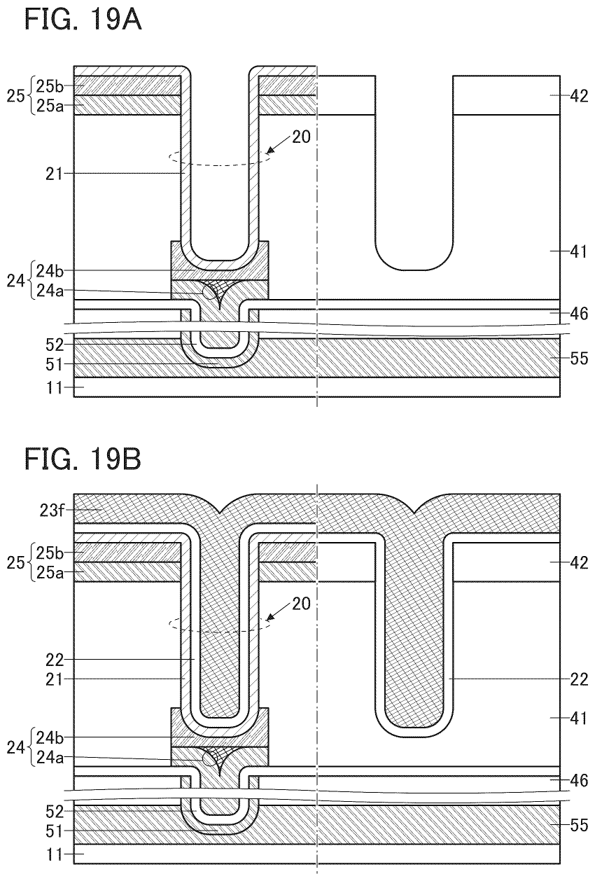

Next, part of the semiconductor film 21f that is not covered with the resist mask 61 is removed by etching, and then the resist mask 61 is removed, whereby the semiconductor layer 21 can be formed (FIG. 19A). In the etching of the semiconductor layer 21, it is difficult to remove part of the semiconductor layer 21 in contact with the side surface of the insulating layer 41 only by anisotropic dry etching; thus, the etching is preferably performed by a combination of isotropic dry etching or wet etching. Alternatively, treatment may be performed in advance on a region of the semiconductor film 21f that is not covered with the resist mask 61 so that the quality of part of the semiconductor film 21f is changed to facilitate etching. Examples of the treatment include plasma treatment, doping (including ion implantation) treatment, and wet treatment.

Next, the insulating layer 22 is formed to cover the semiconductor layer 21 and the insulating layer 41. The insulating layer 22 can be formed by a film formation method such as a sputtering method, an ALD method, or a CVD method. The insulating layer 22 is preferably provided to have as uniform a thickness as possible on the surface of the vertical portion of the semiconductor layer 21. Thus, the insulating layer 22 is particularly preferably formed by an ALD method, which is a film formation method with extremely excellent coverage. Note that in the case where the insulating layer 41 has a sidewall with a tapered shape, the insulating layer 22 can be formed by a film formation method such as a sputtering method or a CVD method.

Next, a conductive film 23f to be the conductive layer 23 later is formed to cover the insulating layer 22 (FIG. 19B). The conductive film 23f can be formed by a CVD method, an ALD method, a sputtering method, or the like. In terms of coverage, the conductive film 23f is particularly preferably formed by a CVD method.

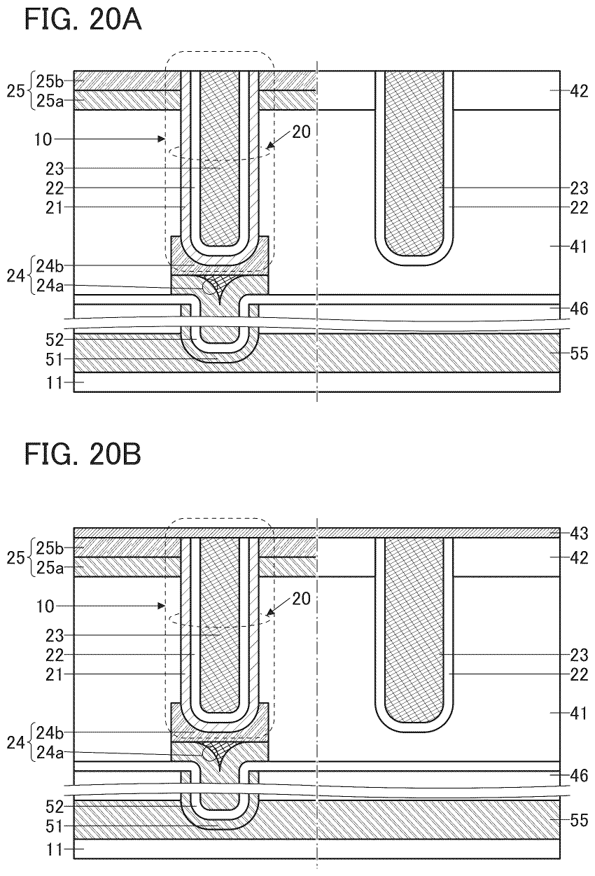

Next, planarization treatment is performed on the conductive film 23f, the insulating layer 22, and the semiconductor layer 21 (FIG. 20A). The planarization treatment is performed until the top surface of the conductive layer 25b is exposed. Thus, the semiconductor layer 21, the insulating layer 22, and the conductive layer 23 positioned inside the slit 20 are formed. By planarization treatment, the top surfaces of the conductive layer 25b, the conductive layer 23, the insulating layer 22, and the semiconductor layer 21 are substantially level with each other (e.g., at substantially the same levels from the substrate surface).

At this time, the transistor 10 can be formed.

Next, the insulating layer 43 is formed to cover the conductive layer 25b, the semiconductor layer 21, the insulating layer 22, and the conductive layer 23 (FIG. 20B). Then, the insulating layer 44 is formed over the insulating layer 43. The insulating layer 43 and the insulating layer 44 can be formed by a CVD method, an ALD method, a sputtering method, or the like.

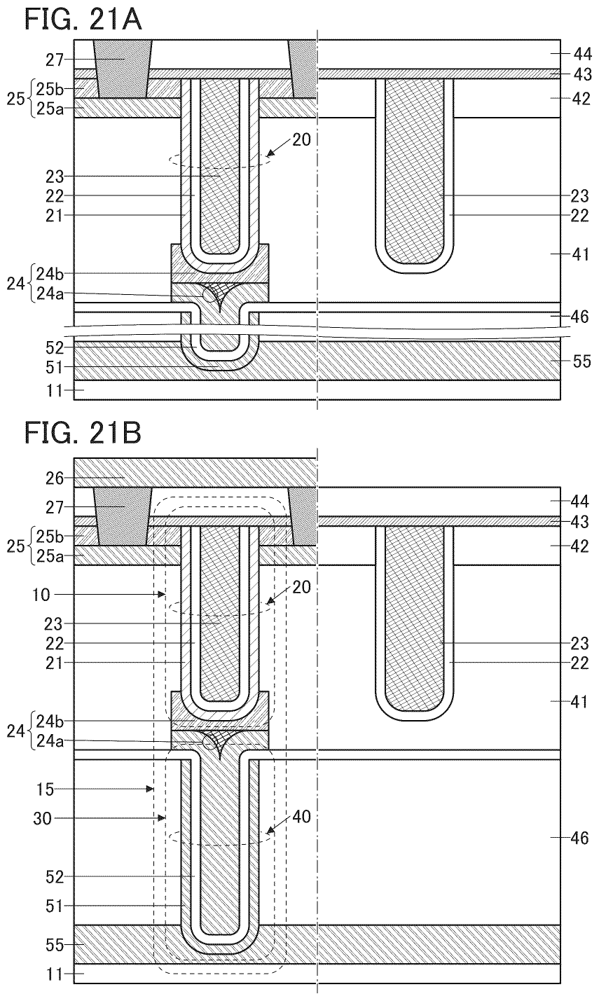

Then, an opening reaching the conductive layer 25a is formed in the insulating layer 44, the insulating layer 43, and the conductive layer 25b. After that, a conductive film that fills the opening is formed and planarization treatment is performed until the top surface of the insulating layer 44 is exposed, so that the plug 27 can be formed (FIG. 21A).

Next, a conductive film is formed over the insulating layer 44 and the plug 27, and an unnecessary portion is removed by etching, whereby the conductive layer 26 is formed (FIG. 21B).

Through the above-described steps, a semiconductor device provided with the memory cell 15 in which the transistor 10 and the capacitor 30 are included can be manufactured.

The above is the description of the manufacturing method example.

At least part of this embodiment can be implemented as appropriate in combination with any of the other embodiments described in this specification.

### Embodiment 2

In this embodiment, an indium oxide film that can be used for the semiconductor layer of the transistor included in the semiconductor device of one embodiment of the present invention will be described.

In this specification and the like, indium oxide including at least a crystal part or a crystal region in a film is referred to as crystal IO or crystalline IO. Examples of crystal IO or crystalline IO include single crystal indium oxide, polycrystal indium oxide, and microcrystal indium oxide.

Indium oxide is a semiconductor material having physical properties completely different from those of an oxide semiconductor such as In—Ga—Zn oxide (hereinafter, also referred to as IGZO) or zinc oxide.

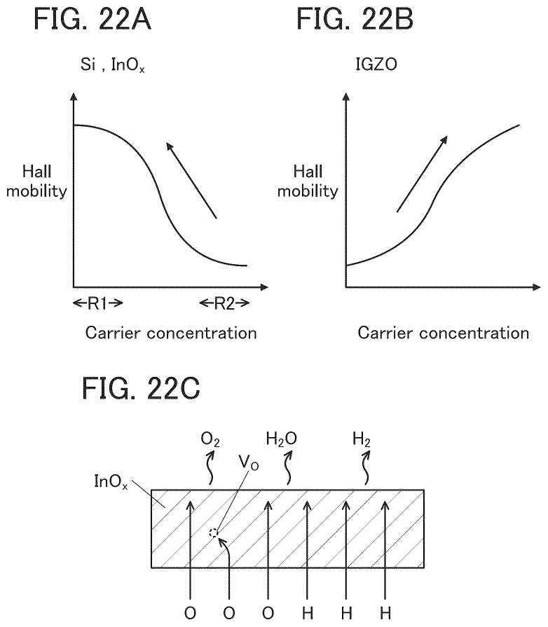

The dependence of the Hall mobility on the carrier concentration of indium oxide, silicon, and IGZO will be described. FIG. 22A is a schematic view showing the dependence of the Hall mobility on the carrier concentration of silicon (Si) and indium oxide (InO_{X}), and FIG. 22B is a schematic view showing the dependence of the Hall mobility on the carrier concentration of IGZO.

As indicated by an arrow in FIG. 22B, IGZO has a tendency in which the Hall mobility is higher as the carrier concentration is higher. By contrast, as indicated by an arrow in FIG. 22A, indium oxide has a tendency in which the Hall mobility is higher as the carrier concentration is lower (see Non-Patent Document 1). This tendency is similar to that of silicon; as the concentration of a dopant (impurity) in a material is lower, impurity scattering is inhibited more and thus the Hall mobility is higher. That is, indium oxide having higher purity and being more intrinsic has higher Hall mobility. Consequently, the physical properties of indium oxide are different from those of IGZO and similar to those of silicon. Note that the characteristics of indium oxide in FIG. 22A are based on the assumption of single crystal indium oxide; thus, the characteristics of non-single-crystal (e.g., polycrystal) indium oxide are sometimes different from those in FIG. 22A.

In FIG. 22A, the Hall mobility is extremely high in a range R1 with a low carrier concentration; thus, the range R1 can be regarded as a carrier concentration range suitable for a channel formation region of a transistor, for example. In the case of indium oxide, for example, the range R1 is a range including a carrier concentration of 1×10¹⁵ cm⁻³, e.g., a range with a carrier concentration higher than or equal to 1×10¹⁴ cm⁻³ and lower than or equal to 1×10¹⁸ cm⁻³. The adequately lowered carrier concentration will increase the Hall mobility to approximately 270 cm²/(V·s).

A region of indium oxide where the carrier concentration falls within the range R1 can include an element that reduces the carrier concentration. Examples of the element that reduces the carrier concentration include magnesium, calcium, zinc, cadmium, and copper. When indium is replaced with any of these elements, the carrier concentration can be reduced. Other examples of the element that reduces the carrier concentration include nitrogen, phosphorus, arsenic, and antimony. For example, when oxygen is replaced with nitrogen, phosphorus, arsenic, or antimony, the carrier concentration can be reduced.

A range R2 with a high carrier concentration has low electric resistance and is a carrier concentration range suitable for a source region and a drain region of a transistor, a resistor, or a transparent conductive film, for example. The range R2 is a range including a carrier concentration of 1×10²⁰ cm⁻³, e.g., a range with a carrier concentration higher than or equal to 1×10¹⁹ cm⁻³ and lower than or equal to 1×10²² cm⁻³. The adequately increased carrier concentration will decrease the resistivity to 1×10⁻⁴ Ω·cm or lower.

A region of indium oxide where the carrier concentration falls within the range R2 can include an element that increases the carrier concentration. For example, the region preferably includes the same element as a source electrode and a drain electrode of a transistor. Examples of the element that increases the carrier concentration include titanium, zirconium, hafnium, tantalum, tungsten, molybdenum, tin, silicon, and boron. It is particularly preferable that an oxide of the element have conductivity or semiconductor properties. As a method for supplying the element that increases the carrier concentration, a method in which a film containing the element is formed to diffuse the element, an ion implantation method, an ion doping method, a plasma immersion ion implantation method, or plasma treatment can be employed. In this specification and the like, whether or not mass separation is performed is not limited, unless otherwise specified. In this specification and the like, a method by which mass-separated ions are supplied is referred to as an ion implantation method, and a method by which non-mass-separated ions are supplied is referred to as an ion doping method, for example.

In this manner, the region with a low carrier concentration and the region with a high carrier concentration of indium oxide are used as a channel formation region and source and drain regions, respectively, of a transistor. That is, indium oxide can be regarded as an oxide whose valence electron can be controlled. As for IGZO, distortion due to stress of an electrode in contact with IGZO is formed in a source region and a drain region and n-type regions are formed in some cases. Since a valence electron can be controlled in indium oxide unlike in IGZO, formation of distortion can be inhibited in a film of indium oxide. The film with less distortion will have higher reliability. For example, when the region where the carrier concentration falls within the range R1 and the region where the carrier concentration falls within the range R2, which are shown in FIG. 22A, are separately formed in an indium oxide film, what is called an n-i-n junction (a junction between an n-type region, an i-type region, and an n-type region) can be formed. Although valence electron control in a transistor containing silicon is generally known, valence electron control in a transistor containing indium oxide is a novel technical idea that cannot be conceived usually.

With the use of the above technical idea, a transistor containing indium oxide in this specification and the like has two or more, preferably three or more, further preferably four or more, and most preferably all of the following features (1) to (5): (1) high on-state current (i.e., high mobility); (2) low off-state current; (3) normally-off characteristics; (4) high reliability; and (5) high cutoff frequency (fT). For example, the transistor containing indium oxide in this specification and the like has high mobility, low off-state current, and normally-off characteristics. This transistor is different from a normally-on transistor having high mobility.

The expression “a semiconductor is of an i-type” can be replaced with the expression “the Fermi level (Ef) is equal to the intrinsic Fermi level (Ei)(Ef=Ei)”. As shown in FIG. 22B, the Hall mobility is lower as the carrier concentration is lower in IGZO. Accordingly, in the case where Ef eventually becomes equal to Ei, carriers disappear (i.e., the physical properties of IGZO become similar to those of an insulator) and a transistor containing IGZO cannot operate. By contrast, the Hall mobility is higher as the carrier concentration is lower in indium oxide as shown in FIG. 22A. In the case where Ef eventually becomes equal to Ei, the Hall mobility is the highest. That is, a transistor containing indium oxide can have high field-effect mobility when Ef is equal to Ei. Note that a transistor containing indium oxide has a low carrier concentration and thus tends to be normally off. Hence, a transistor containing indium oxide can have both normally-off characteristics and high field-effect mobility.

Normally off means a state where no current flows through a transistor when a potential is not applied to its gate or its gate-source voltage is 0 V. The normally-off characteristics can be evaluated using the threshold voltage (Vth) or shift value (Vsh) of a transistor. Note that Vth is calculated by a constant current method unless otherwise specified. Vsh is gate voltage (Vg) at a point of intersection of a straight line of Id=1 pA (1×10⁻¹² A) and a tangent line of drain current (Id) on a logarithmic scale that has the highest gradient in the Id-Vg characteristics of the transistor, or gate voltage (Vg) at a point of intersection of a straight line of Id=1 pA and a straight line extrapolated from two points where the slope of Id on a logarithmic scale has the highest gradient in the Id-Vg characteristics of the transistor. For example, when at least one of Vth and Vsh is 0 or a positive value, the transistor can be regarded as being normally off.

In order that a semiconductor can be of an i-type, i.e., Ef can be equal to Ei, in a transistor containing indium oxide, the structure of a film in contact with an indium oxide film is important. For example, a transistor containing indium oxide can have a film structure in which a silicon oxide film, which is in contact with an indium oxide film, a hafnium oxide film, and a silicon nitride film are stacked. Such a film structure can achieve Ef=Ei, enabling a semiconductor device to have high reliability.

In the above film structure, a film containing oxygen, such as a silicon oxynitride film, a silicon nitride oxide film, an aluminum oxide film, or a gallium oxide film, can be used instead of the silicon oxide film. Also in the above film structure, a silicon nitride oxide film, a silicon oxynitride film, or the like can be used instead of the silicon nitride film. The hafnium oxide film that is closer to the indium oxide film than the silicon nitride film is functions as a hydrogen gettering site.

The above film structure can be regarded as a structure in which a film that is capable of supplying oxygen to the indium oxide film (e.g., the silicon oxide film), a film that is capable of gettering hydrogen (e.g., the hafnium oxide film), and a film that is capable of inhibiting entry of oxygen and hydrogen (e.g., the silicon nitride film) are stacked in this order from the indium oxide film side. With this structure, oxygen vacancies in the indium oxide film are filled with oxygen in the silicon oxide film. Moreover, hydrogen in the indium oxide film is captured in the hafnium oxide film by heat treatment or the like. Providing the silicon nitride film inhibits entry of oxygen and hydrogen from the outside. That is, the above film structure enables the indium oxide film to be closer to an i-type film. Thus, a transistor including the indium oxide film has high field-effect mobility and high reliability.

Next, an indium oxide film used for a transistor will be described. The indium oxide film preferably has crystallinity (i.e., has a crystal grain). Examples of a film having a crystal grain include a single crystal film, a polycrystal film, and an amorphous film having a crystal grain (also referred to as a microcrystal film). In particular, the indium oxide film is preferably a polycrystal film, further preferably a single crystal film. A single crystal film does not have a crystal grain boundary (also referred to as a grain boundary). Impurities that block the carrier flow (typically, an insulating impurity, an insulating oxide, or the like) are likely to be segregated at a crystal grain boundary. The use of a single crystal film can inhibit carrier scattering or the like at the crystal grain boundary, thereby achieving a transistor having high field-effect mobility. In addition, the use of a single crystal film produces an excellent effect of reducing a variation in transistor characteristics caused by the crystal grain boundary.

A polycrystal film is preferable because it can reduce carrier scattering as compared with a microcrystal film or an amorphous film and enables a transistor to have high field-effect mobility. In the case of using a polycrystal film, it is preferable to use a film that has as large a crystal grain size as possible and few crystal grain boundaries. In the case where the crystal grain boundary is neither included nor observed in a channel formation region of a transistor including a polycrystal indium oxide film, the channel formation region is positioned in a single crystal region included in the polycrystal film and thus the transistor can be regarded as a transistor containing single crystal indium oxide.

The crystallinity of indium oxide can be analyzed with an X-ray diffraction (XRD) pattern, a transmission electron microscope (TEM) image, or an electron diffraction (ED) pattern, for example. Alternatively, two or more of these methods may be combined for the analysis.

In this specification and the like, a semiconductor layer where no crystal grain boundary is observed in a channel formation region, a semiconductor layer where a channel formation region is included in one crystal grain, or a semiconductor layer where the directions of crystal axes of at least two regions in a channel formation region are the same can be referred to as a single crystal film. A semiconductor layer where the direction of a crystal axis is continuously changed with another crystal axis or a crystal orientation as a rotation axis in one crystal grain in a channel formation region can also be referred to as a single crystal film.

A channel formation region refers to a region of a semiconductor layer that overlaps with (or faces) a gate electrode with a gate insulating layer therebetween and is positioned between a region in contact with a source electrode and a region in contact with a drain electrode. A current path in a channel formation region is the shortest distance between a source electrode and a drain electrode. Thus, a crystal grain, a crystal grain boundary, a crystal axis, a crystal orientation, or the like in a channel formation region can be confirmed in observation of a cross section including a semiconductor layer, a source electrode, and a drain electrode.

The impurity concentration in an indium oxide film in a channel formation region is preferably as low as possible. Impurities in the indium oxide film in the channel formation region can function as a carrier scattering source and cause a reduction in field-effect mobility. Such impurities might inhibit crystal growth of the indium oxide film. Examples of the impurities for the indium oxide film include boron and silicon. The concentrations of these impurities in the indium oxide film are each preferably lower than or equal to 0.1%, further preferably lower than or equal to 0.01% (100 ppm). Note that carbon, hydrogen, and the like are elements that would be contained in a film formation gas or a precursor in film formation, and the amounts of these elements remaining in the indium oxide film might be larger than those of the impurities.

The indium oxide film in the channel formation region may contain an element that can form a trivalent cation like indium as long as the cubic crystal structure (bixbyite structure) is retained. Examples of the element include Group 13 elements such as gallium and aluminum and Group 3 elements in the periodic table. Since these elements exist mainly as trivalent cations in oxides, the carrier concentration of indium oxide can be kept low.

An indium oxide film in this specification and the like has high film density. Table 1 lists the film densities of indium oxides (In₂O₃ here) that can be used in one embodiment of the present invention.

TABLE 1
Film density of In₂O₃

| | | | | Film |
|---|---|---|---|---|
| | Condition | Condition | Condition | density |
| | 1 | 2 | 3 | [g/cm³] |
| Sample 1 | Glass | SP | as-depo | 6.72 |
| Sample 2 | Glass | SP | 350° C. baking, CDA | 6.75 |
| Sample 3 | Glass | SP | 650° C. baking, CDA | 6.74 |
| Sample 4 | SiOx | ALD | as-depo | 6.97 |
| Sample 5 | YSZ | ALD | as-depo | 7.05 |
| Sample 6 | YSZ | ALD | 250° C. baking, vacuum | 7.08 |

As shown in Table 1, the film densities of the indium oxide films are evaluated using six samples, Sample 1 to Sample 6. In Table 1, Condition 1 corresponds to the base conditions of the indium oxide films: glass for Samples 1 to 3; a SiOx film formed by a sputtering method for Sample 4; and yttria-stabilized zirconia (YSZ) for Samples 5 and 6. Condition 2 corresponds to the deposition conditions of the indium oxide films: a sputtering (SP) method for Samples 1 to 3; and an ALD method for Samples 4 to 6. Condition 3 corresponds to the heat treatment conditions after the deposition of the indium oxide films: no heat treatment (as-depo) for Samples 1, 4, and 5; 350° C. baking in a CDA atmosphere for Sample 2; 650° C. baking in a CDA atmosphere for Sample 3; and 250° C. baking in a vacuum atmosphere for Sample 6.

In Table 1, CDA means clean dry air. Note that the content of hydrogen, water, and the like in the atmosphere for the heat treatment (corresponding to Condition 3) after the deposition of the indium oxide films is preferably as low as possible. As the atmosphere, a high-purity gas with a dew point of −60° C. or lower, preferably −100° C. or lower is preferably used.

As shown in Table 1, the indium oxide film that is subjected to heat treatment tends to have a higher film density than the film that is not subjected to heat treatment (Sample 1, 4, or 5). This is because heat treatment causes release of impurity elements (e.g., carbon, nitrogen, hydrogen, and argon) from the film, making the indium oxide film highly purified. As can be found from Samples 5 and 6, the indium oxide films over YSZ each have a film density exceeding 7.00 g/cm³. The theoretical film density of the indium oxide film is 7.18 g/cm³. The film density of the indium oxide film in this specification and the like ranges from 6.70 g/cm³ to 7.18 g/cm³, preferably from 6.90 g/cm³ to 7.18 g/cm³, further preferably from 7.00 g/cm³ to 7.18 g/cm³.

The film density can be evaluated by Rutherford backscattering spectrometry (RBS) or X-ray reflection (XRR), for example. A difference in film density can be evaluated using a cross-sectional TEM image in some cases. In TEM observation, a transmission electron (TE) image is dark-colored (dark) when the film density is high, and a TE image is pale (bright) when the film density is low.

A transistor including the above indium oxide film can have a field-effect mobility higher than or equal to 50 cm²/(V·s), preferably higher than or equal to 100 cm²/(V·s), further preferably higher than or equal to 150 cm²/(V·s), still further preferably higher than or equal to 200 cm²/(V·s), yet still further preferably higher than or equal to 250 cm²/(V·s).

One feature of an indium oxide film is to have a higher property of transmitting (diffusing) oxygen than an IGZO film. As shown in FIG. 22C, oxygen (O) diffusing in an indium oxide film (denoted as InO_{X}) is transmitted through the indium oxide film and released as an oxygen molecule (O₂). When reacting with hydrogen contained in the film, oxygen is released as a water molecule (H₂O) in some cases. In the case where the film includes oxygen vacancies (V_{O}), the oxygen vacancies are filled with diffusing oxygen atoms. Since oxygen easily diffuses in the indium oxide film, oxygen vacancies in the indium oxide film are filled with oxygen more easily than those in an IGZO film.

As described above, the oxygen vacancies in the indium oxide film are reduced more easily than those in the IGZO film; thus, a transistor including such an indium oxide film can have extremely high reliability.

As shown in FIG. 22C, hydrogen diffuses in the indium oxide film. Hydrogen diffusing into the indium oxide film from the outside is transmitted through the indium oxide film and is released as a hydrogen molecule (H₂). When reacting with oxygen contained in the film, hydrogen is released as a water molecule.

A transistor including an indium oxide film is an accumulation-type transistor in which electrons are majority carriers. Assuming that the relaxation time of carriers is constant, the electron (carrier) mobility is higher as the effective mass of electrons (carriers) is smaller. That is, a transistor in which an indium oxide with a small effective mass of electrons is used for a semiconductor layer can have a high on-state current or high field-effect mobility.

Table 2 shows the effective mass in each of single crystal indium oxide (here, In₂O₃) and single crystal silicon (Si). As shown in Table 2, indium oxide has features of a small effective mass of electrons and a large effective mass of holes. In addition, the effective mass of electrons in indium oxide hardly depends on the crystal orientation. Thus, a transistor containing indium oxide having crystallinity can have high field-effect mobility and high frequency characteristics (also referred to as f characteristics). A large effective mass of holes allows a transistor to have an extremely low off-state current. For example, the off-state current per micrometer of channel width of a vertical transistor including an indium oxide film can be lower than or equal to 1 fA (1×10⁻¹⁵ A) or lower than or equal to 1 aA (1×10⁻¹⁸ A) at 125° C., and can be lower than or equal to 1 aA (1×10⁻¹⁸ A) or lower than or equal to 1 zA (1×10⁻²¹ A) at room temperature (25° C.). Since indium oxide has a smaller effective mass of electrons and a larger effective mass of holes than silicon as shown in Table 2, a transistor containing indium oxide can have higher field-effect mobility and lower off-state current than a Si transistor.

TABLE 2
Effective mass in In₂O₃

| Electron | | | |
|---|---|---|---|
| [100] direction | [110] direction | [111] direction | Hole |
| 0.17 | 0.18 | 0.19 | 3.56 |

Effective mass in Si

| Electron | Hole |
|---|---|
| 0.26 | 0.17 |

A seed layer is preferably provided in contact with at least part of the indium oxide film having crystallinity. A material of the seed layer is preferably selected such that the difference in a lattice constant (also referred to as lattice mismatch) between the crystal included in indium oxide and the crystal included in the material is small. In this case, the crystallinity of the indium oxide film can be improved. As a layer in contact with at least part of the indium oxide film having crystallinity, a substrate (e.g., a single crystal substrate) may be used.

One of methods for evaluating the degree of a lattice mismatch is a method using a value of a lattice mismatch degree described below. A lattice mismatch degree Δa [%] of a crystal included in a film to be formed (here, the indium oxide film) with respect to the crystal included in the seed layer is calculated by the formula: Δa=((L₁−L₂)/L₂)×100. Here, L₁ is the lattice constant or the length of the unit lattice vector of the crystal included in the film to be formed, and L₂ is the lattice constant or the length of the unit lattice vector of the crystal included in the seed layer.

The absolute value of the lattice mismatch degree Δa between the seed layer and the indium oxide film is preferably as small as possible, most preferably 0. For example, Δa can be greater than or equal to −5% and less than or equal to 5%, preferably greater than or equal to −4% and less than or equal to 4%, further preferably greater than or equal to −3% and less than or equal to 3%, still further preferably greater than or equal to −2% and less than or equal to 2%.

An indium oxide crystal has a cubic crystal structure (a bixbyite structure). For example, an yttria-stabilized zirconia (YSZ) crystal can have a cubic crystal structure (a fluorite crystal structure). The lattice mismatch degree of an indium oxide crystal with respect to an YSZ crystal having the cubic crystal structure is within the range of −2% to 2%, which enables epitaxial growth of a single crystal film of indium oxide over the YSZ substrate.

The crystal structures of the seed layer and the indium oxide film do not necessarily have the same crystal system or crystal orientation in some cases. For example, a film including a crystal with a hexagonal crystal structure or a trigonal crystal structure can be provided below an indium oxide film including a crystal with a cubic crystal structure. For example, when the crystal orientation of a seed layer surface is set to [001] and the crystal orientation of a bottom surface of the indium oxide film is set to [111], the necessary condition for crystal orientation in epitaxial growth can be satisfied. Examples of a hexagonal or trigonal crystal structure include a wurtzite structure, a YbFe₂O₄-type structure, a Yb₂Fe₃O₇-type structure, and variations of these structures. An example of a crystal having a YbFe₂O₄-type structure or a Yb₂Fe₃O₇-type structure is IGZO. A single crystal film of indium oxide can be formed not only over a YSZ substrate but also over an insulating film. By contrast, a single crystal film of silicon is not easily formed over an insulating film. Note that a silicon crystal has a diamond structure. Thus, although indium oxide and silicon exhibit similar characteristics as single crystals, they differ in whether a single crystal can be formed over an insulating film.

At least part of this embodiment can be implemented as appropriate in combination with any of the other embodiments described in this specification.

### Embodiment 3

In this embodiment, a semiconductor device 900 of one embodiment of the present invention, which is different from the above embodiment, will be described. The semiconductor device 900 can function as a memory device.

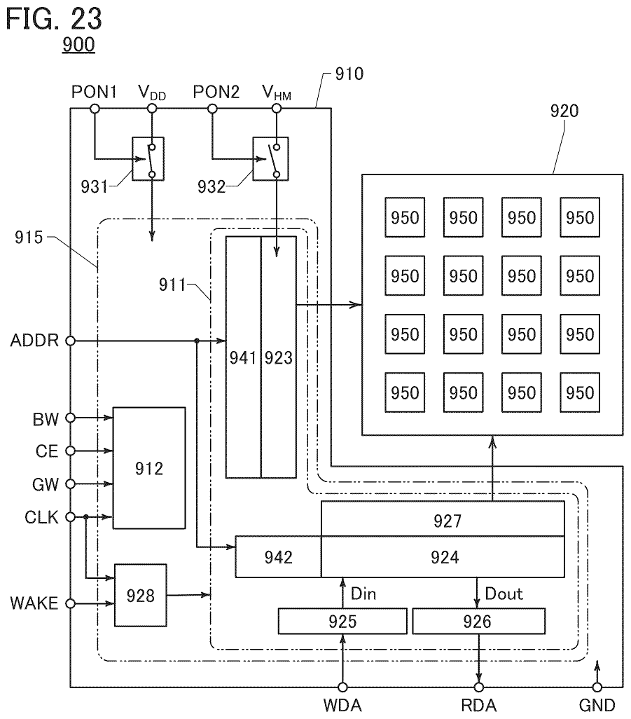

FIG. 23 is a block diagram illustrating a structure example of the semiconductor device 900. The semiconductor device 900 illustrated in FIG. 23 includes a driver circuit 910 and a memory array 920. The memory array 920 includes one or more memory cells 950. FIG. 23 illustrates an example in which the memory array 920 includes a plurality of memory cells 950 arranged in a matrix.

The memory cell 15 or the like exemplified in the above embodiment can be used as the memory cell 950.

The driver circuit 910 includes a power switch (PSW) 931, a PSW 932, and a peripheral circuit 915. The peripheral circuit 915 includes a peripheral circuit 911, a control circuit 912, and a voltage generator circuit 928.

In the semiconductor device 900, the circuits, signals, and voltages can be appropriately selected as needed. Another circuit or another signal may be added. Signals BW, CE, GW, CLK, WAKE, ADDR, WDA, PON1, and PON2 are signals input from the outside, and a signal RDA is a signal output to the outside. The signal CLK is a clock signal.

The signals BW, CE, and GW are control signals. The signal CE is a chip enable signal. The signal GW is a global write enable signal. The signal BW is a byte write enable signal. The signal ADDR is an address signal. The signal WDA is a write data signal, and the signal RDA is a read data signal. The signals PON1 and PON2 are power gating control signals. Note that the signals PON1 and PON2 may be generated in the control circuit 912.

The control circuit 912 is a logic circuit having a function of controlling the overall operation of the semiconductor device 900. For example, the control circuit 912 performs logical operation on the signals CE, GW, and BW to determine the operating mode (e.g., write operation or read operation) of the semiconductor device 900. The control circuit 912 generates a control signal for the peripheral circuit 911 so that the operating mode is executed.

The voltage generator circuit 928 has a function of generating a negative voltage. The signal WAKE has a function of controlling the input of the signal CLK to the voltage generator circuit 928. For example, when an H-level signal is applied as the signal WAKE, the signal CLK is input to the voltage generator circuit 928, and the voltage generator circuit 928 generates a negative voltage.

The peripheral circuit 911 is a circuit for writing and reading data to/from the memory cell 950. The peripheral circuit 911 includes a row decoder 941, a column decoder 942, a row driver 923, a column driver 924, an input circuit 925, an output circuit 926, and a sense amplifier 927.

The row decoder 941 and the column decoder 942 have a function of decoding the signal ADDR. The row decoder 941 is a circuit for specifying a row to be accessed. The column decoder 942 is a circuit for specifying a column to be accessed. The row driver 923 has a function of selecting the row specified by the row decoder 941. The column driver 924 has a function of writing data to the memory cell 950, reading data from the memory cell 950, and retaining the read data, for example.

The input circuit 925 has a function of retaining the signal WDA. Data retained in the input circuit 925 is output to the column driver 924. Data output from the input circuit 925 is data (Din) written to the memory cell 950. Data (Dout) read from the memory cell 950 by the column driver 924 is output to the output circuit 926. The output circuit 926 has a function of retaining Dout. Moreover, the output circuit 926 has a function of outputting Dout to the outside of the semiconductor device 900. The data output from the output circuit 926 is the signal RDA.

The PSW 931 has a function of controlling the supply of VDD to the peripheral circuit 915. The PSW 932 has a function of controlling the supply of VHM to the row driver 923. Here, in the semiconductor device 900, a high power supply voltage is VDD and a low power supply voltage is GND (ground potential). In addition, VHM is a high power supply voltage used for setting a word line to high level, and is higher than VDD. The on/off state of the PSW 931 is controlled by the signal PON1, and the on/off state of the PSW 932 is controlled by the signal PON2. The number of power domains to which VDD is supplied is one in the peripheral circuit 915 in FIG. 23 but can be more than one. In that case, a power switch is preferably provided for each power domain.

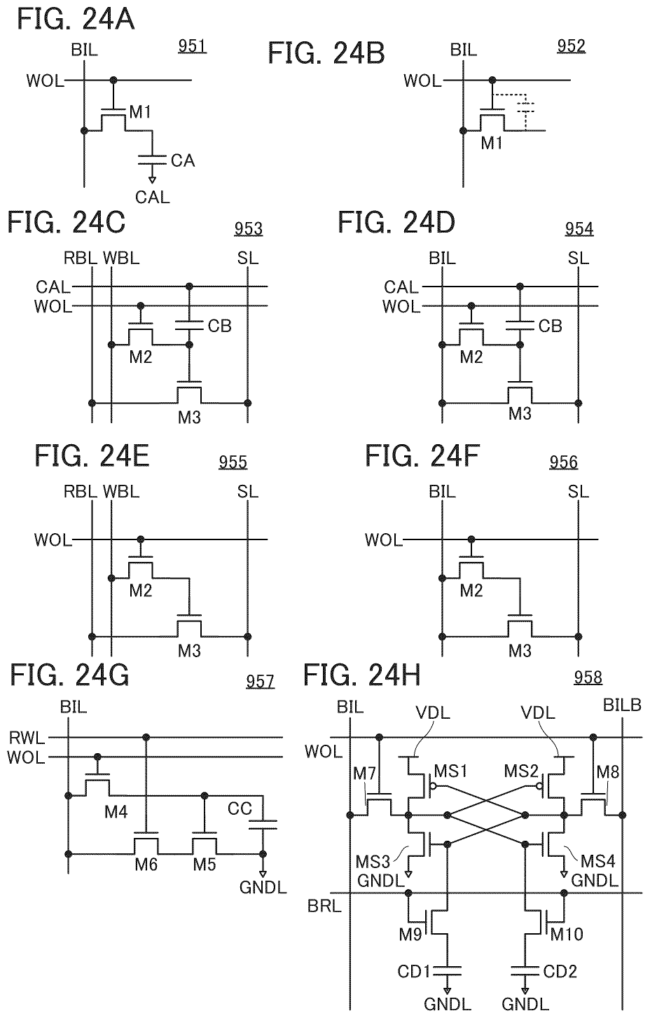

Structure examples of other memory cells that can be used as the memory cell 950 are described with reference to FIGS. 24A to 24H.

In the following description, the expression “two components are connected to each other” includes the case where the two components are electrically connected through a circuit element (a transistor, a switch, a diode, a resistor, or the like). The term “electrical connection” means a state where a current can flow between two components. Note that the case where two components are connected through a switch or a transistor is included in electrical connection because a current can flow when the components are in an on state.

### [DOSRAM]

FIG. 24A illustrates a circuit structure example of a DRAM memory cell. In this specification and the like, a DRAM using an OS transistor is referred to as a dynamic oxide semiconductor random access memory (DOSRAM). A memory cell 951 includes a transistor M1 and a capacitor CA.

Note that the transistor M1 may include a front gate (simply referred to as a gate in some cases) and a back gate. Here, the back gate may be connected to a wiring supplied with a constant potential or a signal, and the front gate and the back gate may be connected to each other.

A first terminal of the transistor M1 is connected to a first terminal of the capacitor CA. A second terminal of the transistor M1 is connected to a wiring BIL. The gate of the transistor M1 is connected to a wiring WOL. A second terminal of the capacitor CA is connected to a wiring CAL.

The wiring BIL functions as a bit line, and the wiring WOL functions as a word line. The wiring CAL functions as a wiring for applying a predetermined potential to the second terminal of the capacitor CA. At the time of data writing and reading, a low-level potential (referred to as a reference potential in some cases) is preferably applied to the wiring CAL.

Data writing and data reading are performed in such a manner that a high-level potential is applied to the wiring WOL to turn on the transistor M1 and establish electrical continuity between the wiring BIL and the first terminal of the capacitor CA (make a state where a current can flow therethrough).

The memory cell that can be used as the memory cell 950 is not limited to the memory cell 951, and the circuit structure can be changed. For example, a structure of a memory cell 952 illustrated in FIG. 24B can be employed. The memory cell 952 is an example including neither the capacitor CA nor the wiring CAL. The first terminal of the transistor M1 is in an electrically floating state.

In the memory cell 952, a potential written through the transistor M1 is retained in a capacitor (also referred to as parasitic capacitance) between the first terminal and the gate, which is shown by a dashed line. With such a structure, the structure of the memory cell can be greatly simplified.

Note that an OS transistor is preferably used as the transistor M1. An OS transistor has a characteristic of an extremely low off-state current. The use of an OS transistor as the transistor M1 enables an extremely low leakage current of the transistor M1. That is, with the use of the transistor M1, written data can be retained for a long time, and thus the frequency of refresh operation for the memory cell can be decreased. Alternatively, refresh operation for the memory cell can be omitted. In addition, owing to an extremely low leakage current, multilevel data or analog data can be retained in the memory cells 951 and 952.

### [NOSRAM]

FIG. 24C illustrates a circuit structure example of a gain-cell memory cell including two transistors and one capacitor. A memory cell 953 includes a transistor M2, a transistor M3, and a capacitor CB. In this specification and the like, a memory device including a gain-cell memory cell using an OS transistor as the transistor M2 is referred to as a nonvolatile oxide semiconductor RAM (NOSRAM).

A first terminal of the transistor M2 is connected to a first terminal of the capacitor CB. A second terminal of the transistor M2 is connected to a wiring WBL. A gate of the transistor M2 is connected to the wiring WOL. A second terminal of the capacitor CB is connected to the wiring CAL. A first terminal of the transistor M3 is connected to a wiring RBL. A second terminal of the transistor M3 is connected to a wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. At the time of data writing, data retention, and data reading, a low-level potential (sometimes referred to as a reference potential) is preferably applied to the wiring CAL.

Data writing is performed in such a manner that a high-level potential is applied to the wiring WOL to turn on the transistor M2 and establish electrical continuity between the wiring WBL and the first terminal of the capacitor CB. Specifically, when the transistor M2 is on, a potential corresponding to data to be stored is applied to the wiring WBL, and the potential is written to the first terminal of the capacitor CB and the gate of the transistor M3. Then, a low-level potential is applied to the wiring WOL to turn off the transistor M2, whereby the potential of the first terminal of the capacitor CB and the potential of the gate of the transistor M3 are retained.

Data reading is performed by applying a predetermined potential to the wiring SL. A current flowing between the source and the drain of the transistor M3 and the potential of the first terminal of the transistor M3 are determined by the potential of the gate of the transistor M3 and the potential of the second terminal of the transistor M3. Accordingly, by reading a potential of the wiring RBL connected to the first terminal of the transistor M3, a potential retained in the first terminal of the capacitor CB (or the gate of the transistor M3) can be read. That is, data written to the memory cell can be read on the basis of the potential retained in the first terminal of the capacitor CB (or the gate of the transistor M3).

As another example, one wiring BIL may be provided instead of the wiring WBL and the wiring RBL. A circuit structure example of the memory cell is illustrated in FIG. 24D. In a memory cell 954, one wiring BIL is provided instead of the wiring WBL and the wiring RBL in the memory cell 953, and the second terminal of the transistor M2 and the first terminal of the transistor M3 are electrically connected to the wiring BIL. In other words, one wiring BIL operates as the write bit line and the read bit line in the memory cell 954.

A memory cell 955 illustrated in FIG. 24E is an example in which the capacitor CB and the wiring CAL in the memory cell 953 are omitted. A memory cell 956 illustrated in FIG. 24F is an example in which the capacitor CB and the wiring CAL in the memory cell 954 are omitted. Such structures enable high integration of memory cells.

Note that an OS transistor is preferably used as at least the transistor M2. In particular, an OS transistor is preferably used as each of the transistors M2 and M3.

Since the OS transistor has a characteristic of an extremely low off-state current, written data can be retained for a long time with the use of the transistor M2, and thus the frequency of refresh operation for the memory cell can be decreased. Alternatively, refresh operation for the memory cell can be omitted. In addition, owing to an extremely low leakage current, multilevel data or analog data can be retained in the memory cells 953, 954, 955, and 956.

The memory cells 953, 954, 955, and 956 each using the OS transistor as the transistor M2 are embodiments of a NOSRAM.

Note that a Si transistor may be used as the transistor M3. The Si transistor can have high field-effect mobility and can be formed as a p-channel transistor, so that circuit design flexibility can be increased.

When the OS transistor is used as the transistor M3, the memory cell can be configured with only n-type transistors.

FIG. 24G illustrates an example of a gain memory cell 957 including three transistors and one capacitor. The memory cell 957 includes transistors M4 to M6 and a capacitor CC.

A first terminal of the transistor M4 is connected to a first terminal of the capacitor CC. A second terminal of the transistor M4 is connected to the wiring BIL. A gate of the transistor M4 is connected to the wiring WOL. A second terminal of the capacitor CC is connected to a first terminal of the transistor M5 and a wiring GNDL. A second terminal of the transistor M5 is connected to a first terminal of the transistor M6. A gate of the transistor M5 is connected to the first terminal of the capacitor CC. A second terminal of the transistor M6 is electrically connected to the wiring BIL. A gate of the transistor M6 is connected to a wiring RWL.

The wiring BIL functions as a bit line. The wiring WOL functions as a write word line. The wiring RWL functions as a read word line. The wiring GNDL is a wiring for supplying a low-level potential.

Data writing is performed in such a manner that a high-level potential is applied to the wiring WOL to turn on the transistor M4 and establish electrical continuity between the wiring BIL and the first terminal of the capacitor CC. Specifically, when the transistor M4 is on, a potential corresponding to data to be stored is applied to the wiring BIL, and the potential is written to the first terminal of the capacitor CC and the gate of the transistor M5. Then, a low-level potential is applied to the wiring WOL to turn off the transistor M4, whereby the potential of the first terminal of the capacitor CC and the potential of the gate of the transistor M5 are retained.

Data reading is performed by precharging the wiring BIL with a predetermined potential, and then making the wiring BIL in an electrically floating state and applying a high-level potential to the wiring RWL. Since the wiring RWL has the high-level potential, the transistor M6 is turned on, so that electrical continuity is established between the wiring BIL and the second terminal of the transistor M5. At this time, the potential of the wiring BIL is applied to the second terminal of the transistor M5; the potential of the second terminal of the transistor M5 and the potential of the wiring BIL change depending on the potential retained in the first terminal of the capacitor CC (or the gate of the transistor M5). Here, the potential retained in the first terminal of the capacitor CC (or the gate of the transistor M5) can be read by reading the potential of the wiring BIL. That is, data written to the memory cell can be read on the basis of the potential retained in the first terminal of the capacitor CC (or the gate of the transistor M5).

Note that an OS transistor is preferably used as at least the transistor M4.

Note that Si transistors may be used as the transistors M5 and M6. As described above, a Si transistor may have higher field-effect mobility than the OS transistor depending on the crystal state of silicon used in a semiconductor layer, for example.

When OS transistors are used as the transistors M5 and M6, the memory cell can be configured with only n-type transistors.

### [OS-SRAM]

FIG. 24H illustrates an example of a static random access memory (SRAM) using an OS transistor. In this specification and the like, an SRAM using an OS transistor is referred to as an oxide semiconductor SRAM (OS-SRAM). A memory cell 958 illustrated in FIG. 24H is a memory cell of an SRAM capable of backup operation.

The memory cell 958 includes transistors M7 to M10, transistors MS1 to MS4, a capacitor CD1, and a capacitor CD2. The transistors MS1 and MS2 are p-channel transistors, and the transistors MS3 and MS4 are n-channel transistors.

A first terminal of the transistor M7 is connected to the wiring BIL. A second terminal of the transistor M7 is connected to a first terminal of the transistor MS1, a first terminal of the transistor MS3, a gate of the transistor MS2, a gate of the transistor MS4, and a first terminal of the transistor M10. A gate of the transistor M7 is connected to the wiring WOL. A first terminal of the transistor M8 is connected to a wiring BILB. A second terminal of the transistor M8 is connected to a first terminal of the transistor MS2, a first terminal of the transistor MS4, a gate of the transistor MS1, a gate of the transistor MS3, and a first terminal of the transistor M9. A gate of the transistor M8 is connected to the wiring WOL.

A second terminal of the transistor MS1 is connected to a wiring VDL. A second terminal of the transistor MS2 is connected to the wiring VDL. A second terminal of the transistor MS3 is connected to the wiring GNDL. A second terminal of the transistor MS4 is connected to the wiring GNDL.

A second terminal of the transistor M9 is connected to a first terminal of the capacitor CD1. A gate of the transistor M9 is connected to a wiring BRL. A second terminal of the transistor M10 is connected to a first terminal of the capacitor CD2. A gate of the transistor M10 is connected to the wiring BRL.

A second terminal of the capacitor CD1 is connected to the wiring GNDL. A second terminal of the capacitor CD2 is connected to the wiring GNDL.

The wirings BIL and BILB function as bit lines. The wiring WOL functions as a word line. The wiring BRL controls the on/off states of the transistors M9 and M10.

The wiring VDL supplies a high-level potential. The wiring GNDL supplies a low-level potential.

Data writing is performed by applying a high-level potential to the wiring WOL and the wiring BRL. Specifically, when the transistor M10 is on, a potential corresponding to data to be stored is applied to the wiring BIL, and the potential is written to the second terminal side of the transistor M10.

In the memory cell 958, the transistors MS1 and MS2 form an inverter loop; hence, an inversion signal of a data signal corresponding to the potential is input to the second terminal side of the transistor M8. Since the transistor M8 is on, an inversion signal of the potential that has been applied to the wiring BIL (i.e., the signal that has been input to the wiring BIL) is output to the wiring BILB. Since the transistors M9 and M10 are on, the potential of the second terminal of the transistor M7 is retained in the first terminal of the capacitor CD2, and the potential of the second terminal of the transistor M8 is retained in the first terminal of the capacitor CD1. After that, a low-level potential is applied to the wiring WOL and the wiring BRL to turn off the transistors M7 to M10, whereby the potential of the first terminal of the capacitor CD1 and the potential of the first terminal of the capacitor CD2 are retained.

Data reading will be described. First, the wiring BIL and the wiring BILB are precharged to a predetermined potential in advance. Next, a high-level potential is applied to the wiring WOL, and a high-level potential is applied to the wiring BRL. At this time, the potential of the first terminal of the capacitor CD1 is refreshed by the inverter loop in the memory cell 958 and output to the wiring BILB. Furthermore, the potential of the first terminal of the capacitor CD2 is refreshed by the inverter loop in the memory cell 958 and output to the wiring BIL. Since the potentials of the wiring BIL and the wiring BILB are changed from the precharged potentials to the potentials of the first terminal of the capacitor CD2 and the first terminal of the capacitor CD1, the potential retained in the memory cell can be read on the basis of the potentials of the wiring BIL and the wiring BILB.

Note that the transistors M7 to M10 are preferably OS transistors. In this case, with the use of the transistors M7 to M10, written data can be retained for a long time, and thus the frequency of refresh operation for the memory cell can be decreased. Alternatively, refresh operation for the memory cell can be omitted.

Note that the transistors MS1 to MS4 may be Si transistors.

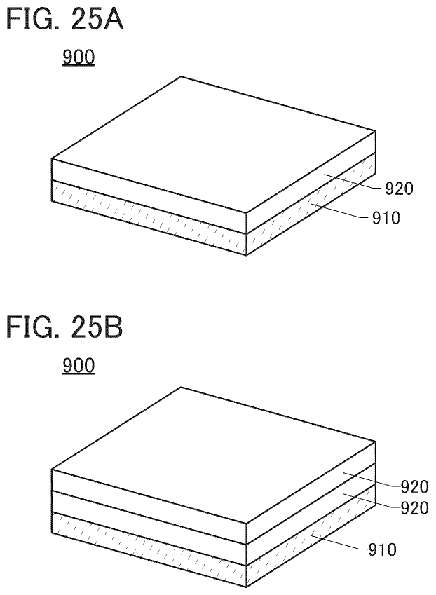

The driver circuit 910 and the memory array 920 included in the semiconductor device 900 may be provided on the same plane. Alternatively, as illustrated in FIG. 25A, the driver circuit 910 and the memory array 920 may be provided to overlap each other. Overlapping the driver circuit 910 and the memory array 920 can shorten a signal propagation distance. As illustrated in FIG. 25B, a plurality of memory cell arrays 920 may be stacked over the driver circuit 910.

Next, description is made on an example of an arithmetic processing device that can include the semiconductor device, such as the memory device described above.

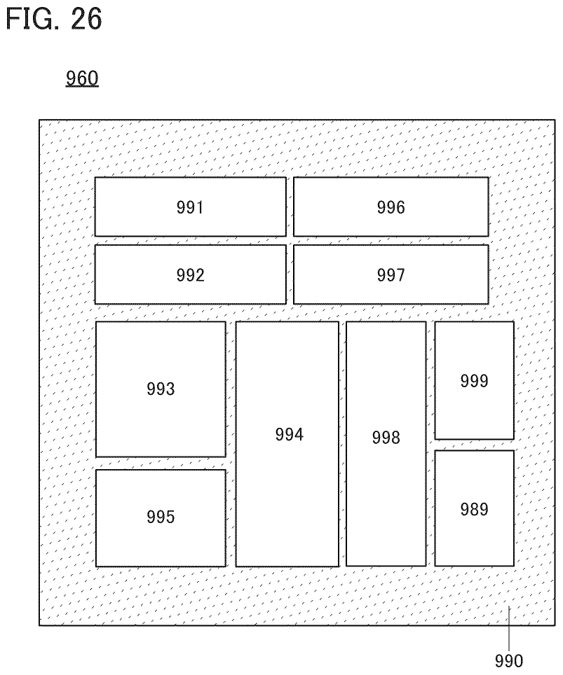

FIG. 26 is a block diagram of an arithmetic device 960. The arithmetic device 960 illustrated in FIG. 26 can be used for a central processing unit (CPU), for example. The arithmetic device 960 can also be used for a processor including a larger number of (several tens to several hundreds of) processor cores capable of parallel processing than a CPU, such as a graphics processing unit (GPU), a tensor processing unit (TPU), or a neural processing unit (NPU).

The arithmetic device 960 illustrated in FIG. 26 includes, over a substrate 990, an arithmetic logic unit (ALU) 991, an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic device 960 may also include a rewritable ROM and a ROM interface. The cache 999 and the cache interface 989 may be provided in a separate chip.

The cache 999 is connected via the cache interface 989 to a main memory provided in another chip. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory array 920 can be stacked over the arithmetic device 960. The memory array 920 can be used as a cache. Here, the cache interface 989 may have a function of supplying data retained in the memory array 920 to the cache 999. Moreover, in this case, the driver circuit 910 is preferably included in part of the cache interface 989.

Note that it is also possible that the cache 999 is not provided and only the memory array 920 is used as a cache.

The arithmetic device 960 illustrated in FIG. 26 is only an example with a simplified structure, and the actual arithmetic device 960 has a variety of structures depending on the application. For example, what is called a multicore structure is preferably employed in which a plurality of cores each including the arithmetic device 960 in FIG. 26 operate in parallel. The larger number of cores can further enhance the arithmetic performance. The number of cores is preferably larger; for example, the number is preferably 2, further preferably 4, still further preferably 8, still further preferably 12, yet still further preferably 16 or larger. For application requiring extremely high arithmetic performance, e.g., a server, it is preferable to employ the multicore structure including 16 or more, preferably 32 or more, further preferably 64 or more cores. The number of bits that the arithmetic device 960 can handle with an internal arithmetic circuit, a data bus, or the like can be 8, 16, 32, or 64, for example.

An instruction input to the arithmetic device 960 through the bus interface 998 is input to the instruction decoder 993 and decoded, and then input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. The interrupt controller 994 judges and processes an interrupt request from an external input/output device, a peripheral circuit, or the like on the basis of its priority, a mask state, or the like while the arithmetic device 960 is executing a program. The register controller 997 generates the address of the register 996, and reads/writes data from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above circuits.

In the arithmetic device 960 in FIG. 26, the register controller 997 selects operation of retaining data in the register 996 in accordance with an instruction from the ALU 991. That is, the register controller 997 selects whether data is retained by a flip-flop or by a capacitor in a memory cell included in the register 996. When data retention by the flip-flop is selected, a power supply voltage is supplied to the memory cell in the register 996. When data retention by the capacitor is selected, the data is rewritten into the capacitor, and supply of the power supply voltage to the memory cell in the register 996 can be stopped.

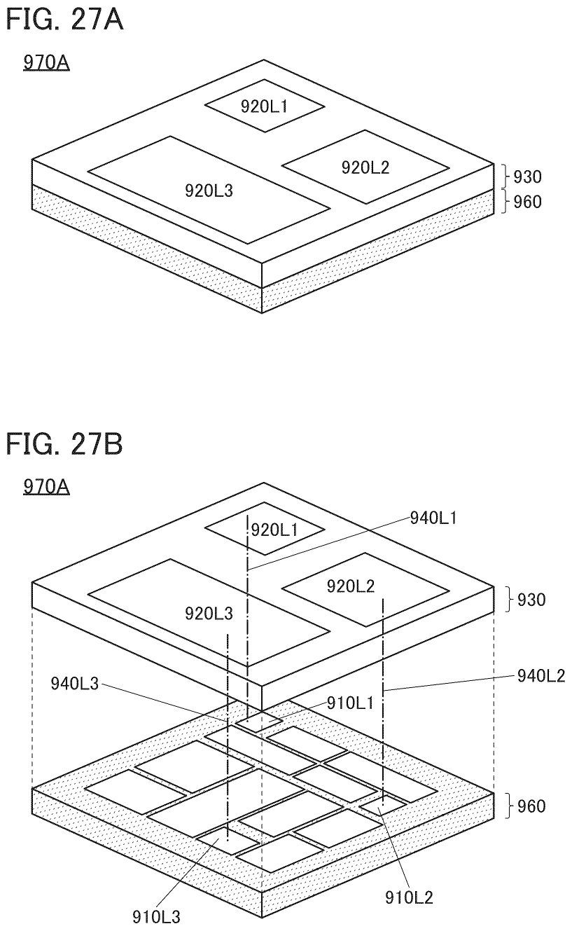

The memory array 920 and the arithmetic device 960 can be provided to overlap with each other. FIGS. 27A and 27B are perspective views of a semiconductor device 970A. The semiconductor device 970A includes a layer 930 provided with memory arrays over the arithmetic device 960. A memory array 920L1, a memory array 920L2, and a memory array 920L3 are provided in the layer 930. The arithmetic device 960 and each of the memory arrays overlap with each other. For easy understanding of the structure of the semiconductor device 970A, the arithmetic device 960 and the layer 930 are separately illustrated in FIG. 27B.

Overlapping the arithmetic device 960 and the layer 930 including the memory arrays can shorten the connection distance therebetween. Accordingly, the communication speed therebetween can be increased. Moreover, a short connection distance leads to lower power consumption.

As a method for stacking the layer 930 including the memory arrays and the arithmetic device 960, either of the following methods may be employed: a method in which the layer 930 including the memory arrays is stacked directly on the arithmetic device 960, which is also referred to as monolithic stacking, and a method in which the arithmetic device 960 and the layer 930 are formed over two different substrates, the substrates are bonded to each other, and the arithmetic device 960 and the layer 930 are electrically connected to each other with a through via or by a technique for bonding conductive films (e.g., Cu—Cu bonding). The former method does not require consideration of misalignment in bonding; thus, not only the chip size but also the manufacturing cost can be reduced.

Here, it is possible that the arithmetic device 960 does not include the cache 999 and the memory arrays 920L1, 920L2, and 920L3 provided in the layer 930 are each used as a cache. In this case, for example, the memory array 920L1, the memory array 920L2, and the memory array 920L3 can be used as an L1 cache (also referred to as a level 1 cache), an L2 cache (also referred to as a level 2 cache), and an L3 cache (also referred to as a level 3 cache), respectively. Among the three memory arrays, the memory array 920L3 has the highest capacity and the lowest access frequency. The memory array 920L1 has the lowest capacity and the highest access frequency.

Note that in the case where the cache 999 provided in the arithmetic device 960 is used as the L1 cache, the memory arrays provided in the layer 930 can each be used as the lower-level cache or the main memory. The main memory has higher capacity and lower access frequency than the cache.

As illustrated in FIG. 27B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Note that although the case where three memory arrays function as caches is described here, the number of memory arrays can be one, two, or four or more.

In the case where the memory array 920L1 is used as a cache, the driver circuit 910L1 may function as part of the cache interface 989 or the driver circuit 910L1 may be connected to the cache interface 989. Similarly, each of the driver circuits 910L2 and 910L3 may function as part of the cache interface 989 or be connected thereto.

Whether the memory array 920 functions as the cache or the main memory is determined by the control circuit 912 included in each of the driver circuits 910. The control circuit 912 can make some of the memory cells 950 in the semiconductor device 900 function as RAM in accordance with a signal supplied from the arithmetic device 960.

In the semiconductor device 900, some of the memory cells 950 can function as the cache and the other memory cells 950 can function as the main memory. That is, the semiconductor device 900 can have both the function of the cache and the function of the main memory. The semiconductor device 900 of one embodiment of the present invention can function as a universal memory, for example.

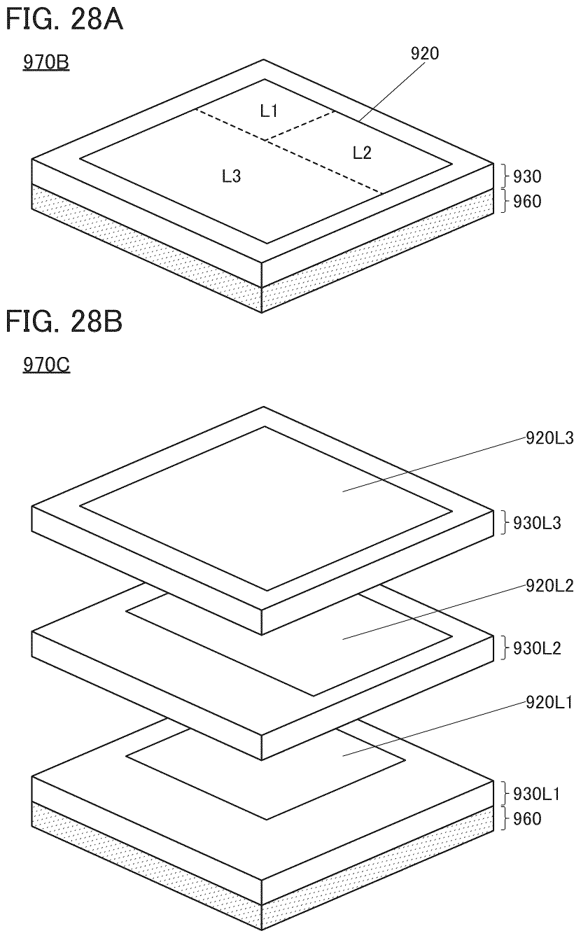

The layer 930 including one memory array 920 may be provided to overlap with the arithmetic device 960. FIG. 28A is a perspective view of a semiconductor device 970B.

In the semiconductor device 970B, one memory array 920 can be divided into a plurality of areas having different functions. FIG. 28A illustrates an example in which a region L1, a region L2, and a region L3 are used as the L1 cache, the L2 cache, and the L3 cache, respectively.

In the semiconductor device 970B, the capacity of each of the regions L1 to L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 28B is a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. Such a structure can increase the capacity of each memory array, leading to higher processing capability.

At least part of this embodiment can be implemented as appropriate in combination with any of the other embodiments described in this specification.

### Embodiment 4

In this embodiment, application examples of the semiconductor device of one embodiment of the present invention are described. The semiconductor device of one embodiment of the present invention can be used for an electronic component, an electronic device, a large computer, space equipment, and a data center (also referred to as DC), for example. An electronic component, an electronic device, a large computer, space equipment, and a data center each employing the semiconductor device of one embodiment of the present invention are effective in improving performance, for example, reducing power consumption.

### [Electronic Component]

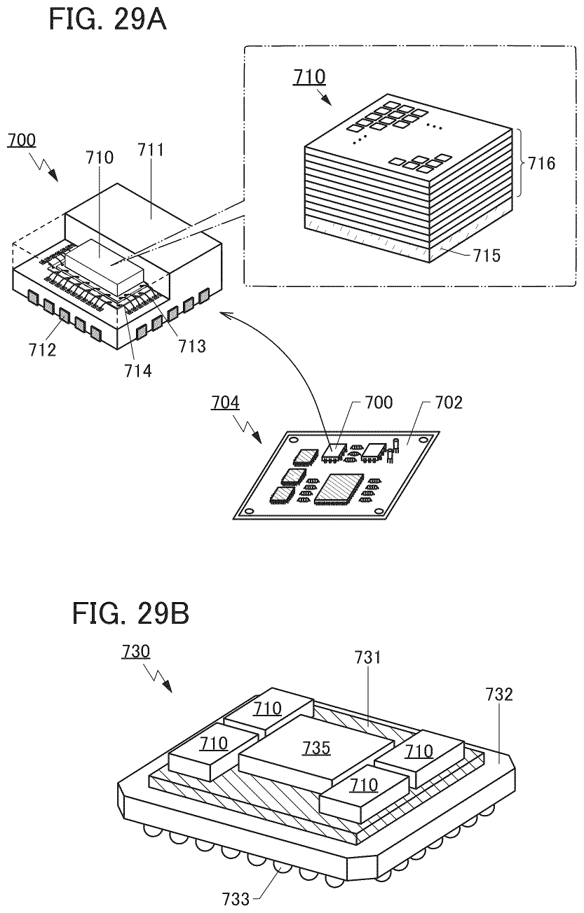

FIG. 29A is a perspective view of a substrate (a circuit board 704) provided with an electronic component 700. The electronic component 700 illustrated in FIG. 29A includes a semiconductor device 710 in a mold 711. FIG. 29A omits some components to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the circuit board 704.

The semiconductor device 710 includes a driver circuit layer 715 and a memory layer 716. The memory layer 716 has a structure where a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as a through silicon via (TSV) technique and a bonding technique such as Cu-to-Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is used, which means that the number of connection pins can be increased. The increase in the number of connection pins enables parallel operations, which can improve the bandwidth of the memory (also referred to as a memory bandwidth).

It is preferable that the plurality of memory cell arrays included in the memory layer 716 be formed with OS transistors and be monolithically stacked. Monolithically stacking the plurality of memory cell arrays can improve one or both of a memory bandwidth and a memory access latency. Note that the bandwidth refers to the data transfer volume per unit time, and the access latency refers to a period of time from data access to the start of data transmission. Note that in the case where the memory layer 716 is formed with Si transistors, the monolithic stacked-layer structure is difficult to form compared with the case where the memory layer 716 is formed with OS transistors. Therefore, an OS transistor is superior to a Si transistor in the monolithic stacked-layer structure.

The semiconductor device 710 may be called a die. Note that in this specification and the like, a die refers to a chip obtained by, for example, forming a circuit pattern on a disc-like substrate (also referred to as a wafer) or the like and cutting the substrate with the pattern into dices in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

FIG. 29B is a perspective view of an electronic component 730. The electronic component 730 is an example of a system in package (SiP) or a multi-chip module (MCM). In the electronic component 730, an interposer 731 is provided over a package substrate 732 (printed circuit board), and a semiconductor device 735 and a plurality of semiconductor devices 710 are provided over the interposer 731.

The electronic component 730 using the semiconductor device 710 as a high bandwidth memory (HBM) is illustrated as an example. The semiconductor device 735 can be used for an integrated circuit such as a central processing unit (CPU), a graphics processing unit (GPU), a neural processing unit (NPU) or a field programmable gate array (FPGA).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

In the case where a plurality of integrated circuits with different terminal pitches are electrically connected with use of a silicon interposer, a TSV, and the like, a space for a width of the terminal pitch and the like is needed. Accordingly, in the case where the size of the electronic component 730 is reduced, the width of the terminal pitch becomes an issue, which sometimes makes it difficult to provide a large number of wirings for obtaining a wide memory bandwidth. For this reason, the above-described monolithic stacked-layer structure with use of OS transistors is suitable. A composite structure combining memory cell arrays stacked using a TSV and monolithically stacked memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 29B illustrates an example where the electrode 733 is formed of a solder ball. Solder balls are provided in a matrix on the bottom portion of the package substrate 732, so that ball grid array (BGA) mounting can be achieved. Alternatively, the electrode 733 may be formed of a conductive pin. When conductive pins are provided in a matrix on the bottom portion of the package substrate 732, pin grid array (PGA) mounting can be achieved.

The electronic component 730 can be mounted on another substrate by various mounting methods other than BGA and PGA. Examples of a mounting method include staggered pin grid array (SPGA), land grid array (LGA), quad flat package (QFP), quad flat J-leaded package (QFJ), and quad flat non-leaded package (QFN).

### [Large Computer]

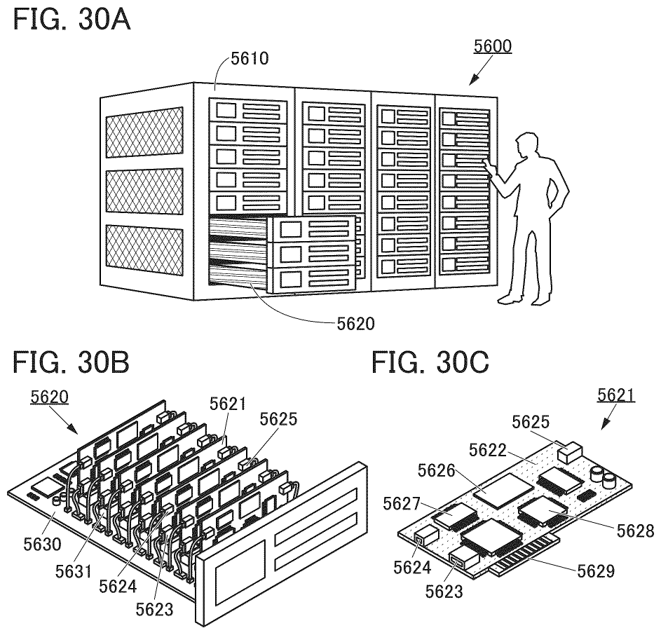

FIG. 30A is a perspective view of a large computer 5600. In the large computer 5600 illustrated in FIG. 30A, a plurality of rack mount computers 5620 are stored in a rack 5610. Note that the large computer 5600 may be referred to as a supercomputer.

FIG. 30B is a perspective view of an example of the computer 5620. The computer 5620 includes a motherboard 5630. The motherboard 5630 is provided with a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

FIG. 30C illustrates an example of the PC card 5621. The PC card 5621 is a processing board provided with a CPU, a GPU, a memory device, and the like, for example. The PC card 5621 includes a board 5622 and components mounted on the board 5622, such as the connection terminal 5623, the connection terminal 5624, the connection terminal 5625, an electronic component 5626, an electronic component 5627, an electronic component 5628, and a connection terminal 5629. Note that FIG. 30C illustrates components other than the electronic component 5626, the electronic component 5627, and the electronic component 5628.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can each serve as, for example, an interface for performing power supply, signal input, or the like to the PC card 5621. For another example, they can each serve as an interface for outputting a signal calculated by the PC card 5621. Examples of the standard for each of the connection terminal 5623, the connection terminal 5624, and the connection terminal 5625 include Universal Serial Bus (USB), Serial ATA (SATA), and Small Computer System Interface (SCSI). In the case where video signals are output from the connection terminal 5623, the connection terminal 5624, and the connection terminal 5625, an example of the standard therefor is HDMI (registered trademark).

The electronic component 5626 includes a terminal (not illustrated) for inputting and outputting signals, and when the terminal is inserted in a socket (not illustrated) of the board 5622, the electronic component 5626 and the board 5622 can be electrically connected to each other.

The electronic components 5627 and 5628 include a plurality of terminals; when the terminals are reflow-soldered, for example, to the wirings of the board 5622, the electronic components 5627 and 5628 can be mounted. Examples of the electronic component 5627 include an FPGA, a GPU, and a CPU. As the electronic component 5627, the electronic component 730 can be used, for example. Examples of the electronic component 5628 include a memory device. As the electronic component 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used as space equipment.

The semiconductor device of one embodiment of the present invention includes an OS transistor. A change in electrical characteristics of the OS transistor due to radiation irradiation is small. That is, the OS transistor is highly resistant to radiation, and thus can be suitably used in an environment where radiation can enter. For example, the OS transistor can be suitably used in outer space. Specifically, the OS transistor can be used as a transistor in a semiconductor device provided in a space shuttle, an artificial satellite, or a space probe. Examples of radiation include X-rays and a neutron beam. Note that although outer space refers to, for example, space at an altitude greater than or equal to 100 km, outer space described in this specification includes one or more of thermosphere, mesosphere, and stratosphere.

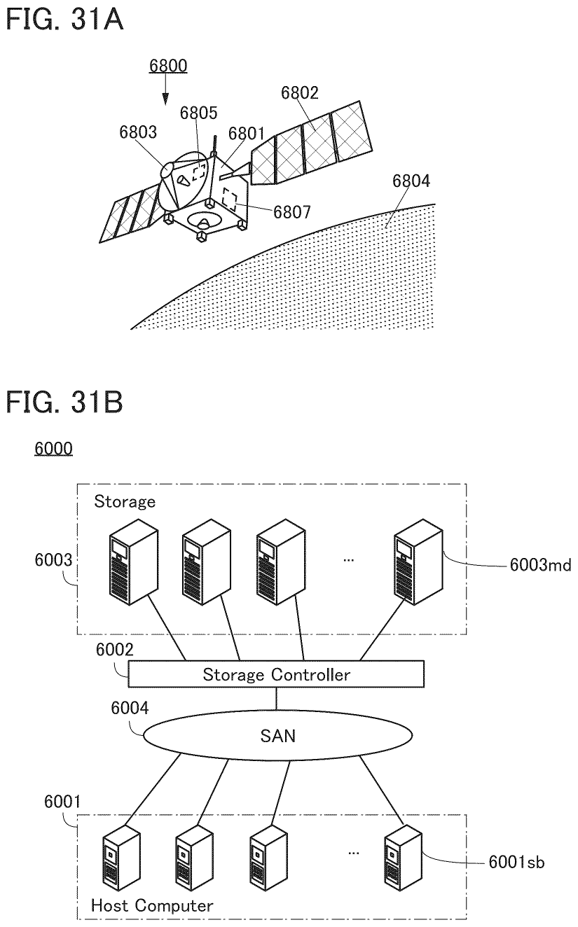

FIG. 31A illustrates an artificial satellite 6800 as an example of a space equipment. The artificial satellite 6800 includes a body 6801, a solar panel 6802, an antenna 6803, a secondary battery 6805, and a control device 6807. In FIG. 31A, a planet 6804 in outer space is illustrated as an example.

Although not illustrated in FIG. 31A, a battery management system (also referred to as BMS) or a battery control circuit may be provided in the secondary battery 6805. The battery management system or the battery control circuit preferably uses the OS transistor, in which case low power consumption and high reliability are achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used for the control device 6807. A change in electrical characteristics due to radiation irradiation is smaller in an OS transistor than in a Si transistor. Accordingly, the OS transistor has high reliability and thus can be suitably used even in an environment where radiation can enter.

The artificial satellite 6800 can include a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can function as an earth observing satellite, for example.

Although the artificial satellite is described as an example of a device for space in this embodiment, one embodiment of the present invention is not limited to this example. The semiconductor device of one embodiment of the present invention can be suitably used for a device for space such as a spacecraft, a space capsule, or a space probe, for example.

As described above, an OS transistor has excellent effects of achieving a wide memory bandwidth and high radiation tolerance as compared with a Si transistor.

### [Data Center]

The semiconductor device of one embodiment of the present invention can be suitably used for, for example, a storage system in a data center or the like. Long-term management of data, such as guarantee of data immutability, is required for the data center. The long-term management of data needs setting a storage and a server for retaining a huge amount of data, stable power supply for retaining data, cooling equipment for retaining data, an increase in building size, and the like.

With use of the semiconductor device of one embodiment of the present invention for a storage system in a data center, electric power used for retaining data can be reduced and a semiconductor device for retaining data can be downsized. Accordingly, downsizing of the storage system and the power supply for retaining data, downscaling of the cooling equipment, and the like can be achieved. Therefore, a space of the data center can be reduced.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention enables a data center that operates stably even in a high temperature environment. Thus, the reliability of the data center can be increased.

FIG. 31B illustrates a storage system that can be used in a data center. A storage system 6000 illustrated in FIG. 31B includes a plurality of servers 6001sb as a host 6001 (indicated as “Host Computer” in the diagram). The storage system 6000 includes a plurality of memory devices 6003md as a storage 6003 (indicated as “Storage” in the diagram). In the illustrated example, the host 6001 and the storage 6003 are connected to each other through a storage area network 6004 (indicated as “SAN” in the diagram) and a storage control circuit 6002 (indicated as “Storage Controller” in the diagram).

The host 6001 corresponds to a computer that accesses data stored in the storage 6003. The host 6001 may be connected to another host 6001 through a network.

The data access speed, i.e., the time taken for storing and outputting data, of the storage 6003 is shortened by using a flash memory, but is still considerably longer than the data access speed of a DRAM that can be used as a cache memory in a storage. In the storage system, in order to solve the problem of low access speed of the storage 6003, a cache memory is normally provided in the storage to shorten the time taken for data storage and output.

The above-described cache memory is used in the storage control circuit 6002 and the storage 6003. The data transmitted between the host 6001 and the storage 6003 is stored in the cache memories in the storage control circuit 6002 and the storage 6003 and then output to the host 6001 or the storage 6003.

With a structure in which an OS transistor is used as a transistor for storing data in the cache memory to retain a potential based on data, the frequency of refreshing can be decreased, so that power consumption can be reduced. Furthermore, downscaling is possible by stacking memory cell arrays.

The use of the semiconductor device of one embodiment of the present invention for one or more selected from an electronic component, an electronic device, a large computer, space equipment, and a data center will produce an effect of reducing power consumption. While the demand for energy is expected to increase with higher performance or higher integration of semiconductor devices, the emission amount of greenhouse effect gases typified by carbon dioxide (CO₂) can be reduced with use of the semiconductor device of one embodiment of the present invention. Furthermore, the semiconductor device of one embodiment of the present invention has low power consumption and thus is effective as a global warming countermeasure.

At least part of this embodiment can be implemented as appropriate in combination with any of the other embodiments described in this specification.

### Example 1

In this example, samples including OS transistors and capacitors were fabricated and cross-sectional observation was performed. In addition, the electrical characteristics of the OS transistors were evaluated.

In this example, as Sample 1A, a semiconductor device which includes the layer 60 including Si transistors and the layer 80 positioned over the layer 60 and including the memory cells 15 as illustrated in FIG. 5 was fabricated. In Sample 1A, the memory cells 15 each have a structure including the capacitor 30 and the transistor 10 as in the structure illustrated in FIG. 10 and FIG. 11. The memory cells 15 were arranged in a matrix on the XY plane illustrated in FIG. 10 and FIG. 11, the conductive layer 26 functioning as a wiring was provided to extend in the X direction, and the conductive layer 55 and the conductive layer 23 functioning as wirings were provided to extend in the Y direction. For the details of the capacitor 30 and the transistor 10 in Sample 1A, the description of FIG. 10 and FIG. 11 can be referred to.

The memory cells of this example will be described in detail below.

As illustrated in FIG. 10 and FIG. 11, the conductive layer 55 was formed in the opening of the insulating layer 53. As the insulating layer 53, a silicon oxide film was formed by a sputtering method. The conductive layer 55 had a stacked-layer structure of the conductive layer 55a and the conductive layer 55b. As the conductive layer 55a, a stacked-layer film of a tantalum nitride film formed by a sputtering method and a titanium nitride film formed by a CVD method was used. As the conductive layer 55b, a tungsten film was formed by a CVD method.

The insulating layer 46 having the opening 40 was formed over the insulating layer 53. The insulating layer 48 was formed in contact with the sidewall of the opening 40. The insulating layer 46 had a stacked-layer structure of the insulating layer 46a, the insulating layer 46b, and the insulating layer 46c. As the insulating layer 46a, a silicon nitride film was formed by a PEALD method. As the insulating layer 46b, a silicon oxide film was formed by a sputtering method. As the insulating layer 46c, a silicon nitride film was formed by a sputtering method. As the insulating layer 48, a silicon nitride film was formed by a PEALD method.

The conductive layer 51 was formed along the opening 40, the insulating layer 52 was formed along the conductive layer 51, and the conductive layer 24 was formed to fill the depression portion of the insulating layer 52. As the conductive layer 51, a titanium nitride film was formed by a CVD method. As the insulating layer 52, a stacked-layer film of a zirconium oxide film, an aluminum oxide film, and a zirconium oxide film which were formed by a thermal ALD method was used. As the conductive layer 24a1, a stacked-layer film of a titanium nitride film and a tungsten film which were formed by a CVD method was used. As the conductive layer 24a2, a titanium nitride film was formed by a CVD method. As the conductive layer 24b, an In—Sn—Si oxide film was formed by a sputtering method.

The conductive layer 24 was formed through the steps illustrated in FIG. 15B to FIG. 16C. First, the conductive film 24a1f was formed, and the conductive film 24a2f was formed over the conductive film 24a1f. Next, CMP treatment was performed until the conductive film 24a1f was exposed, so that the conductive layer 24a2 which fills the depression portion of the conductive film 24a1f was formed. Next, the conductive film 24bf was formed, and the conductive film 24a1f and the conductive film 24bf were processed, so that the conductive layer 24a1 and the conductive layer 24b were formed. Here, the insulating layer 52 was formed to have the same top surface shape as the conductive layer 24a1 and the conductive layer 24b.

The insulating layer 41 was formed over the conductive layer 24. The insulating layer 41 had a stacked-layer structure of the insulating layer 41a, the insulating layer 41b, and the insulating layer 41c. As the insulating layer 41a, a stacked-layer film of a silicon nitride film formed by a PEALD method and a silicon nitride film formed by a sputtering method was used. After the formation of the insulating layer 41a, CMP treatment was performed to planarize the top surface of the insulating layer 41a. As the insulating layer 41b, a silicon oxide film was formed by a sputtering method. As the insulating layer 41c, a silicon nitride film was formed by a sputtering method. Here, the thickness of the insulating layer 41 above the conductive layer 24 was set to 115 nm.

The conductive layer 25 was formed over the insulating layer 41. The slit 20 was formed in the insulating layer 41 and the conductive layer 25. The conductive layer 25 had a stacked-layer structure of the conductive layer 25a and the conductive layer 25b. As the conductive layer 25a, a tungsten film formed by a sputtering method was used. As the conductive layer 25b, an In—Sn—Si oxide film formed by a sputtering method was used.

The semiconductor layer 21 was formed along the slit 20. The semiconductor layer 21 was a stacked-layer film of a crystalline In₂O₃ film formed by a thermal ALD method and an In—Ga—Zn oxide film formed by a sputtering method. The thickness of the In₂O₃ film was set to 5 nm. The In—Ga—Zn oxide film was formed to a thickness of 5 nm using a target with an atomic ratio of In:Ga:Zn=1:1:1.2. The semiconductor layer 21 was formed into an island shape in the slit 20. Here, the width of the semiconductor layer 21 in the Y direction was set to 400 nm.

The insulating layer 22 was formed along the semiconductor layer 21, and the conductive layer 23 was formed along the insulating layer 22. The conductive layer 23 had a stacked-layer structure of the conductive layer 23a and the conductive layer 23b. As the insulating layer 22, a stacked-layer film of an aluminum oxide film formed by a thermal ALD method, a silicon oxide film formed by a PEALD method, a hafnium oxide film formed by a thermal ALD method, and a silicon nitride film formed by a PEALD method was used. As the conductive layer 23a, a titanium nitride film was formed by a CVD method. As the conductive layer 23b, a tungsten film was formed by a CVD method. Here, the conductive layer 23, the insulating layer 22, and the semiconductor layer 21 were formed so that part of the conductive layer 23, part of the insulating layer 22, and part of the semiconductor layer 21 were positioned over the conductive layer 25.

The insulating layer 43 was formed to cover the conductive layer 23, and the insulating layer 44 was formed over the insulating layer 43. For the insulating layer 43, silicon nitride formed by a PEALD method was used. As the insulating layer 44, a stacked-layer film of a silicon oxide film and a silicon nitride film which were formed by a sputtering method was used. Furthermore, the plug 27 which penetrates the insulating layer 43 and the insulating layer 44 and is in contact with the conductive layer 25 was formed, and the conductive layer 26 was formed in contact with the top surface of the plug 27.

In the above-described manner, Sample 1A which includes the transistor 10 with a channel width of 800 nm and a channel length of 115 nm and the capacitor 30 was fabricated.

### [Cross-Sectional Observation]

With a scanning transmission electron microscope (STEM), a cross-sectional STEM image of the fabricated sample was taken. As the cross-sectional STEM image, a phase contrast image was taken at an acceleration voltage of 200 kV using “HD-2700” produced by Hitachi High-Tech Corporation.

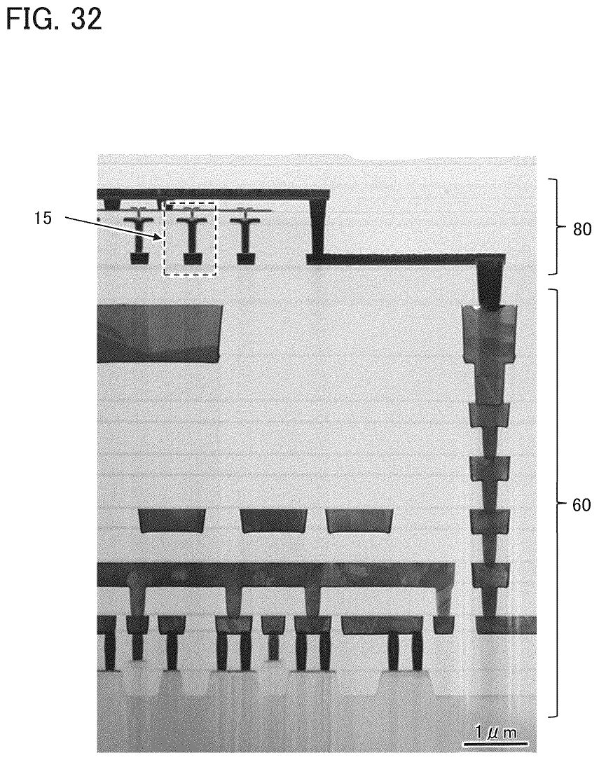

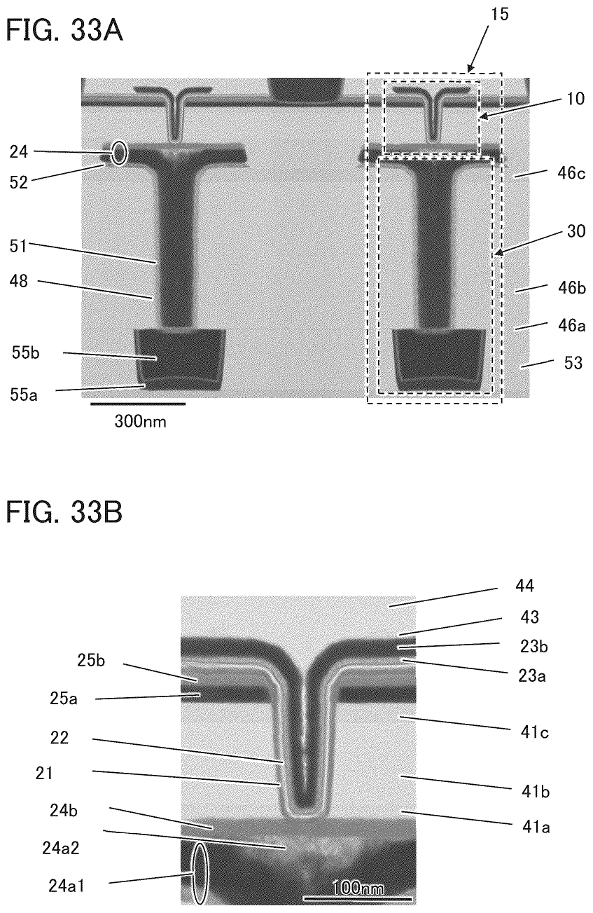

FIG. 32 and FIGS. 33A and 33B are cross-sectional STEM images of Sample 1A. FIG. 32 is a whole cross-sectional view, FIG. 33A is an enlarged view of the memory cell 15, and FIG. 33B is an enlarged view of the transistor 10.

As illustrated in FIG. 32, in the layer 60 in Sample 1A, Si transistors were formed and a multilayer wiring was formed above the Si transistors. The layer 80 including the memory cells 15 was formed over the layer 60.

As illustrated in FIG. 33A, the capacitor 30 and the transistor 10 over the capacitor 30 were formed in the memory cell 15.

As illustrated in FIG. 33B, in the conductive layer 24, the conductive layer 24a2 was formed to fill the depression portion of the conductive layer 24a1. The top surface of the conductive layer 24a1 is significantly uneven and low in planarity. Providing the conductive layer 24a2 increases the planarity of the top surface of the conductive layer 24a2 and the exposed top surface of the conductive layer 24a1. This increases the planarity of the surface where the conductive layer 24b is formed, so that the conductive layer 24b can be formed planar.

The side surfaces of the conductive layer 24 and the insulating layer 52 are substantially aligned with each other, and the conductive layer 24 and the insulating layer 52 are formed with the same pattern. The conductive layer 23 has a depression portion in the slit 20, and the depression portion is filled with the insulating layer 43 and the insulating layer 44. Part of the conductive layer 23, part of the insulating layer 22, and part of the semiconductor layer 21 are formed above the conductive layer 25.

### [Evaluation of Electrical Characteristics of Transistor]

Id-Vgs characteristics of 40 transistors included in Sample 1A were measured. Here, Vgs refers to a voltage between a gate and a source and is hereinafter referred to as a gate voltage Vgs in some cases.

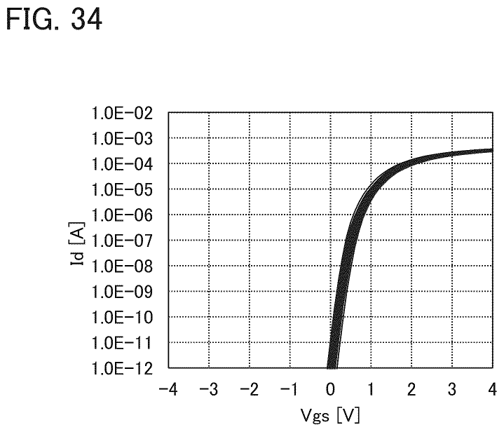

In the measurement, the drain voltage Vds was set to 1.2 V, and the gate voltage Vgs was swept from −4 V to +4 V in increments of 0.1 V. The measurement temperature was room temperature (27° C.). FIG. 34 shows Id-Vgs characteristics of the transistors. In FIG. 34, the vertical axis represents a drain current Id[A] and the horizontal axis represents a gate voltage Vgs [V].

As shown in FIG. 34, it was confirmed that all the transistors included in Sample 1A exhibited favorable electrical characteristics. Specifically, in the transistors included in Sample 1A, the median value of the threshold voltage (Vth) was 0.04 V, the standard deviation of the threshold voltage was 57 mV, the median value of the S value was 76 mV/dec, and the median value of the mutual conductance was 143 μS. Here, the threshold voltage (Vth) is the value of gate voltage Vgs of the time when the drain current Id is 1 pA.

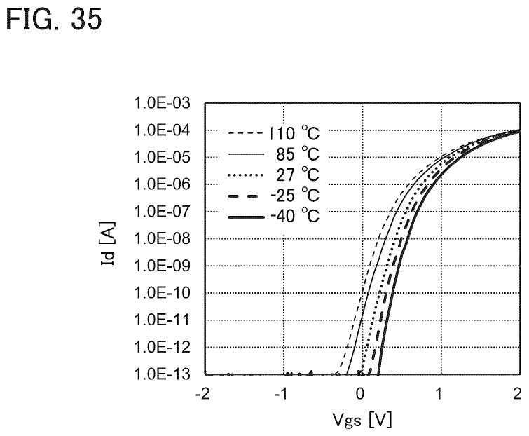

FIG. 35 shows the results of examining the temperature dependence of the Id-Vgs characteristics of the transistors included in Sample 1A. As shown in FIG. 35, the Id-Vgs characteristics were measured at measurement temperatures of −40° C., −25° C., 27° C., 85° C., and 110° C. Note that the lower measurement limit in the measurement of the Id-Vgs characteristics in FIG. 35 is Id=1.0×10⁻¹² A. As shown in FIG. 35, favorable electrical characteristics were observed in a wide temperature range. Under each of the temperature conditions, the off-state current is lower than 1 pA, which is the lower measurement limit. Accordingly, it can be said that the transistors included in Sample 1A each have an extremely lower off-state leakage current than a Si transistor.

### [Evaluation of Off-State Current]

In this section, evaluation of the off-state current of a transistor will be described. Sample 1B was prepared to evaluate the off-state current of a transistor.

Sample 1B includes a device under test (DUT) which is an off-state current evaluation target. Since the off-state current of an OS transistor is extremely low, 19800 transistors connected in parallel were prepared as the DUT in this example.

For the structures of the transistors included in the DUT of Sample 1B, the above-described structure of the transistors included in Sample 1A can be referred to. That is, the DUT has a total channel width of 15.84 mm to amplify the off-state current to a value that can be detected.

As a comparative example, a reference sample including a silicon transistor (Si-FET) with a channel width (W)/channel length (L) of 120 nm/60 nm in a DUT was prepared.

In the evaluation of the off-state current of the transistors included in the DUT of Sample 1B, −2.0 V, 0 V, and 0.8 V were applied to the gate terminal, the source terminal, and the drain terminal, respectively, of the transistors in the DUT. Next, the drain terminal was brought into a floating state, and a change over time in the potential of the drain terminal was observed with a source follower circuit. The off-state current Ioff of the transistors in the DUT was calculated from the parasitic capacitance of the drain terminal measured in advance and the change in the potential of the drain terminal during the measurement time. In the evaluation of the off-state current of the transistor included in the reference sample, 0 V was applied to the gate terminal and the source terminal of the transistor in the DUT, and 1.2 V was applied to the drain terminal thereof.

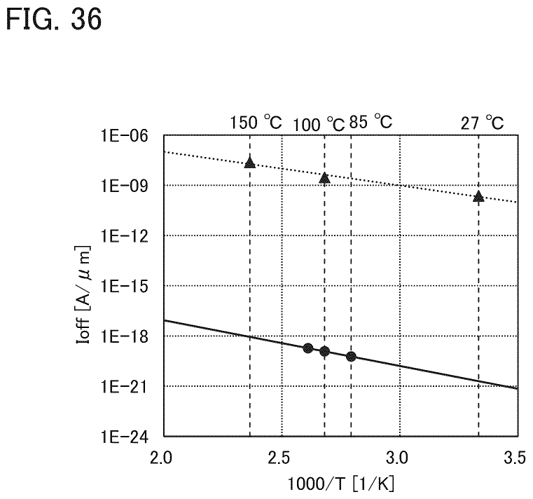

FIG. 36 shows Arrhenius plots of the results of calculating the off-state current of the transistors included in Sample 1B and the reference sample. In FIG. 36, the horizontal axis represents the inverse of temperature T(1000/T)[1/K] and the vertical axis represents the off-state current Ioff per micrometer of channel width [A/μm]. A circular plot represents a calculated off-state current of the transistor included in Sample 1B, and the calculated values of the off-state currents in the environments of 110° C., 100° C., and 85° C. are plotted. A triangular plot represents a calculated off-state current of the silicon transistor, and the calculated values of the off-state currents in the environments of 150° C., 100° C., and 27° C. are plotted. A solid line is a regression straight line obtained from the calculated off-state current values of the transistor included in Sample 1B, and a dashed line is a regression straight line obtained from the calculated off-state current values of the silicon transistor.

As shown in FIG. 36, the off-state current per micrometer of channel width of the transistor included in Sample 1B is 2.0 zA/μm in an environment of 27° C. (extrapolation). This is lower than the off-state current of the silicon transistor in an environment of 27° C. by more than ten orders of magnitude. From the above, it was confirmed that the OS transistor had a low off-state current and small temperature dependence.

### [Estimation of Writing Speed Assuming DOSRAM]

In this section, estimation of the writing speed assuming a ITIC DOSRAM in which a capacitor Cs of 5.9 fF is connected to the transistor 10 of Sample 1A is described.

The wiring WL, the wiring BL, and one electrode of the capacitor Cs are respectively connected to the gate terminal, the drain terminal, and the source terminal of the transistor 10. Here, a node to which the source terminal and the one electrode of the capacitor of 5.9 fF are connected is referred to as a retention node SN.

A period in time from the time when a voltage Vwl for turning on the transistor 10 is supplied to the wiring WL and a voltage of 1.2 V is supplied to the wiring BL to the time when the potential of the retention node SN becomes 0.96 V (80% of the wiring BL's potential of 1.2 V), which is write time t_{w}, was roughly calculated. The write time t_{w} can be expressed by the following formula.

$${t}_{W} = {\int }_{0}^{0.96} \frac{{C}_{S}}{{I}_{SN}} {d V}_{SN} \qquad [ Formula 1 ]$$

Here, I_{SN} is the current value of the retention node SN, V_{SN} is the potential of the retention node SN, and Cs is the capacitance value of the capacitor Cs. For the above calculation, the Id-Vs measurement results of the transistor 10 at −40° C. were used.

The threshold voltage Vth and the S value were calculated from the results of the Id-Vgs measurement of the transistor 10 at 85° C. In the case where the current value in the off state is extrapolated on the basis of the threshold voltage Vth and the S value and the corresponding potential is Voff, the time for the potential of the retention node SN to change by 0.1 V (referred to as data retention time tᵣₑₜ) was calculated.

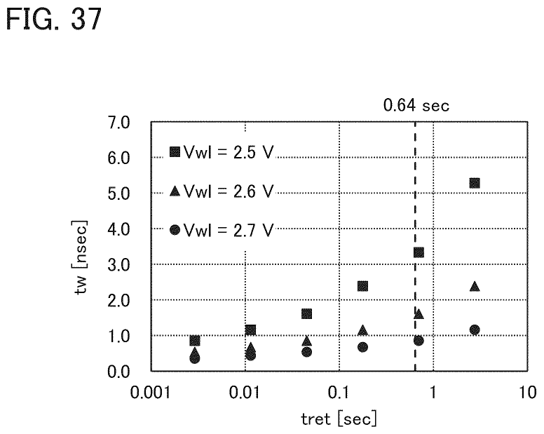

FIG. 37 shows the correlation between the data retention time tᵣₑₜ and the write time t_{w} at voltages Vwl of 2.5 V, 2.6 V, and 2.7 V. In FIG. 37, the horizontal axis represents the data retention time tᵣₑₜ [sec], and the vertical axis represents the write time t_{w} [nsec]. The dashed line in FIG. 37 represents tᵣₑₜ being 0.64 sec.

As shown in FIG. 37, even in the case where the data retention time tᵣₑₜ was 0.64 sec at 85° C., the write time t_{w} at −40° C. was approximately 0.9 to 3.3 nsec. It was confirmed that the writing speed was high even when the assumed data retention time was sufficiently longer than that of a silicon transistor.

The structure, configuration, method, or the like described in this example can be used in an appropriate combination with any of the structures, configurations, methods, or the like described in the other embodiments and the like.

### Example 2

In this example, evaluation results of a DRAM memory cell 800 formed by stacking a transistor TrN, which is a VFET, over a capacitor VC and a DRAM chip 850 formed to include a plurality of the memory cells 800 are described.

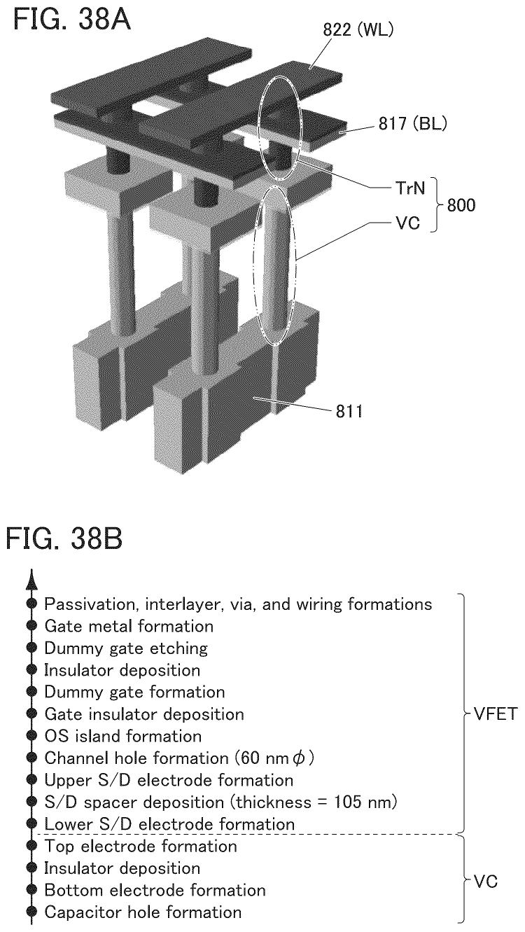

FIG. 38A is a schematic perspective view of a memory cell array in which the memory cells 800 are arranged in a matrix of two rows and two columns. FIG. 38B illustrates steps for forming the memory cell 800. The temperatures in all the steps are lower than or equal to 400° C.

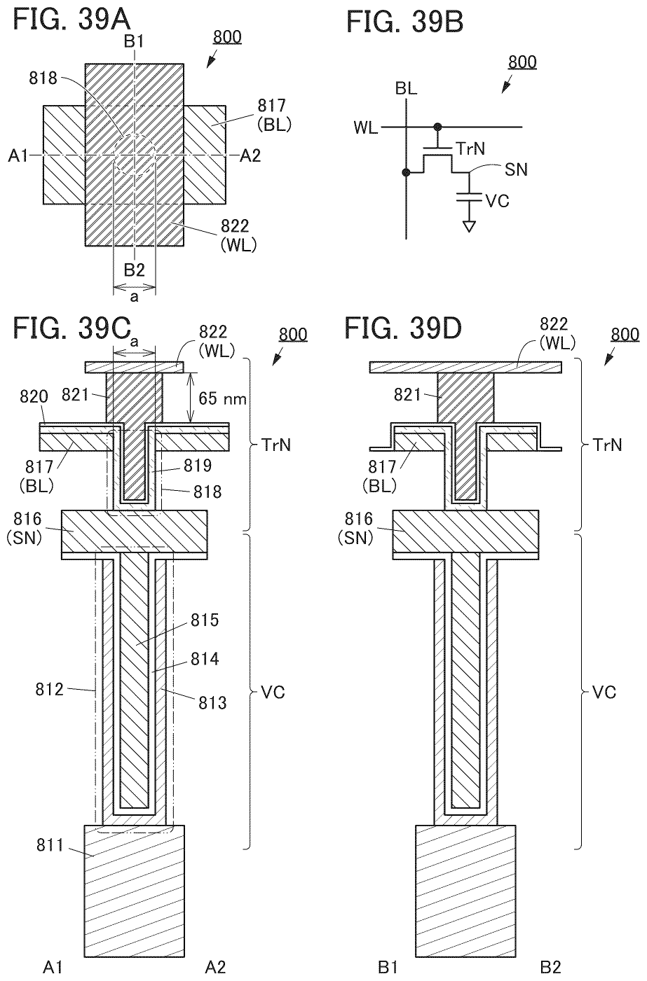

FIG. 39A is a schematic plan view of the memory cell 800, and FIG. 39B is an equivalent circuit diagram of the memory cell 800. FIG. 39C is a schematic cross-sectional view taken along the dashed-dotted line A1-A2 in FIG. 39A. FIG. 39D is a schematic cross-sectional view taken along the dashed-dotted line B1-B2 in FIG. 39A. In the schematic perspective view, the schematic plan view, and the schematic cross-sectional views, some components might not be illustrated for easy understanding of the structure.

As illustrated in the equivalent circuit diagram in FIG. 39B, one of a source and a drain of the transistor TrN is connected to one electrode of the capacitor VC, and the other is connected to a bit line BL. Furthermore, a gate of the transistor TrN is connected to a word line WL. At the time of driving the memory cell 800, a fixed potential is supplied to the other electrode of the capacitor VC.

### [Formation Process of Memory Cell]

The memory cell 800 in which the transistor TrN was stacked over the capacitor VC was formed in the following procedure.

First, a conductive layer 811 was formed over a substrate, an insulating layer was formed over the conductive layer 811, and part of the insulating layer was removed to form an opening 812 in a region overlapping with the conductive layer 811 (Capacitor hole formation). Next, a conductive layer 813, an insulating layer 814, and a conductive layer 815 each including a region overlapping with the inner wall and the bottom portion of the opening 812 were formed in this order (Bottom electrode formation, Insulator deposition, and Top electrode formation). The conductive layer 813 includes a region in contact with the conductive layer 811 at the bottom portion of the opening 812. The conductive layer 815 includes a region overlapping with the conductive layer 813 with the insulating layer 814 provided therebetween. The insulating layer 814 includes a region extending beyond the edge of the opening 812. A region where the conductive layer 815 and the conductive layer 813 overlap with each other with the insulating layer 814 therebetween functions as the capacitor VC.

Next, a conductive layer 816 covering the opening 812 was formed over the insulating layer 814 and the conductive layer 815. The conductive layer 816 includes a region in contact with the conductive layer 815. The conductive layer 816 functions as one of the source electrode and the drain electrode of the transistor TrN, which is a VFET (Lower S/D electrode formation). The conductive layer 816 functions as the retention node SN that retains charge supplied to the memory cell 800.

Next, an insulating layer with a thickness of 105 nm was formed over the conductive layer 816 (S/D spacer deposition (thickness=105 nm)), and a conductive layer 817 was formed over the insulating layer (Upper S/D electrode formation). The thickness of the insulating layer determines the distance between the source electrode and the drain electrode of the transistor TrN, that is, the channel length of the transistor TrN, which is a VFET. The conductive layer 817 functions as the other of the source electrode and the drain electrode of the transistor TrN, which is a VFET. The conductive layer 817 also functions as a bit line BL.

Next, part of the insulating layer and part of the conductive layer 817 were removed, so that an opening 818 with a diameter of 60 nm was formed in a region overlapping with the conductive layer 816 (Channel hole formation (60 nmϕ)). Next, an oxide semiconductor layer 819 including a region overlapping with the inner wall and the bottom portion of the opening 818 was formed (OS island formation). In the transistor TrN, crystalline indium oxide (also referred to as “IO”) was used for the oxide semiconductor layer 819. The oxide semiconductor layer 819 includes a region in contact with the conductive layer 816 and a region in contact with the conductive layer 819.

Note that when the shape of the opening 818 seen in a plan view is assumed to be circular and the diameter is denoted by a, the channel width W of the transistor TrN can be expressed by W=a×pi.

Next, an insulating layer 820 was formed over the oxide semiconductor layer 819 (Gate insulator deposition). The insulating layer 820 includes a region overlapping with the inner wall of the opening 818 with the oxide semiconductor layer 819 therebetween. Next, a sacrificial layer including a region filling the inside of the opening 818 was formed over the opening 818 (Dummy gate formation), and an insulating layer covering the sacrificial layer was formed (Insulator deposition). Next, CMP treatment was performed on the insulating layer to reduce unevenness of the upper portion of the insulating layer and expose the upper portion of the sacrificial layer. Next, the sacrificial layer was removed (Dummy gate etching), so that a conductive layer 821 was formed (Gate metal formation). The conductive layer 821 includes a region overlapping with the oxide semiconductor layer 819 with the insulating layer 820 therebetween inside the opening 818. The conductive layer 821 functions as the gate electrode of the transistor TrN.

Next, a conductive layer 822 which includes a region in contact with the conductive layer 821 and functions as the word line WL was formed over the conductive layer 821. A protective layer, an interlayer insulating layer, a via layer, and the like for preventing entry of an impurity element from the outside were formed above the conductive layer 822 (Passivation, interlayer, via, and wiring formations). In this manner, the memory cell 800 was formed.

In the memory cell 800 described in this example, the distance between the top surface of the insulating layer 820 and the word line WL was set to 65 nm. When the transistor TrN has such a structure in which the gate electrode is pulled up (also referred to as a “GE pulled-up structure”), parasitic capacitance generated between the gate electrode and the other of the source electrode and the drain electrode is reduced. Thus, parasitic capacitance generated between the word line WL and the bit line BL can be reduced.

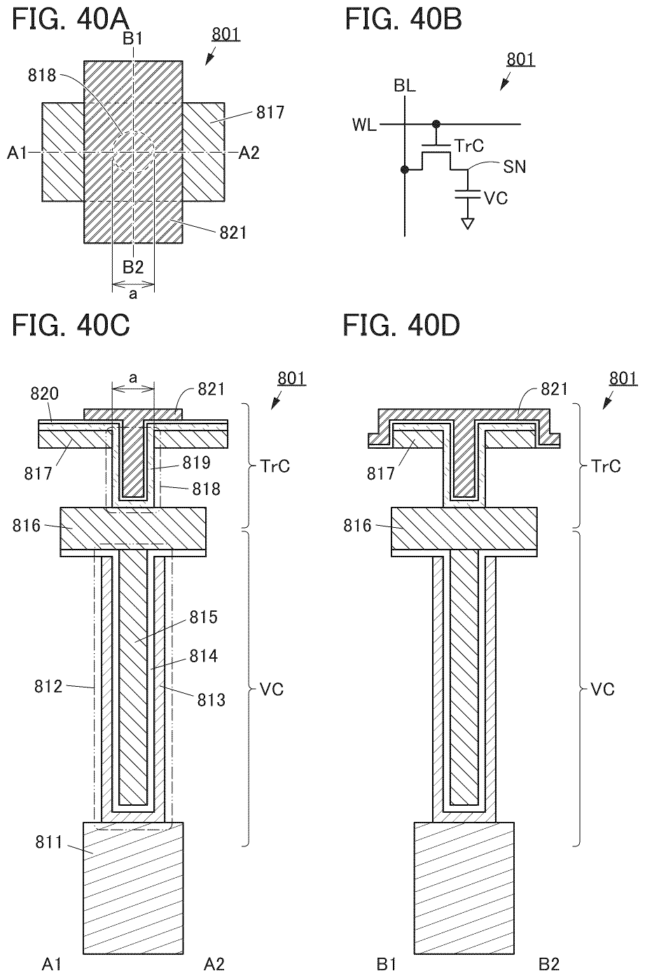

In addition, for comparison with the memory cell 800, a memory cell 801 that does not have the GE pulled-up structure was formed. FIG. 40A is a schematic plan view of the memory cell 800, and FIG. 40B is an equivalent circuit diagram of the memory cell 800. FIG. 40C is a schematic cross-sectional view taken along the dashed-dotted line A1-A2 in FIG. 40A. FIG. 40D is a schematic cross-sectional view taken along the dashed-dotted line B1-B2 in FIG. 40A.

The memory cell 801 has a structure in which a transistor TrC, which is a VFET, is stacked over the capacitor VC. That is, the memory cell 801 has a structure in which the transistor TrN of the memory cell 800 is replaced with the transistor TrC.

The transistor TrC is a VFET similar to the transistor TrN, but formation of a sacrificial layer, formation of an insulating layer over the sacrificial layer, CMP treatment, removal of the sacrificial layer, and formation of the conductive layer 822 functioning as the word line WL are not performed. Thus, in the memory cell 801, the conductive layer 821 also functions as the word line WL. That is, the distance between the top surface of the insulating layer 820 and the word line WL is 0 nm; accordingly, the capacitance generated between the word line WL and the bit line BL is larger than that in the memory cell 800. The transistor TrC has a larger capacitance value between the gate electrode and the other of the source electrode and the drain electrode than the transistor TrN. In other words, the transistor TrC is a transistor having larger parasitic capacitance of the gate electrode than the transistor TrN.

### [Parasitic Capacitance of Transistor]

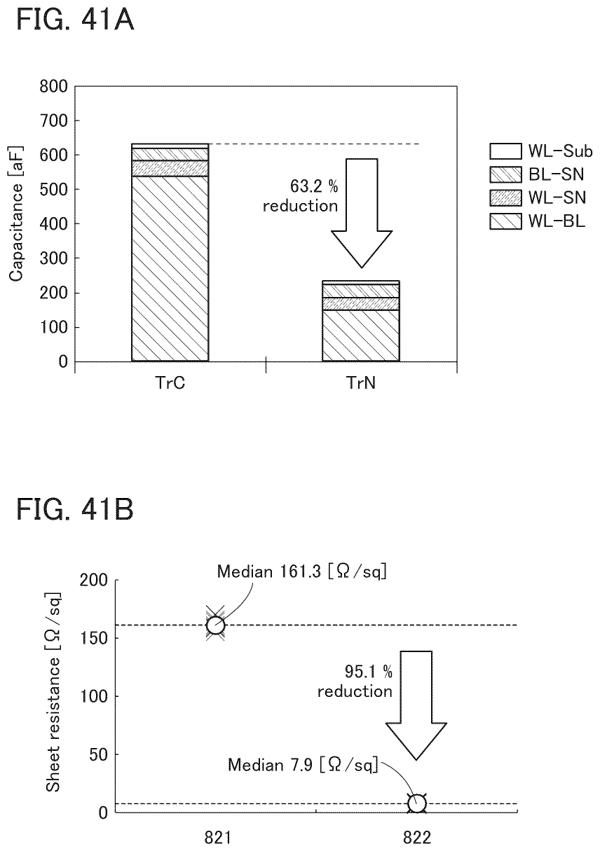

The magnitudes of parasitic capacitances generated in the transistor TrN and the transistor TrC were examined. Samples in which 20000 transistors (the transistors TrN for one sample; the transistors TrC for the other sample) each having a channel length L of 105 nm and a channel width W of 60 nmϕ were connected in parallel were fabricated, and CV measurement was performed. FIG. 41A shows the measurement results of parasitic capacitance, that is, the parasitic capacitance between the gate electrode and the other of the source electrode and the drain electrode (WL-BL), the parasitic capacitance between the gate electrode and the one of the source electrode and the drain electrode (WL-SN), the parasitic capacitance between the source electrode and the drain electrode (BL-SN), and the parasitic capacitance between the gate electrode and the substrate (WL-Sub).

It is found from FIG. 41A that the parasitic capacitance between the gate electrode and the other of the source electrode and the drain electrode (WL-BL) is dominant in both the transistor TrN and the transistor TrC. It is also found that the total parasitic capacitance can be reduced by 63.2% with the use of the GE pulled-up structure.

### [Sheet Resistance of Word Line WL]

FIG. 41B shows measured sheet resistance of the conductive layer 822 functioning as the word line WL of the memory cell 800 and the conductive layer 821 functioning as the word line WL of the memory cell 801. The sheet resistance of the conductive layer 821 was 161.3 Ω/sq. The sheet resistance of the conductive layer 822 was 7.9 Ω/sq., which was 95.1% lower than that of the conductive layer 821. This is because using a low-resistance material for the conductive layer 821 including a region embedded in the opening 818 is difficult in the memory cell 801 not employing the GE pulled-up structure, where the conductive layer 821 serves as both the gate electrode and the word line WL.

Meanwhile, in the memory cell 800 employing the GE pulled-up structure, the conductive layer 822 functioning as the word line WL can be formed after the formation of the conductive layer 821 which is embedded in the opening 818 and functions as the gate electrode. Thus, a low-resistance material can be used for the conductive layer 822.

### [Id-Vgs Characteristics of Transistors]

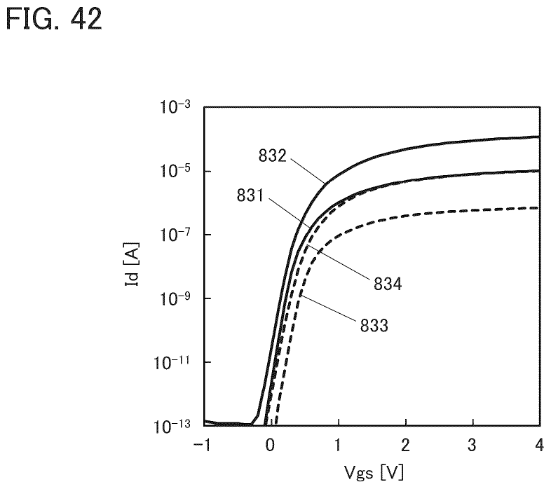

Next, the Id-Vgs characteristics of the transistors TrN were measured in a room temperature environment. FIG. 42 shows the measurement results. In FIG. 42, the horizontal axis represents gate voltage (Vgs) and the vertical axis represents drain current (Id).

The channel length L and the channel width of the transistor TrN used for the measurement are 105 nm and 60 nmϕ, respectively. In FIG. 42, characteristics 831 and characteristics 832 are Id-Vgs characteristics of the transistor TrN using IO for the oxide semiconductor layer 819. Furthermore, characteristics 833 and characteristics 834 are Id-Vgs characteristics of the transistor TrN using indium-gallium-zinc oxide with a c-axis aligned crystal (CAAC) structure (also referred to as “CAAC-IGZO”) for the oxide semiconductor layer 819. The characteristics 831 and 833 are Id-Vgs characteristics of the time when the drain voltage (Vds) is 0.1 V, and the characteristics 832 and 834 are Id-Vgs characteristics of the time when Vds is 1.2 V.

From the Id-Vgs characteristics, the transistor TrN using IO for the oxide semiconductor layer 819 had a threshold voltage (Vth) of 0.4 V and showed enhancement characteristics. The transistor TrN using IO for the oxide semiconductor layer 819 had a mutual conductance (gm) of 47.6 μS, a subthreshold swing value (SS) of 91.0 mV/dec, and an on-state current of the time when the gate voltage exceeded Vth by 1 V of 112.2 μA/μm.

The transistor TrN using CAAC-IGZO for the oxide semiconductor layer 819 had a Vth of 0.45 V and showed enhancement characteristics. The transistor TrN using CAAC-IGZO for the oxide semiconductor layer 819 had a gm of 4.7 μS, an SS value of 91.0 mV/dec, and an on-state current of the time when Vgs exceeded Vth by 1 V of 13.5 μA/μm.

The off-state currents of both types of the transistors TrN were lower than or equal to the lower measurement limit (1×10⁻¹³ A). The on-state current of the time when the gate voltage exceeded Vth by 1 V of the transistor TrN using IO for the oxide semiconductor layer 819 was 8.3 times as high as that of the transistor TrN using CAAC-IGZO for the oxide semiconductor layer 819.

### [Temperature Dependence of Gm and Vth]

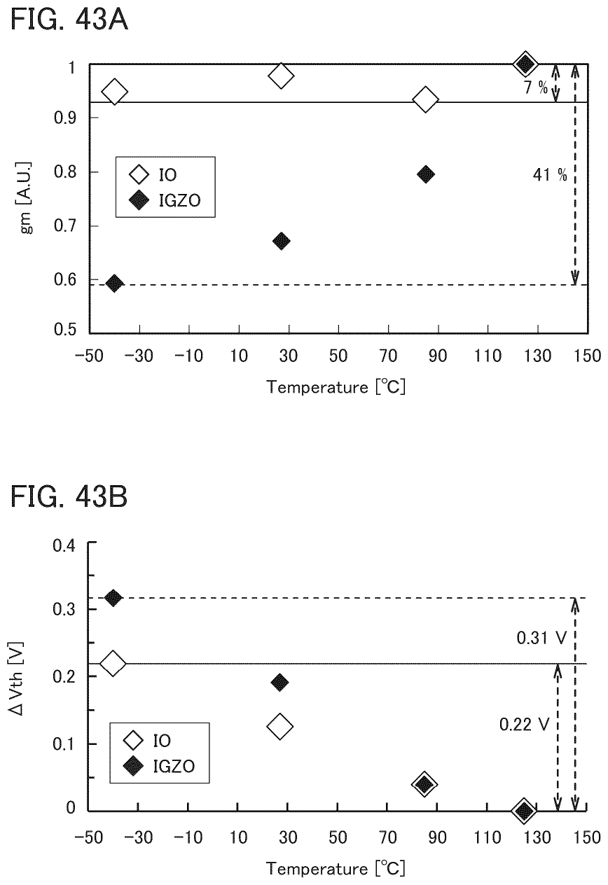

The temperature dependence of gm and Vth of each of the transistor TrN using IO for the oxide semiconductor layer 819 and the transistor TrN using CAAC-IGZO for the oxide semiconductor layer 819 was evaluated. FIG. 43A shows the temperature dependence of gm of each transistor. In FIG. 43A, the horizontal axis represents temperature, and the vertical axis represents the relative gm value with the assumption that the maximum value of the measurement result is 1.

The gm change rate due to the temperature change was 7% in the transistor TrN using IO for the oxide semiconductor layer 819, and 41% in the transistor TrN using CAAC-IGZO for the oxide semiconductor layer 819.

FIG. 43B shows temperature dependence of the amount of Vth change in each transistor. In FIG. 43B, the horizontal axis represents temperature, and the vertical axis represents the amount of Vth change (ΔVth) relative to Vth at 125° C.

The amount of Vth change due to the temperature change was 0.22 V in the transistor TrN using IO for the oxide semiconductor layer 819 and 0.31 V for the transistor TrN using CAAC-IGZO for the oxide semiconductor layer 819.

It was found from FIGS. 43A and 43B that the temperature dependence of both gm and Vth was smaller in the transistor TrN using IO for the oxide semiconductor layer 819 than in the transistor TrN using CAAC-IGZO for the oxide semiconductor layer 819.

### [Arrhenius Plots of Leakage Current]

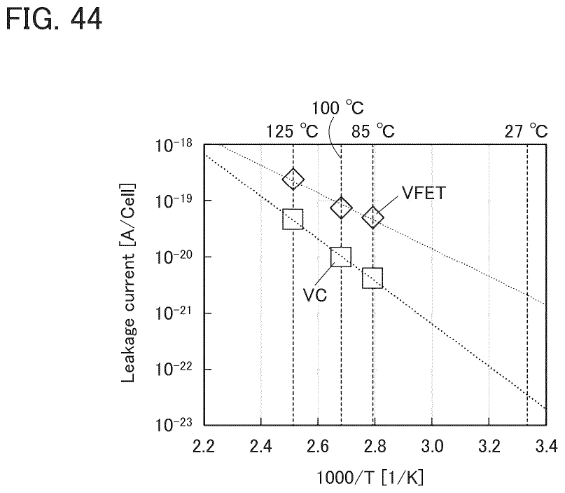

FIG. 44 shows Arrhenius plots of the leakage current of the transistor TrN (off-state current) and the leakage current of the capacitor VC per memory cell 800. The measurement was performed using a circuit specially designed to measure the leakage current. In the 125° C. environment, the leakage current of the transistor TrN was 238 zA/Cell, and the leakage current of the capacitor VC was as low as 46 zA/Cell.

### [Simulation Results of Read Time and Write Time]

Data read time (read time) and data write time (write time) of the memory cell 800 and the memory cell 801 were investigated by SPICE simulation.

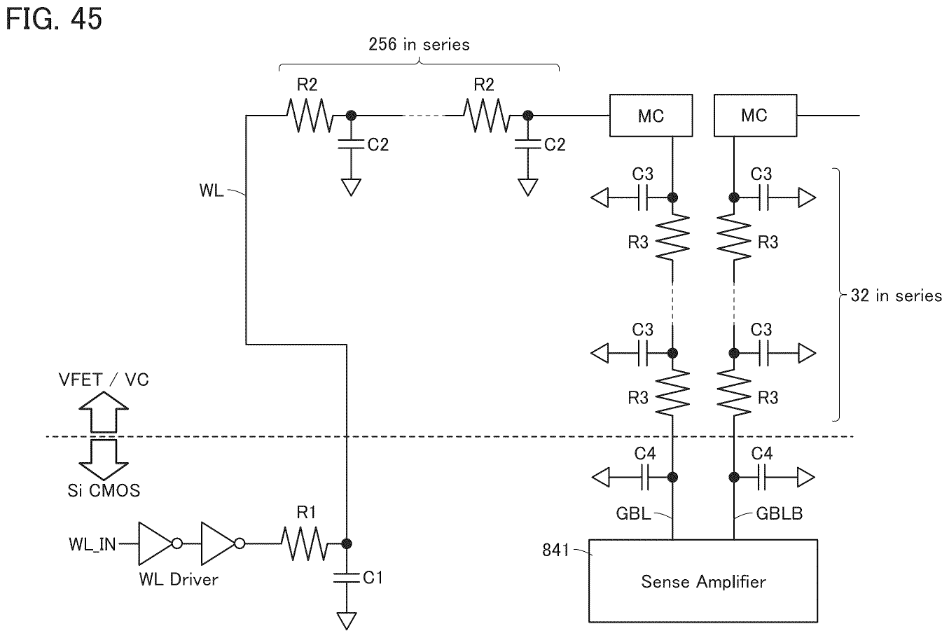

FIG. 45 illustrates a circuit structure used in the simulation. In the simulation, a word line WL driver (WL Driver) and a sense amplifier circuit (Sense Amplifier) 841, which are formed using a Si CMOS, and a structure in which the capacitor VC and the transistor TrN, which is a VFET, were combined (VFET/VC) were assumed. Note that a word line selection signal WL_IN is input to the input of the word line WL driver.

The simulation was performed assuming that a memory cell array includes memory cells arranged in 32 rows and 256 columns. Specifically, parasitic capacitances C3 and parasitic resistances R3 of 32 memory cells MC were added (32 in series) to each of the bit line BL and an inverted bit line BLB of one memory cell MC (the memory cell 800 or the memory cell 801) composed of a VFET and a VC. In addition, parasitic capacitances C2 and parasitic resistances R2 of 256 word lines WL were added (256 in series) to the word line WL of one memory cell MC.

In addition, parasitic capacitance C4 of the sense amplifier circuit 841 was added to each of the bit line BL and the inverted bit line BLB. In addition, parasitic capacitance C1 and parasitic resistance R1 of an output portion of the word line WL driver were added to the word line WL of one memory cell MC.

The parasitic capacitance of the memory cell MC was calculated through three-dimensional electromagnetic field analysis of the layer structure and layout of the formed memory cell 800. For the parasitic resistance of the memory cell MC, the measurement results shown in FIG. 41B were referred to.

The simulation was performed on the transistor TrN having the GE pulledup structure (w/pull up) and the transistor TrC not having the GE pulled-up structure (w/o pull up) for both of the case where the oxide semiconductor layer 819 is IO and the case where the oxide semiconductor layer 819 is CAAC-IGZO.

Table 3 and Table 4 show a variety of parameters used in the simulation.

TABLE 3

VFET structure

| | | | Rs of WL |
|---|---|---|---|
| Type | VFET gate | VFET channel | [Ω/sq] |
| 1 | Gate w/o pull up | CAAC-IGZO | 161.3 |
| 2 | Gate w/o pull up | IO | 161.3 |
| 3 | Gate w/pull up | CAAC-IGZO | 161.3 |
| 4 | Gate w/pull up | CAAC-IGZO | 7.9 |
| 5 | Gate w/pull up | IO | 7.9 |

TABLE 4

| | Si CMOS | | | VFET/VC | | | |
|---|---|---|---|---|---|---|---|
| | R1 | C1 | C4 | R2 | C2 | R3 | C3 |
| Type | [Ω] | [fF] | [fF] | [Ω/Cell] | [fF/Cell] | [Ω/Cell] | [fF/Cell] |
| 1 | 340 | 37 | 4 | 302.5 | 0.38 | 25.9 | 0.36 |
| 2 | 340 | 37 | 4 | 302.5 | 0.38 | 25.9 | 0.36 |
| 3 | 340 | 37 | 4 | 302.5 | 0.15 | 25.9 | 0.16 |
| 4 | 340 | 37 | 4 | 14.8 | 0.15 | 25.9 | 0.16 |
| 5 | 340 | 37 | 4 | 14.8 | 0.15 | 25.9 | 0.16 |

In the simulation, the sheet resistance of the word line WL (Rs of WL) was set to two levels, 161.3 Ω/sq. and 7.9 Ω/sq. The parasitic resistance R1 was set to 340 $2, the parasitic capacitance C1 was set to 37 fF, and the parasitic capacitance C4 was set to 4 fF. In addition, the parasitic resistance R2 was set to two levels, 302.5 Ω/Cell and 14.8 Ω/Cell, and the parasitic capacitance C2 was set to two levels, 0.38 fF/Cell and 0.15 fF/Cell. The parasitic resistance R1 was set to 25.9 Ω/Cell. In addition, the parasitic capacitance C3 was set to two levels, 0.36 fF/Cell and 0.16 fF/Cell. The simulation was performed with combinations of parameters shown as types 1 to 5 in Tables 3 and 4.

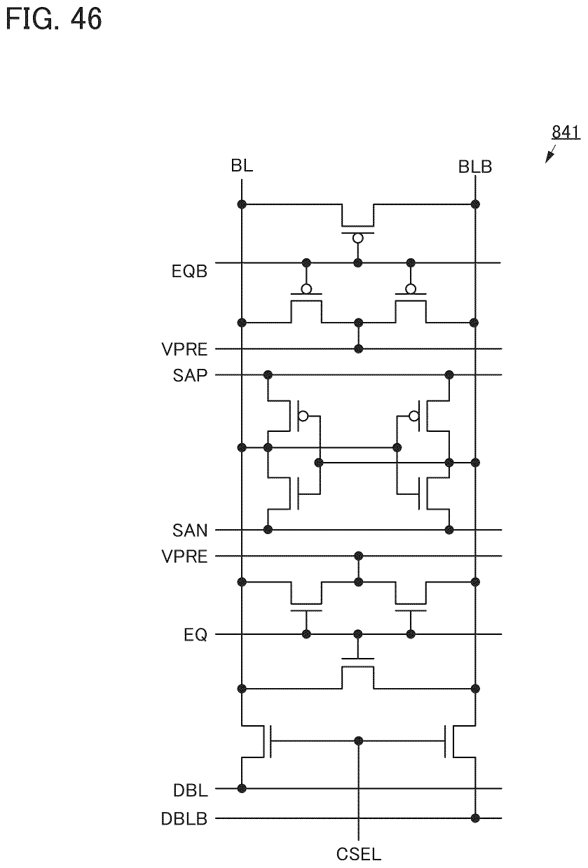

FIG. 46 is a circuit diagram of the sense amplifier circuit 841. In addition to the bit line BL and the inverted bit line BLB, a wiring EQB, a wiring SAP, a wiring SAN, a wiring VPRE, a wiring EQ, a wiring DBL, a wiring DBLB, and a wiring CSEL are connected to the sense amplifier circuit 841.

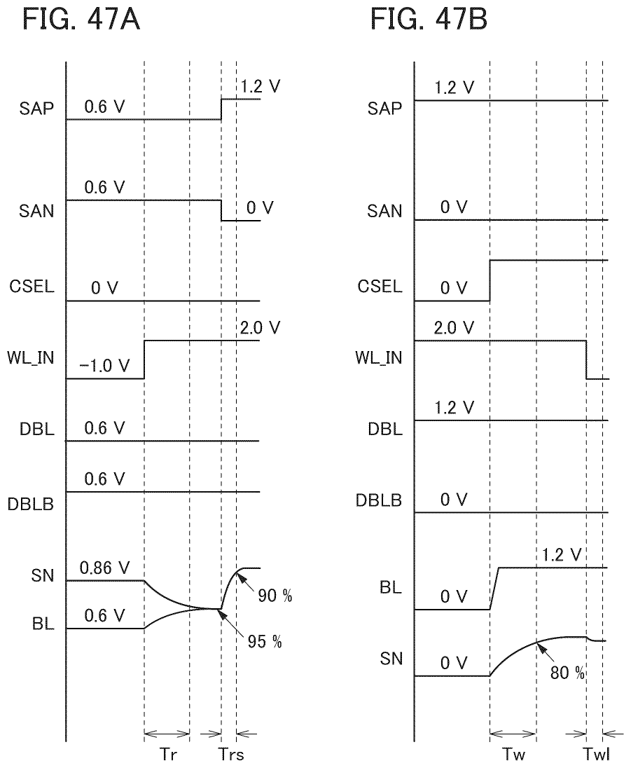

FIG. 47A is a timing chart of a data reading operation of the memory cell 800 and the memory cell 801. FIG. 47B is a timing chart of a data writing operation of the memory cell 800 and the memory cell 801.

In FIG. 47A, time Tr is the time required for charge sharing between the retention node SN of the selected memory cell and the bit line BL. Time Trs is the time for the sense amplifier circuit 841 to amplify the voltage of the bit line BL. In this example, read time is defined as the sum of the time Tr and the time Trs.

In FIG. 47B, time Tw is the time from writing of the voltage of the wiring DBL to the retention node SN of the memory cell 800 or the memory cell 801 until the voltage of the retention node SN reaches 80% of the voltage of the wiring DBL. Time Twl is a fall time of WL_IN. In this example, the write time is defined as the sum of the time Tw and the time Twl.

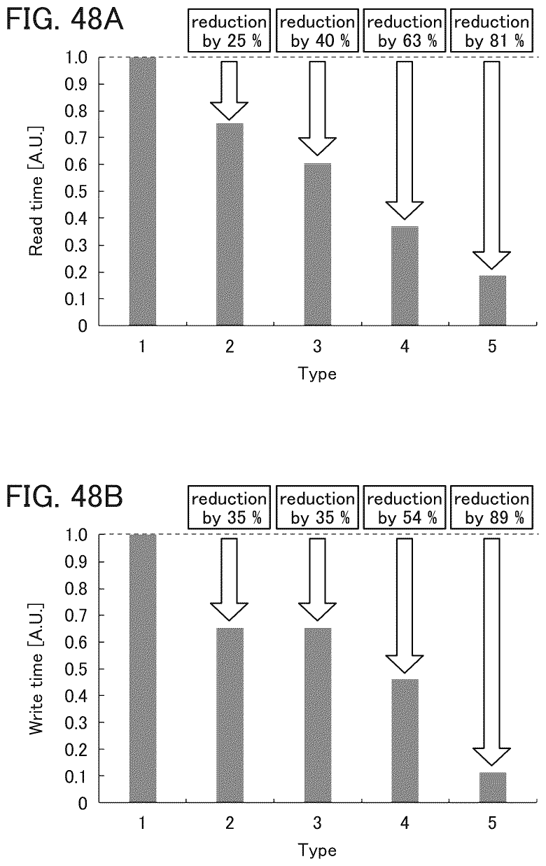

FIG. 48A shows simulation results of read time. It can be seen that the read times of the type 2, type 3, type 4, and type 5 are respectively reduced by 25%, 40%, 63%, and 81% from the read time of the type 1.

FIG. 48B shows simulation results of write time. It can be seen that the write times of the type 2 and type 3 are each reduced by 35% from the write time of the type 1, and the write times of the type 4 and type 5 are respectively reduced by 54% and 89% from the write time of the type 1.

The simulation results show that the use of the GE pulledup structure has an effect of shortening the processing time of both the read time and the write time. In addition, the effect of using IO for the oxide semiconductor layer 819 on shortening the processing time of both the read time and the write time was confirmed. Furthermore, it was confirmed that using both the GE pulled-up structure and IO further enhances the effect of shortening the processing time of both the read time and the write time. That is, it was found that the use of IO for the oxide semiconductor layer 819 and the use of the GE pulled-up structure improve the access speed of the DRAM memory cell.

### [DRAM Chip]

The DRAM chip 850 in which the memory cell 800 having the GE pulled-up structure was stacked over a Si CMOS was fabricated. The channel length L and the channel width W of the transistor TrN included in the memory cell 800 are 105 nm and 60 nmϕ, respectively, and IO was used for the oxide semiconductor layer 819. The sheet resistance of the word line WL was set to 7.9 Ω/sq. In the capacitor VC, the diameter of the opening 812 was 80 nmϕ and the capacitance value was set to 2.3 fF.

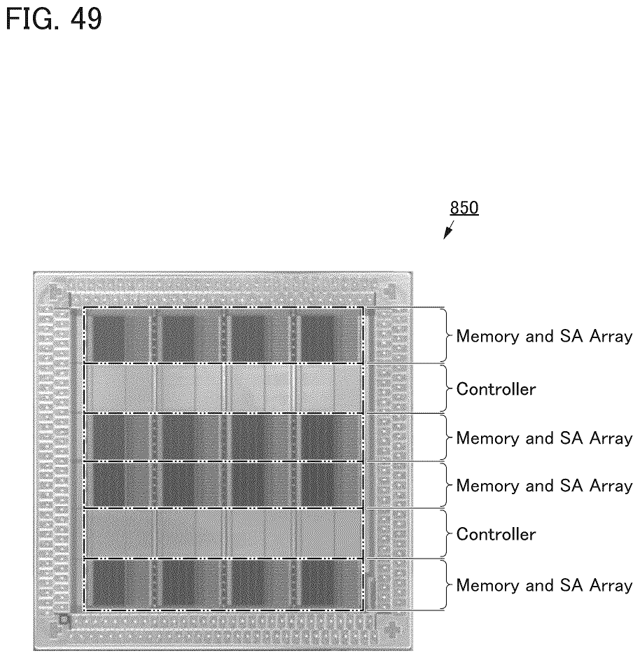

FIG. 49 shows an external-view photograph of the DRAM chip 850. The outer dimensions of the fabricated DRAM chip 850 is 4 mm×4 mm. The DRAM chip 850 includes a sense amplifier array (Memory and SA Array) including a plurality of memory cell arrays and a plurality of sense amplifier circuits, and a control circuit (Controller) for controlling their operations.

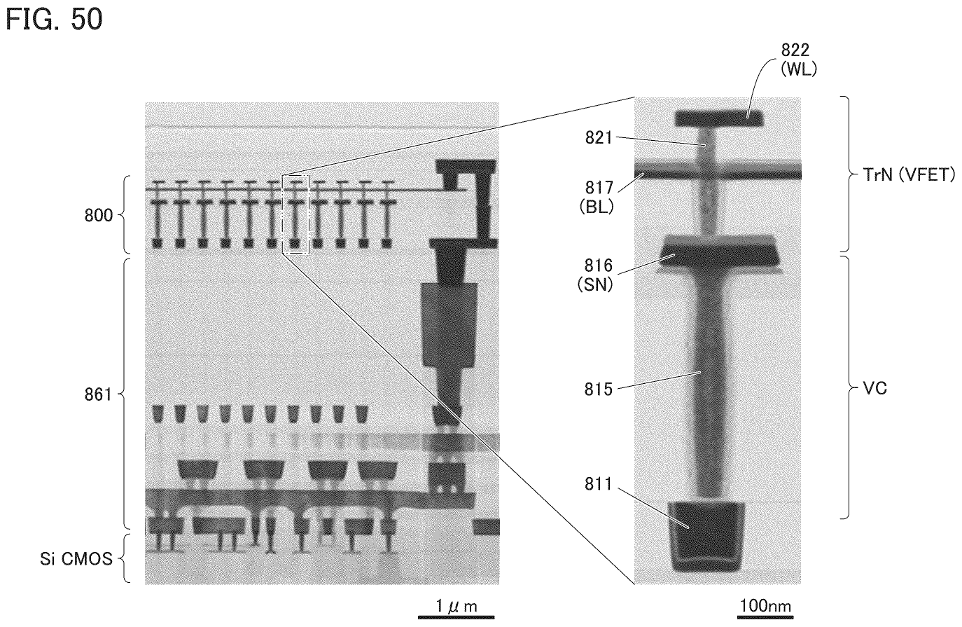

FIG. 50 shows a cross-sectional STEM image of part of the fabricated DRAM chip 850. The fabricated DRAM chip 850 has a structure in which a Si CMOS with a technology node of 55 nm is used in front end of line (FEOL), a wiring layer 861 including six conductive layers is formed thereover, and one layer of VFET/VC, which is the memory cell 800, is formed thereover.

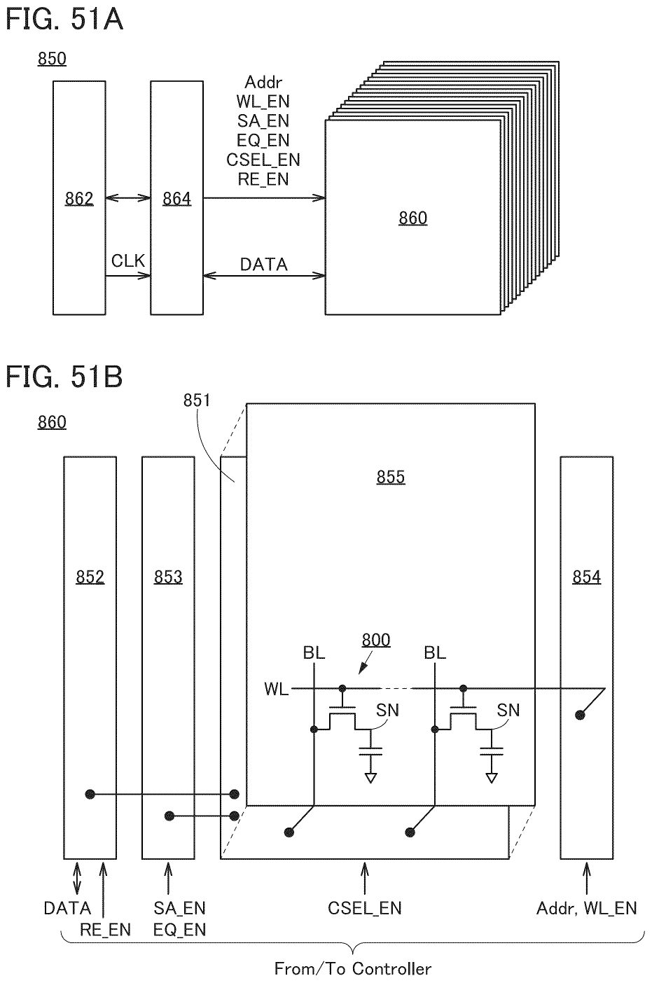

FIGS. 51A and 51B are block diagrams of the fabricated DRAM chip 850. As illustrated in FIG. 51A, the DRAM chip 850 includes an input/output circuit 862, a control circuit 864, and 16 banks 860. As illustrated in FIG. 51B, each of the banks 860 includes a sense amplifier array 851 including a plurality of sense amplifier circuits, a memory cell array 855 including a plurality of the memory cells 800, a data detection amplifier circuit 852, a sense amplifier driver circuit 853, and a word line driver circuit 854. The sense amplifier array 851, the data detection amplifier circuit 852, the sense amplifier driver circuit 853, the word line driver circuit 854, the input/output circuit 862, the control circuit 864, and the like are formed using the Si CMOS in FEOL. The memory cell array 855 including the plurality of memory cells 800 is formed above the Si CMOS. Although FIG. 51A illustrates the structure in which the control circuit 864 is provided outside the banks 860, it is also possible to provide part or whole of the control circuit 864 inside the banks 860.

In addition to the input or output data (DATA), a data output control signal (a signal RE_EN), a sense amplifier control signal (a signal SA_EN), a precharge control signal (a signal EQ_EN), a column selection control signal (a signal CSEL_EN), memory address data Addr, a word line control signal (a signal WL_EN), and the like are supplied to the bank 860 through the control circuit 864 (From/To Controller). The control circuit 864 can output the signals in synchronization with a clock signal (a signal CLK).

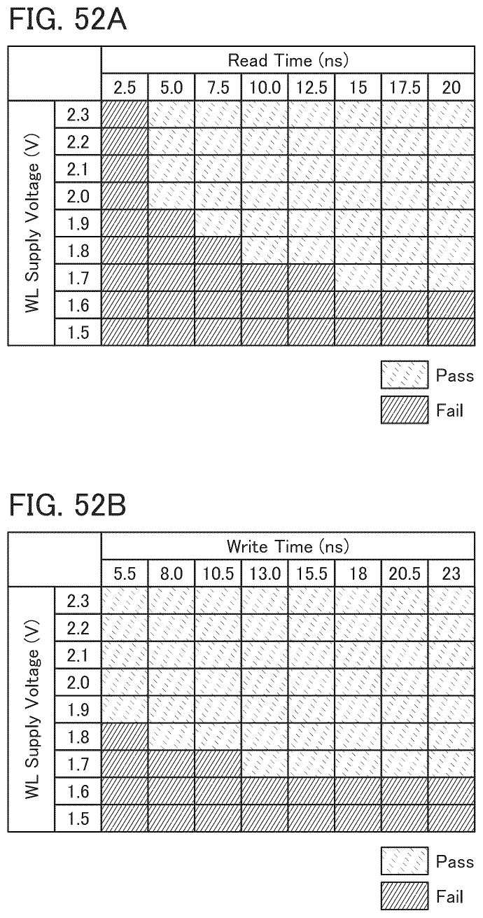

FIG. 52A shows a shmoo plot of read time, where the voltage supplied to the word line WL (WL Supply Voltage) was changed from 1.5 V to 2.3 V in increments of 0.1 V and the read time was changed from 2.5 ns to 20 ns in increments of 2.5 ns under a room-temperature environment.

In the shmoo plot of FIG. 52A, a pass ratio of the DRAM chip 850 higher than or equal to 99% is regarded as Pass, and a pass ratio lower than 99% is regarded as Fail. Note that the pass ratio is the percentage of memory cells that has achieved data reading or data writing in all the evaluation-targeted memory cells.

It was found from FIG. 52A that a stable data reading operation can be achieved when the voltage supplied to the word line WL is higher than or equal to 2.0 V and the read time is longer than or equal to 5.0 ns.

FIG. 52B shows a shmoo plot of write time, where the voltage supplied to the word line WL was changed from 1.5 V to 2.3 V in increments of 0.1 V and the write time was changed from 5.5 ns to 23 ns in increments of 2.5 ns under a room-temperature environment.

In the shmoo plot of FIG. 52B, a pass ratio of the DRAM chip 850 higher than or equal to 99% under a room-temperature environment is regarded as Pass, and a pass ratio lower than 99% under a room-temperature environment is regarded as Fail.

It was found from FIG. 52B that a stable data writing operation can be achieved when the voltage supplied to the word line WL is higher than or equal to 1.9 V and the write time is longer than or equal to 5.5 ns.

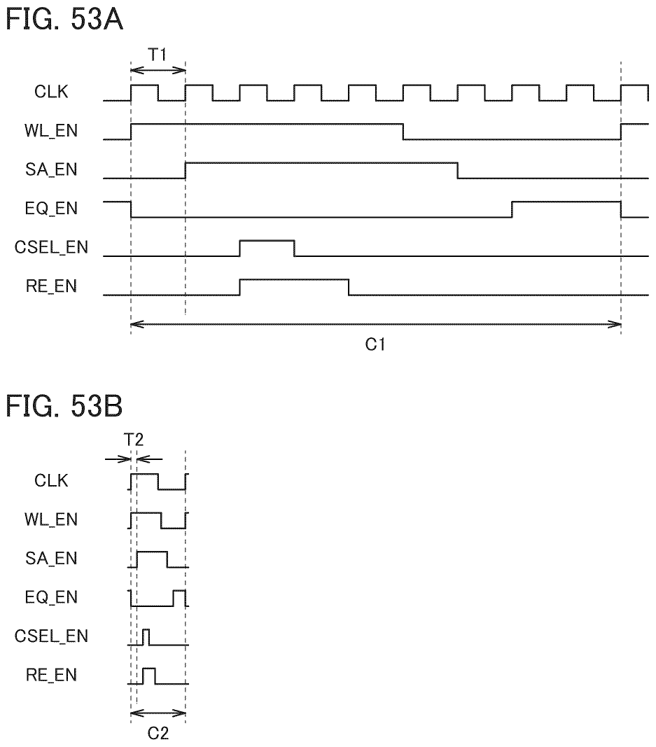

Here, FIG. 53A shows a timing chart of the reading operation in the read time measurement in FIG. 52A. As illustrated in FIG. 53A, in the reading operation, the signal WL_EN, the signal SA_EN, the signal EQ_EN, the signal CSEL_EN, and the signal RE_EN were input to the corresponding circuits in the banks 860. The signals were controlled in synchronization with the signal CLK. Thus, the rise and fall of each signal were performed at the rise timing of the signal CLK.

As shown in FIG. 53A, the number of cycles taken in one reading operation C1 is nine. Here, the read time in this reading operation (hereinafter referred to as read time T1) is defined as the time from when the signal WL_EN is turned on to when the signal SA_EN is turned on. As illustrated in FIG. 53A, the read time T1 corresponds to one cycle of the signal CLK. In the above reading operation, the frequency of the signal CLK was 200 MHZ, so that the read time T1 was 5 ns.

In the case where the reading operation is performed without synchronization with the signal CLK, the read time can be further shortened. For example, the signal WL_EN, the signal SA_EN, the signal EQ_EN, the signal CSEL_EN, and the signal RE_EN can be generated on the basis of a delayed signal of the signal CLK. FIG. 53B is a timing chart of the reading operation of this case. As illustrated in FIG. 53B, although the pulse widths of the signal WL_EN, the signal SA_EN, the signal EQ_EN, the signal CSEL_EN, and the signal RE_EN are smaller than those of the signals illustrated in FIG. 53A, the on/off order is the same as that in FIG. 53A. Thus, the number of cycles taken in one reading operation C2 in FIG. 53B is one. In this manner, the read time T2 can be shorter than the read time T1.

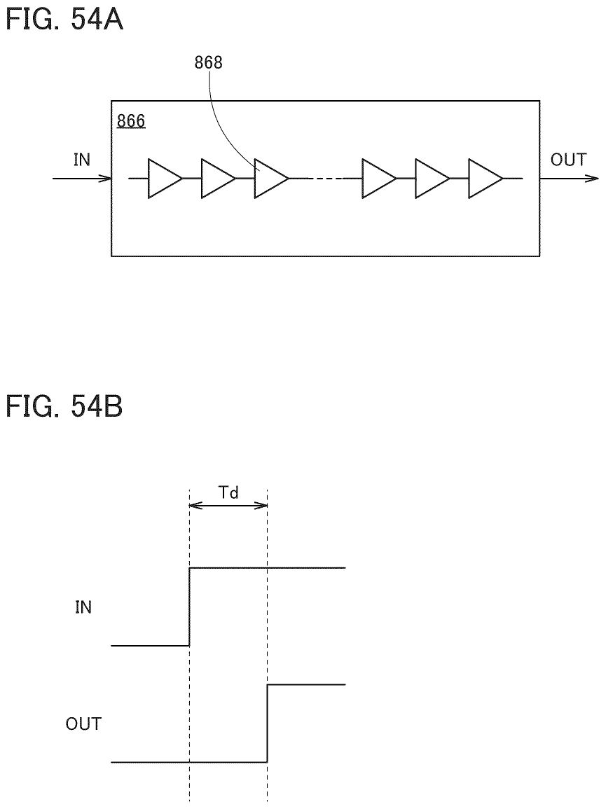

In order to delay the signal CLK, a delay circuit 866 illustrated in FIG. 54A can be used. As illustrated in FIG. 54A, the delay circuit 866 includes a plurality of buffer circuits 868 connected in series. A multiple stages of the buffer circuits 868 can be connected to each other using a multiplexer or the like.

As illustrated in FIG. 54B, a signal IN input to the delay circuit 866 passes through the multiple stages of buffer circuits 868 and is output as a signal OUT that is delayed by a delay time Td. The delay time Td of the signal OUT can be adjusted by appropriately selecting the number of stages of buffer circuits. In this manner, the signal WL_EN, the signal SA_EN, the signal EQ_EN, the signal CSEL_EN, and the signal RE_EN illustrated in FIG. 53B can be generated on the basis of the signal IN and the signal OUT delayed by the adjusted delay time Td.

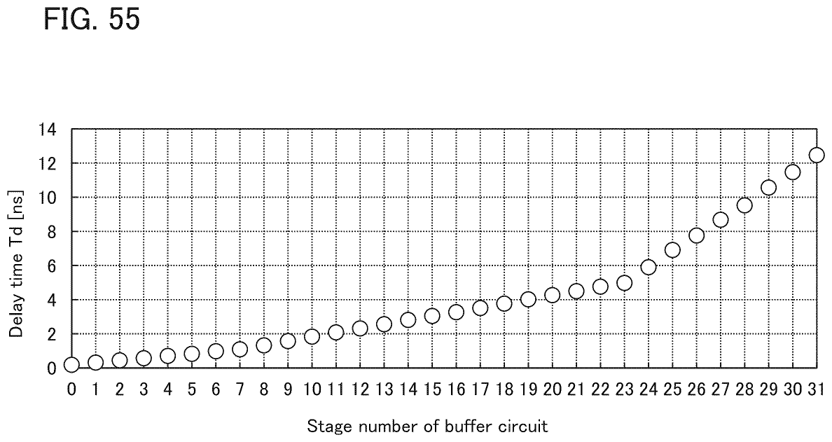

FIG. 55 shows the results of SPICE simulation performed on the delay circuit 866 including 31 stages of the buffer circuits 868. In FIG. 55, the horizontal axis represents the stage number of buffer circuit, and the vertical axis represents the delay time Td [ns]. Note that not all the buffer circuits 868 have the same delay time, and the buffer circuits 868 having different delay times are also included.

As illustrated in FIG. 55, by setting the number of stages of the buffer circuits 868 to 1 to 31, the delay time Td is adjusted from approximately 0.2 ns to approximately 12 ns. Thus, the on/off of each signal can be accurately controlled as illustrated in FIG. 53B.

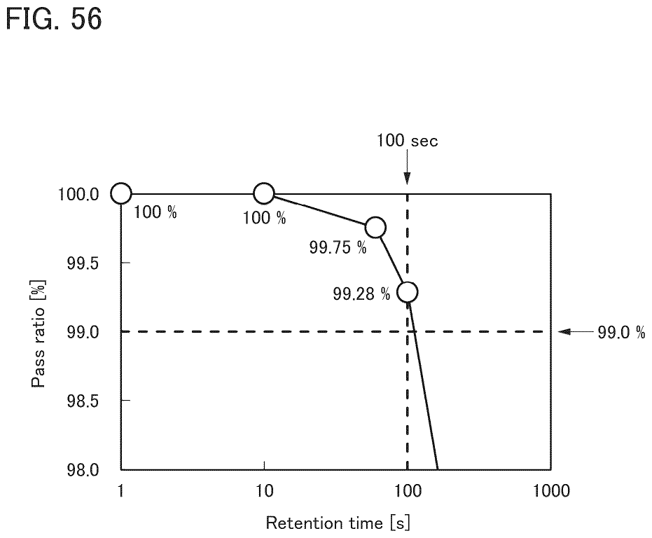

FIG. 56 shows measurement results of data retention time of the DRAM chip 850 in a 125° C. environment. In FIG. 56, the horizontal axis represents the logarithm of retention time. The vertical axis represents the pass ratio which indicates the percentage of memory cells that keep retaining data in all the evaluation-targeted memory cells.

The measurement was performed such that adjacent memory cells retain different one-bit data (data 1 and data 0). The fabricated DRAM chip 850 maintained a pass ratio of higher than 99% even after a retention time of 100 s elapsed in a 125° C. environment. The retention time of 100 s is approximately 1563 times as long as 64 ms, which is the refresh cycle of a general DRAM. Thus, the fabricated DRAM chip 850 can reduce refresh cycles and can reduce standby power. The fabricated DRAM chip 850 was found to be a memory device capable of high-speed access and long-term data retention.

Table 5 shows performance of the fabricated DRAM chip 850.

TABLE 5

| | |
|---|---|
| 3D integration | Monolithic stacking |
| Technology | 60 nm (OS VFET)/55 nm (Si) |
| Memory supply voltage | 3 V (Mem.), 1.2 V (Logic) |
| Memory cell structure | 1T1C |
| Cell size [μm²] | 0.09 |
| Data retention | >100 sec @ 125° C. |
| Write time | 5.5 ns |
| Read time | 5 ns |
| W/L | 60 nmφ/105 nm |
| Ion [μA/μm] | 112.2 |
| Ioff [A/μm] | 1.26 × 10⁻¹⁸ @ 125° C. |
| Vth [V] | 0.4 |
| SS [mV/dec] | 83.8 |
| gm [μS] | 47.6 |
| Vgs/Vds [V] | (Vth + 1)/1.2 |

The structure, configuration, method, or the like described in this example can be used in an appropriate combination with any of the structures, configurations, methods, or the like described in the other embodiments and the like.

This application is based on Japanese Patent Application Serial No. 2024-111322 filed with Japan Patent Office on Jul. 10, 2024 and Japanese Patent Application Serial No. 2024-213737 filed with Japan Patent Office on Dec. 6, 2024, the entire contents of which are hereby incorporated by reference.

What is claimed is:

1. A semiconductor device comprising:
a first insulating layer comprising a first opening;
a second insulating layer comprising a slit over the first insulating layer;
a capacitor comprising:
a first conductive layer along the first opening; and
a second conductive layer over the first conductive layer and in the first opening; and
a transistor over the capacitor, the transistor comprising:
the second conductive layer serving as one of a source electrode and a drain electrode;
a semiconductor layer in contact with a side surface of the second insulating layer in the slit and a top surface of the second conductive layer;
a gate insulating layer over the semiconductor layer; and
a gate electrode over the gate insulating layer,
wherein the semiconductor layer, the gate insulating layer, and the gate electrode are in the slit of the second insulating layer,
wherein the second conductive layer comprises a first layer, a second layer over the first layer, and a third layer over the second layer,
wherein a top surface of the first layer comprises a depression portion, and
wherein the second layer is in the depression portion.

2. The semiconductor device according to claim 1, wherein the top surface of the first layer is substantially level with a top surface of the second layer.

3. The semiconductor device according to claim 2, wherein a bottom surface of the third layer is in contact with the top surface of the first layer and the top surface of the second layer.

4. The semiconductor device according to claim 1, further comprising a third insulating layer between the first conductive layer and the second conductive layer,
wherein a side surface of the third insulating layer is aligned with a side surface of the first layer and a side surface of the third layer.

5. The semiconductor device according to claim 1,
wherein the semiconductor layer comprises a first metal oxide,
wherein the third layer comprises a second metal oxide, and
wherein each of the first metal oxide and the second metal oxide comprises indium.

6. The semiconductor device according to claim 1,
wherein the first layer comprises tungsten, and
wherein the second layer comprises titanium nitride.

7. A semiconductor device comprising:
a first insulating layer comprising a first opening;
a second insulating layer comprising a slit over the first insulating layer;
a capacitor comprising:
a first conductive layer along the first opening;
a third insulating layer over the first conductive layer; and
a second conductive layer over the third insulating layer and in the first opening; and
a transistor over the capacitor, the transistor comprising:
the second conductive layer serving as one of a source electrode and a drain electrode;
a third conductive layer serving as the other of the source electrode and the drain electrode over the second insulating layer;
a semiconductor layer in contact with a side surface of the second insulating layer in the slit, a side surface of the third conductive layer, and a top surface of the second conductive layer;
a gate insulating layer over the semiconductor layer; and
a gate electrode over the gate insulating layer,
wherein the semiconductor layer, the gate insulating layer, and the gate electrode are in the slit of the second insulating layer,
wherein the second conductive layer comprises a first layer, a second layer over the first layer, and a third layer over the second layer,
wherein a top surface of the first layer comprises a depression portion, and
wherein the second layer is in the depression portion.

8. The semiconductor device according to claim 7, wherein the top surface of the first layer is substantially level with a top surface of the second layer.

9. The semiconductor device according to claim 8, wherein a bottom surface of the third layer is in contact with the top surface of the first layer and the top surface of the second layer.

10. The semiconductor device according to claim 7, wherein a side surface of the third insulating layer is aligned with a side surface of the first layer and a side surface of the third layer.

11. The semiconductor device according to claim 7,
wherein the semiconductor layer comprises a first metal oxide,
wherein the third layer comprises a second metal oxide, and
wherein each of the first metal oxide and the second metal oxide comprises indium.

12. The semiconductor device according to claim 7,
wherein the first layer comprises tungsten, and
wherein the second layer comprises titanium nitride.
